(19) United States
(12) Patent Application Publication
(10) Pub. No.: US 2025/0203808 A1
(43) Pub. Date: Jun. 19, 2025

(54) REFRIGERANTS FOR AND METHODS OF COOLING ELECTRONICS

(71) Applicant: HONEYWELL INTERNATIONAL INC., Charlotte, NC (US)

(72) Inventors: Martin Bluhm, Charlotte, NC (US); Yian Zhai, Charlotte, NC (US); Iamnica Linares Mendez, NC, NC (US); Sudharsanam Ramanathan, Charlotte, NC (US)

(73) Assignee: HONEYWELL INTERNATIONAL INC., Charlotte, NC (US)

(21) Appl. No.: 18/976,675

(22) Filed: Dec. 11, 2024

Related U.S. Application Data
(60) Provisional application No. 63/610,458, filed on Dec. 15, 2023.

(51) Int. Cl. H05K 7/20

(52) U.S. Cl. CPC H05K 7/20236; H05K 7/20763

(57) ABSTRACT

Methods of heating and/or cooling of electronic components, articles and/or devices during the manufacture and/or operation thereof comprising: providing an electronic component, article or device which is being manufactured and/or being operated for its intended purpose; and transferring heat to and/or from said electronic component, article and/or device during at least a portion of said manufacturing and/or operating process by directly or indirectly transferring heat between said electronic component, article and/or device and a refrigerant fluid comprising at least 1,3,4,4,4-pentafluoro-(3-trifluoromethyl)-but-1-ene.

### CROSS REFERENCE TO RELATED APPLICATIONS

The present application claims the priority benefit of U.S. Provisional application 63/610,458, filed Dec. 15, 2023, which is incorporated herein by reference in its entirety.

### FIELD

The present invention is related to fluorine substituted olefins and to methods of using same in various applications, including as refrigerants, and especially in connection with the cooling and/or heating of electronics during manufacture thereof and/or during operation thereof.

### BACKGROUND

The industry continues to experience a need for heat transfer fluids which have low global warming potential while providing one or more of (and preferably all of) the following properties: high thermal stability, low toxicity, nonflammability and effective heat transfer properties to meet the requirements of various applications. One particular application which presents an especially difficult challenge in this regard is the cooling (and in some cases also heating) of electronic components, devices and articles during the manufacture and/or during operation thereof. For example, the following electronic devices present a challenge to cool in manufacture and/or in operation: high-capacity energy storage devices, power electronics (TVs, cell phones, monitors, drones), battery thermal management (automotive and stationary), e-powertrain, IGBT, computer server systems, computer chips, 5G network devices, central processing units (CPUs) and displays. The challenge associated with cooling such equipment has increased, at least in part, because such electronic devices have been moving in a direction of higher and higher levels of performance in smaller and smaller packages (such as, for example, in high performance data center computing). This product progression has created the need for higher levels of heat transfer performance (while maintaining many of, and preferably all of, the other factors mentioned above) to ensure that such systems operate within the design temperature range.

By way of example, there has recently been interest in the possibility of providing much needed computing power by running CPUs in an overclocked condition by increasing core frequency and core voltage. However, while overclocking can provide the desired improvement in processing capacity, it also generally results in a concomitant need for improvements in cooling the component during operation to maintain the electronic component within temperature limits and to avoid unacceptable decreases in the reliability and longevity of the electronic component. In this regard, applicants have come to appreciate that advantages can be achieved if cooling fluids used for immersion cooling have boiling points less than 40° C. in order to achieve the coolest operating temperature and the most desirable levels of longevity and reliability. In addition, applicants have come to appreciate that while lower refrigerant boiling point temperatures can have beneficial effects, as boiling point temperatures begin to approach the temperature of the heat sink used to condense the refrigerant (e.g., cooling water), the heat transfer driving force (i.e., delta T) becomes a limiting factor. A significant challenge is thus presented to identify a new, low-GWP cooling fluid that has a boiling point less than about 40° C. while at the same time a sufficiently low dielectric constant to permit immersion cooling, as well as the other properties that are important for immersion cooling applications. For example, while the cooling fluid sold by 3M as FC-3284 has a relatively acceptable dielectric constant of about 1.9, it has a relatively high boiling point of 50° C. On the other hand, the material sold by 3M as HFE7000 has a desirably low boiling point of 34° C. but an undesirably high dielectric constant of 7.4.

Applicants have thus come to appreciate the need for refrigerants, methods and systems which are at once environmentally acceptable (low GWP and low ODP), non-flammable, have low or no toxicity, and have one or more properties needed for the particular application (for example, appropriate heat transfer properties for particular heat transfer applications (including sub−40° C. boiling points for high demand applications such as overclocking) and/or low dielectric constant if the application involves exposure or potential exposure to electronic equipment or components during operation (e.g., immersion cooling of electronic components).

A need also continues to exist for improved fluids to heat and/or cool (i.e., manage the temperature of) electronic components, devices, articles, and in the manufacturing process for such components, devices and articles. This is a substantial technical challenge since the refrigerant will frequently need to operate effectively over a relatively wide range of processing conditions, including process temperatures, and during potential exposure to electronics during said processing.

Examples of electronic manufacturing processes that experience thermal management challenges include the etching, rapid thermal annealing (RTA) and the like of semiconductor integrated circuitry, especially as the line width of such circuitry continues to decrease. These manufacturing challenges include an increasing need to achieve effective and relatively precise temperature control of certain of the fluids and/or components used in the manufacturing process. See for example U.S. Pat. No. 5,904,572 (relating to wet etching processes), U.S. 2005/0155555 (relating to vapor deposition in semiconductor manufacture) and U.S. 2007/0117362 (relating to RTA), each of which is incorporated herein by reference. These challenges are intensified because it is also required in certain electronics cooling applications that the viscosity of the refrigerant fluid being used to manage the temperature of the electronic component has a sufficiently low viscosity in the operating temperature range of the refrigerant fluid to allow the fluid to be circulated and to maintain its desired heat transfer properties.

Vapor phase soldering is another example of an electronics manufacturing process that utilizes refrigerants to help manage processing temperatures. In this application, high temperatures are used and accordingly the heat transfer fluid must be suitable for high temperature exposure (e.g., up to 250° C.). Currently, perfluoropolyethers (PFPE, that is, compounds that have only carbon, oxygen and fluorine) are commonly used as the heat transfer fluids in this application. Although many PFPEs have adequate thermal stability for these high temperatures, they are environmentally persistent with extremely long atmospheric lifetimes which, in turn, gives rise to very high global warming potentials (GWPs).

Another example of the challenge in providing thermal management fluids is the increasing use of electronic vehicles, including particularly, cars, trucks, motorcycles and the like. In electric vehicles the thermal management function is especially important and challenging for several reasons, including the criticality of cooling and/or heating the batteries to be within a relatively narrow temperature range and in a way that is reliable, efficient and safe, and the challenge to provide effective thermal battery management is becoming greater as the demand for battery-operated vehicles with greater range and faster charging increases.

The efficiency and effectiveness of batteries, especially the batteries that provide the power in electronic vehicles, is a function of the operating temperature at which they operate. Thus, thermal management system must frequently be able to do more than simply remove heat from the battery during operation and/or charging—it must be able to effect cooling in a relatively narrow temperature range using equipment that is as low cost as possible and as light weight as possible. This results in the need for a heat transfer fluid in such systems that possesses a difficult-to-achieve combination of physical and performance properties. Furthermore, in some important applications the thermal management system must be able to add heat to the battery, especially as the vehicle is started in cold weather, which adds further to the difficulty of discovering and developing/obtaining compounds and/or compositions effective in such systems, not only from a thermal performance standpoint, but also a myriad of other standpoints, including environmental, safety (flammability and toxicity), dielectric properties, and others.

As a particular example of the importance of dielectric constant, one frequently used system for the thermal management of electric vehicle batteries involves immersing the battery in the fluid used for thermal management. Such systems add the additional constraint that the fluid used in such systems must be electronically compatible with the intimate contact with the battery, or other electronic device or component, while the battery or device is in operation. In general, this means the fluid must not only be non-flammable, but it must also have a low electrical conductivity and a high level of stability while in contact with the battery or other electronic component(s) while the component(s) are operating and at the relatively high temperatures existing during operation. Applicants have come to appreciate the desirability of such properties even in indirect cooling of operating electronic devices and batteries because leakage of any such fluid may result in contact with operating electronic components.

Certain fluorinated compounds, including perfluorinated compounds, have heretofore frequently been used in many of the demanding applications mentioned above. It has been noted, however, that while many of such perfluorinated fluids (such as Fluoroinert FC-72 and FC-3284) exhibit desirable dielectric properties (e.g., dielectric constants of 2.0 or less), these fluids are undesirable from the environmental standpoint since they are generally associated with very high GWP values. See, for example, US Patent Application 2023/0112841, which proposes the use of certain five (5) and six (6) carbon fluorinated olefins for use in an application involving immersion cooling.

U.S. Pat. No. 10,188,887 discloses azeotropic or azeotrope-like compositions comprising of HFO-E-1,3,4,4,4-pentafluoro-3-trifluoromethyl-1-butene (also sometimes referred to as HFO-1438ezy) and a second compound selected from the group consisting of methyl formate and HFO-E-1,1,1,4,4,4-hexafluoro-2-butene. Various uses for such an azeotropic mixture are disclosed, including as a blowing agent for making foam, as a solvent for cleaning and as a heat transfer media. Such azeotropic compositions in which the second component is methyl formate are said to consist essentially of HFO-1438ezy and at least about 53.5% of methyl formate (see col. 5, lines 1-16), and azeotropic compositions in which the second component is HFO-E-1,1,1,4,4,4-hexafluoro-2-butene are said to consist essentially of HFO-1438ezy and either 91-99 mole % or 1 to 6 mole % of is HFO-E-1,1,1,4,4,4-hexafluoro-2-butene. (see col. 6, lines 42-56). This publication neither recognizes the challenges disclosed herein with heat transfer in electronics, nor does it disclose immersion cooling techniques.

Thus, applicants have come to appreciate the need, among the other needs described herein, for thermal management methods and systems which use a heat transfer fluid which is environmentally acceptable (low GWP and low ODP), non-flammable, has low or no toxicity, and has excellent electrical insulating properties and has thermal properties that provide effective cooling and/or heating, especially in electronics and semiconductor manufacturing processes that involve relatively high temperatures and/or for use to maintain process conditions in relatively narrow temperature range(s).

### SUMMARY

The present invention includes methods of heating and/or cooling of electronic components, articles and/or devices during the manufacture and/or operation thereof.

The present methods include the use of a refrigerant composition comprising at least the trans isomer of 1,3,4,4,4-pentafluoro-(3-trifluoromethyl)-but-1-ene (hereinafter sometimes referred to herein as “HFO-1438ezy(E)”) and not having greater than 50% by weight of methyl formate and not having an amount of HFO-E-1,1,1,4,4,4-hexafluoro-2-butene in the range of 1 to 6 mole % or in the range of 91-99 mole % of the refrigerant composition. Refrigerant compositions according to this paragraph are sometimes referred to herein for convenience as Refrigerant 1A.

The present methods include the use of a refrigerant composition comprising at least the cis isomer of 1,3,4,4,4-pentafluoro-(3-trifluoromethyl)-but-1-ene (hereinafter sometimes referred to herein as “HFO-1438ezy(Z)”) and not having greater than 50% by weight of methyl formate and not having an amount of HFO-E-1,1,1,4,4,4-hexafluoro-2-butene in the range of 1 to 6 mole % or in the range of 91-99 mole % of the refrigerant composition. Refrigerant compositions according to this paragraph are sometimes referred to herein for convenience as Refrigerant 1B.

The present methods include the use of a refrigerant composition comprising at least HFO-1438ezy(E). Refrigerant compositions according to this paragraph are sometimes referred to herein for convenience as Refrigerant 1C.

The present methods include the use of a refrigerant composition comprising HFO-1438ezy(Z). Refrigerant compositions according to this paragraph are sometimes referred to herein for convenience as Refrigerant 1D.

The present methods include the use of a refrigerant composition comprising at least about 10% by weight of HFO-1438ezy(E) and not having greater than 50% by weight of methyl formate and not having an amount of HFO-E-1,1,1,4,4,4-hexafluoro-2-butene in the range of 1 to 6 mole % or in the range of 91-99 mole % of the refrigerant composition. Refrigerant compositions according to this paragraph are sometimes referred to herein for convenience as Refrigerant 2A.

The present methods include the use of a refrigerant composition comprising at least about 10% by weight of HFO-1438ezy(E). Refrigerant compositions according to this paragraph are sometimes referred to herein for convenience as Refrigerant 2B.

The present methods include the use of a refrigerant composition comprising at least about 50% by weight of HFO-1438ezy(E) and not having greater than 50% by weight of methyl formate and not having an amount of HFO-E-1,1,1,4,4,4-hexafluoro-2-butene in the range of 1 to 6 mole % or in the range of 91-99 mole % of the refrigerant composition. Refrigerant compositions according to this paragraph are sometimes referred to herein for convenience as Refrigerant 3A.

The present methods include the use of a refrigerant composition comprising at least about 50% by weight of HFO-1438ezy(E). Refrigerant compositions according to this paragraph are sometimes referred to herein for convenience as Refrigerant 3B.

The present methods include the use of a refrigerant composition comprising at least about 75% by weight of HFO-1438ezy(E) and not having greater than 50% by weight of methyl formate and not having an amount of HFO-E-1,1,1,4,4,4-hexafluoro-2-butene in the range of 1 to 6 mole % or in the range of 91-99 mole % of the refrigerant composition. Refrigerant compositions according to this paragraph are sometimes referred to herein for convenience as Refrigerant 4A.

The present methods include the use of a refrigerant composition comprising at least about 75% by weight of HFO-1438ezy€. Refrigerant compositions according to this paragraph are sometimes referred to herein for convenience as Refrigerant 4B.

The present methods include the use of a refrigerant composition comprising at least about 90% by weight of HFO-1438ezy(E) and not having greater than 50% by weight of methyl formate and not having an amount of HFO-E-1,1,1,4,4,4-hexafluoro-2-butene in the range of 1 to 6 mole % or in the range of 91-99 mole % of the refrigerant composition. Refrigerant compositions according to this paragraph are sometimes referred to herein for convenience as Refrigerant 5A.

The present methods include the use of a refrigerant composition comprising at least about 90% by weight of HFO-1438ezy(E). Refrigerant compositions according to this paragraph are sometimes referred to herein for convenience as Refrigerant 5B.

The present methods include the use of a refrigerant composition consisting essentially of HFO-1438ezy(E) and not having greater than 50% by weight of methyl formate and not having an amount of HFO-E-1,1,1,4,4,4-hexafluoro-2-butene in the range of 1 to 6 mole % or in the range of 91-99 mole % of the refrigerant composition. Refrigerant compositions according to this paragraph are sometimes referred to herein for convenience as Refrigerant 6A.

The present methods include the use of a refrigerant composition consisting essentially of HFO-1438ezy(E). Refrigerant compositions according to this paragraph are sometimes referred to herein for convenience as Refrigerant 6B.

The present methods include the use of a refrigerant composition consisting of HFO-1438ezy(E). Refrigerant compositions according to this paragraph are sometimes referred to herein for convenience as Refrigerant 7.

The present methods include the use of a refrigerant composition comprising a combination of HFO-1438ezy(Z) and HFO-1438ezy(E) and not having greater than 50% by weight of methyl formate and not having an amount of HFO-E-1,1,1,4,4,4-hexafluoro-2-butene in the range of 1 to 6 mole % or in the range of 91-99 mole % of the refrigerant composition. Refrigerant compositions according to this paragraph are sometimes referred to herein for convenience as Refrigerant 8A.

The present methods include the use of a refrigerant composition comprising a combination of HFO-1438ezy(Z) and HFO-1438ezy(E). Refrigerant compositions according to this paragraph are sometimes referred to herein for convenience as Refrigerant 8B.

The present invention includes methods of heating and/or cooling of electronic components, articles and/or devices during the manufacture and/or operation thereof comprising:
(a) providing an electronic component, article and/or device which is being manufactured and/or being operated for its intended purpose; and
(b) during at least a portion of said manufacturing process or operating process, transferring heat to and/or from said electronic component, article or device by directly or indirectly transferring heat between said electronic component, article and/or device and a refrigerant fluid comprising at least HFO-1438ezy(E).
   Heat transfer methods according to this paragraph are sometimes referred to herein for convenience as Heat Transfer Methods 1.

The present invention also includes methods of heating and/or cooling of components, articles and/or devices during the manufacture and/or operation thereof comprising:
(a) providing an electronic component, article and/or device which is being manufactured and/or being operated for its intended purpose; and
(b) during at least a portion of said manufacturing and/or operating process, transferring heat to and/or from said electronic component, article and/or device by directly transferring heat between said electronic component, article or device and a refrigerant fluid comprising at least HFO-1438ezy(E).
   Heat transfer methods according to this paragraph are sometimes referred to herein for convenience as Heat Transfer Methods 2A.

The present invention also includes methods of heating and/or cooling of components, articles and/or devices during the manufacture and/or operation thereof comprising:
(a) providing an electronic component, article and/or device which is being manufactured and/or being operated for its intended purpose; and
(b) during at least a portion of said manufacturing and/or operating process, transferring heat to and/or from said electronic component, article and/or device by direct sensible heat transfer between said electronic component, article and/or device and a refrigerant fluid comprising at least HFO-1438ezy(E).
   Heat transfer methods according to this paragraph are sometimes referred to herein for convenience as Heat Transfer Methods 2B.

The present invention also includes methods of heating and/or cooling of components, articles and/or devices during the manufacture and/or operation thereof comprising:
(a) providing an electronic component, article and/or device which is being manufactured and/or being operated for its intended purpose; and
(b) during at least a portion of said manufacturing and/or operating process, transferring heat to and/or from said electronic component, article and/or device by direct latent heat transfer between said electronic component, article and/or device and a refrigerant fluid comprising at least HFO-1438ezy(E).
   Heat transfer methods according to this paragraph are sometimes referred to herein for convenience as Heat Transfer Methods 2C.

The present invention also includes methods of heating and/or cooling of components, articles and/or devices during the manufacture and/or operation thereof comprising:
(a) providing an electronic component, article and/or device which is being manufactured and/or being operated for its intended purpose; and
(b) during at least a portion of said manufacturing and/or operating process, transferring heat to and/or from said electronic component, article and/or device by directly transferring heat between said electronic component, article and/or device and a refrigerant fluid comprising at least about 10% by weight of HFO-1438ezy(E).
   Heat transfer methods according to this paragraph are sometimes referred to herein for convenience as Heat Transfer Methods 3A.

The present invention also includes methods of heating and/or cooling of components, articles and/or devices during the manufacture and/or operation thereof comprising:
(a) providing an electronic component, article and/or device which is being manufactured and/or being operated for its intended purpose; and
(b) during at least a portion of said manufacturing and/or operating process, transferring heat to and/or from said electronic component, article and/or device by direct sensible heat transfer between said electronic component, article and/or device and a refrigerant fluid comprising at least at least about 10% by weight of HFO-1438ezy(E).
   Heat transfer methods according to this paragraph are sometimes referred to herein for convenience as Heat Transfer Methods 3B.

The present invention also includes methods of heating and/or cooling of components, articles and/or devices during the manufacture and/or operation thereof comprising:
(a) providing an electronic component, article and/or device which is being manufactured and/or being operated for its intended purpose; and
(b) during at least a portion of said manufacturing and/or operating process, transferring heat to and/or from said electronic component, article and/or device by direct latent heat transfer between said electronic component, article and/or device and a refrigerant fluid comprising at least at least about 10% by weight of HFO-1438ezy(E).
   Heat transfer methods according to this paragraph are sometimes referred to herein for convenience as Heat Transfer Methods 3C.

The present invention also includes methods of heating and/or cooling of components, articles and/or devices during the manufacture and/or operation thereof comprising:
(a) providing an electronic component, article and/or device which is being manufactured and/or being operated for its intended purpose; and
(b) during at least a portion of said manufacturing and/or operating process, transferring heat to and/or from said electronic component, article and/or device by directly transferring heat between said electronic component, article and/or device and a refrigerant fluid comprising at least about 50% by weight of HFO-1438ezy(E).
   Heat transfer methods according to this paragraph are sometimes referred to herein for convenience as Heat Transfer Methods 4A.

The present invention also includes methods of heating and/or cooling of components, articles and/or devices during the manufacture and/or operation thereof comprising:
(a) providing an electronic component, article and/or device which is being manufactured and/or being operated for its intended purpose; and
(b) during at least a portion of said manufacturing and/or operating process, transferring heat to and/or from said electronic component, article and/or device by direct sensible heat transfer between said electronic component, article and/or device and a refrigerant fluid comprising at least at least about 50% by weight of HFO-1438ezy(E).
   Heat transfer methods according to this paragraph are sometimes referred to herein for convenience as Heat Transfer Methods 4B.

The present invention also includes methods of heating and/or cooling of components, articles and/or devices during the manufacture and/or operation thereof comprising:
(a) providing an electronic component, article and/or device which is being manufactured and/or being operated for its intended purpose; and
(b) during at least a portion of said manufacturing and/or operating process, transferring heat to and/or from said electronic component, article and/or device by direct latent heat transfer between said electronic component, article and/or device and a refrigerant fluid comprising at least at least about 50% by weight of HFO-1438ezy(E).
   Heat transfer methods according to this paragraph are sometimes referred to herein for convenience as Heat Transfer Methods 4C.

The present invention also includes methods of heating and/or cooling of components, articles and/or devices during the manufacture and/or operation thereof comprising:
(a) providing an electronic component, article and/or device which is being manufactured and/or being operated for its intended purpose; and
(b) during at least a portion of said manufacturing and/or operating process, transferring heat to and/or from said electronic component, article and/or device by directly transferring between said electronic component, article and/or device and a refrigerant fluid comprising at least about 75% by weight of HFO-1438ezy(E).
   Heat transfer methods according to this paragraph are sometimes referred to herein for convenience as Heat Transfer Methods 5A.

The present invention also includes methods of heating and/or cooling of components, articles and/or devices during the manufacture and/or operation thereof comprising:
(a) providing an electronic component, article and/or device which is being manufactured and/or being operated for its intended purpose; and
(b) during at least a portion of said manufacturing and/or operating process, transferring heat to and/or from said electronic component, article and/or device by direct sensible heat transfer between said electronic component, article and/or device and a refrigerant fluid comprising at least at least about 75% by weight of HFO-1438ezy(E).
   Heat transfer methods according to this paragraph are sometimes referred to herein for convenience as Heat Transfer Methods 5B.

The present invention also includes methods of heating and/or cooling of components, articles and/or devices during the manufacture and/or operation thereof comprising:
(a) providing an electronic component, article and/or device which is being manufactured and/or being operated for its intended purpose; and
(b) during at least a portion of said manufacturing and/or operating process, transferring heat to and/or from said electronic component, article and/or device by direct latent heat transfer between said electronic component, article and/or device and a refrigerant fluid comprising at least at least about 75% by weight of HFO-1438ezy(E).
   Heat transfer methods according to this paragraph are sometimes referred to herein for convenience as Heat Transfer Methods 5C.

The present invention also includes methods of heating and/or cooling of components, articles and/or devices during the manufacture and/or operation thereof comprising:
(a) providing an electronic component, article and/or device which is being manufactured and/or being operated for its intended purpose; and
(b) during at least a portion of said manufacturing and/or operating process, transferring heat to and/or from said electronic component, article and/or device by directly transferring between said electronic component, article and/or device and a refrigerant fluid comprising at least about 90% by weight of HFO-1438ezy(E).
   Heat transfer methods according to this paragraph are sometimes referred to herein for convenience as Heat Transfer Methods 6A.

The present invention also includes methods of heating and/or cooling of components, articles and/or devices during the manufacture and/or operation thereof comprising:
(a) providing an electronic component, article and/or device which is being manufactured and/or being operated for its intended purpose; and
(b) during at least a portion of said manufacturing and/or operating process, transferring heat to and/or from said electronic component, article and/or device by direct sensible heat transfer between said electronic component, article and/or device and a refrigerant fluid comprising at least at least about 90% by weight of HFO-1438ezy(E).
   Heat transfer methods according to this paragraph are sometimes referred to herein for convenience as Heat Transfer Methods 6B.

The present invention also includes methods of heating and/or cooling of components, articles and/or devices during the manufacture and/or operation thereof comprising:
(a) providing an electronic component, article and/or device which is being manufactured and/or being operated for its intended purpose; and
(b) during at least a portion of said manufacturing and/or operating process, transferring heat to and/or from said electronic component, article and/or device by direct latent heat transfer between said electronic component, article and/or device and a refrigerant fluid comprising at least at least about 90% by weight of HFO-1438ezy(E).
   Heat transfer methods according to this paragraph are sometimes referred to herein for convenience as Heat Transfer Methods 6C.

The present invention also includes methods of heating and/or cooling of components, articles and/or devices during the manufacture and/or operation thereof comprising:
(a) providing an electronic component, article and/or device which is being manufactured and/or being operated for its intended purpose; and
(b) during at least a portion of said manufacturing and/or operating process, transferring heat to and/or from said electronic component, article and/or device by directly transferring between said electronic component, article and/or device and a refrigerant fluid consisting essentially of HFO-1438ezy(E).
   Heat transfer methods according to this paragraph are sometimes referred to herein for convenience as Heat Transfer Methods 7A.

The present invention also includes methods of heating and/or cooling of components, articles and/or devices during the manufacture and/or operation thereof comprising:
(a) providing an electronic component, article and/or device which is being manufactured and/or being operated for its intended purpose; and
(b) during at least a portion of said manufacturing and/or operating process, transferring heat to and/or from said electronic component, article and/or device by direct sensible heat transfer between said electronic component, article and/or device and a refrigerant fluid consisting essentially of HFO-1438ezy(E).
   Heat transfer methods according to this paragraph are sometimes referred to herein for convenience as Heat Transfer Methods 7B.

The present invention also includes methods of heating and/or cooling of components, articles and/or devices during the manufacture and/or operation thereof comprising:
(a) providing an electronic component, article and/or device which is being manufactured and/or being operated for its intended purpose; and
(b) during at least a portion of said manufacturing and/or operating process, transferring heat to and/or from said electronic component, article and/or device by direct latent heat transfer between said electronic component, article and device and a refrigerant fluid consisting essentially of HFO-1438ezy(E).
   Heat transfer methods according to this paragraph are sometimes referred to herein for convenience as Heat Transfer Methods 7C.

The present invention also includes methods of heating and/or cooling of components, articles and/or devices during the manufacture and/or operation thereof comprising:
(a) providing an electronic component, article and/or device which is being manufactured and/or being operated for its intended purpose; and
(b) during at least a portion of said manufacturing and/or operating process, transferring heat to and/or from said electronic component, article and/or device by directly transferring heat between said electronic component, article and/or device and a refrigerant fluid consisting of HFO-1438ezy(E).
   Heat transfer methods according to this paragraph are sometimes referred to herein for convenience as Heat Transfer Methods 8A.

The present invention also includes methods of heating and/or cooling of components, articles and/or devices during the manufacture and/or operation thereof comprising:
(a) providing an electronic component, article and/or device which is being manufactured and/or being operated for its intended purpose; and
(b) during at least a portion of said manufacturing and/or operating process, transferring heat to and/or from said electronic component, article and/or device by direct sensible heat transfer between said electronic component, article and/or device and a refrigerant fluid consisting of HFO-1438ezy(E).
   Heat transfer methods according to this paragraph are sometimes referred to herein for convenience as Heat Transfer Methods 8B.

The present invention also includes methods of heating and/or cooling of components, articles and/or devices during the manufacture and/or operation thereof comprising:
(a) providing an electronic component, article and/or device which is being manufactured and/or being operated for its intended purpose; and
(b) during at least a portion of said manufacturing and/or operating process, transferring heat to and/or from said electronic component, article and/or device by direct latent heat transfer between said electronic component, article and/or device and a refrigerant fluid consisting of HFO-1438ezy(E).
   Heat transfer methods according to this paragraph are sometimes referred to herein for convenience as Heat Transfer Methods 8C.

The present invention also includes operating electronic components, devices, articles and systems which are in thermal contact, either directly or indirectly, with Refrigerant 1. Electronic components, devices, articles and systems according to this paragraph are sometimes referred to herein for convenience as Electronic 1.

The present invention also includes operating electronic components, devices, articles and systems which are in thermal contact, either directly or indirectly, with Refrigerant 2. Electronic components, devices, articles and systems according to this paragraph are sometimes referred to herein for convenience as Electronic 2.

The present invention also includes operating electronic components, devices, articles and systems which are in thermal contact, either directly or indirectly, with Refrigerant 3. Electronic components, devices, articles and systems according to this paragraph are sometimes referred to herein for convenience as Electronic 3.

The present invention also includes operating electronic components, devices, articles and systems which are in thermal contact, either directly or indirectly, with Refrigerant 4. Electronic components, devices, articles and systems according to this paragraph are sometimes referred to herein for convenience as Electronic 4.

The present invention also includes operating electronic components, devices, articles and systems which are in thermal contact, either directly or indirectly, with a Refrigerant 5. Electronic components, devices, articles and systems according to this paragraph are sometimes referred to herein for convenience as Electronic 5.

The present invention also includes operating electronic components, devices, articles and systems which are in thermal contact, either directly or indirectly, with Refrigerant 6. Electronic components, devices, articles and systems according to this paragraph are sometimes referred to herein for convenience as Electronic 6.

The present invention also includes operating electronic components, devices, articles and systems which are in thermal contact, either directly or indirectly, with Refrigerant 7. Electronic components, devices, articles and systems according to this paragraph are sometimes referred to herein for convenience as Electronic 7.

The present invention also includes operating electronic components, devices, articles and systems which are in thermal contact, either directly or indirectly, with Refrigerant 8. Electronic components, devices, articles and systems according to this paragraph are sometimes referred to herein for convenience as Electronic 8.

The present invention also includes operating electronic components, devices, articles and systems which are in direct thermal contact with Refrigerant 1, wherein said Refrigerant 1 is in only the liquid phase. Electronic components, devices, articles and systems according to this paragraph are sometimes referred to herein for convenience as Electronic 9.

The present invention also includes operating electronic components, devices, articles and systems which are in direct thermal contact with Refrigerant 2, wherein said Refrigerant 2 is in only the liquid phase. Electronic components, devices, articles and systems according to this paragraph are sometimes referred to herein for convenience as Electronic 10.

The present invention also includes operating electronic components, devices, articles and systems which are in direct thermal contact with Refrigerant 3, wherein said Refrigerant 3 is in only the liquid phase. Electronic components, devices, articles and systems according to this paragraph are sometimes referred to herein for convenience as Electronic 11.

The present invention also includes operating electronic components, devices, articles and systems which are in direct thermal contact with Refrigerant 4, wherein said Refrigerant 4 is in only the liquid phase. Electronic components, devices, articles and systems according to this paragraph are sometimes referred to herein for convenience as Electronic 12.

The present invention also includes operating electronic components, devices, articles and systems which are in direct thermal contact with Refrigerant 5, wherein said Refrigerant 5 is in only the liquid phase. Electronic components, devices, articles and systems according to this paragraph are sometimes referred to herein for convenience as Electronic 13.

The present invention also includes operating electronic components, devices, articles and systems which are in direct thermal contact with Refrigerant 6, wherein said Refrigerant 6 is in only the liquid phase. Electronic components, devices, articles and systems according to this paragraph are sometimes referred to herein for convenience as Electronic 14.

The present invention also includes operating electronic components, devices, articles and systems which are in direct thermal contact with Refrigerant 7, wherein said Refrigerant 7 is in only the liquid phase. Electronic components, devices, articles and systems according to this paragraph are sometimes referred to herein for convenience as Electronic 15.

The present invention also includes operating electronic components, devices, articles and systems which are in direct thermal contact with Refrigerant 8, wherein said Refrigerant 8 is in only the liquid phase. Electronic components, devices, articles and systems according to this paragraph are sometimes referred to herein for convenience as Electronic 16.

The present invention also includes operating electronic components, devices, articles and systems which are in direct thermal contact with Refrigerant 1, wherein said Refrigerant 1 is in only the liquid phase. Electronic components, devices, articles and systems according to this paragraph are sometimes referred to herein for convenience as Electronic 17.

The present invention also includes operating electronic components, devices, articles and systems which are in direct thermal contact with Refrigerant 2, wherein said Refrigerant 2 is in only the liquid phase. Electronic components, devices, articles and systems according to this paragraph are sometimes referred to herein for convenience as Electronic 18.

The present invention also includes operating electronic components, devices, articles and systems which are in direct thermal contact with Refrigerant 3, wherein said Refrigerant 3 is in only the liquid phase. Electronic components, devices, articles and systems according to this paragraph are sometimes referred to herein for convenience as Electronic 19.

The present invention also includes operating electronic components, devices, articles and systems which are in direct thermal contact with Refrigerant 4, wherein said Refrigerant 4 is in only the liquid phase. Electronic components, devices, articles and systems according to this paragraph are sometimes referred to herein for convenience as Electronic 20.

The present invention also includes operating electronic components, devices, articles and systems which are in direct thermal contact with Refrigerant 5, wherein said Refrigerant 5 is in only the liquid phase. Electronic components, devices, articles and systems according to this paragraph are sometimes referred to herein for convenience as Electronic 21.

The present invention also includes operating electronic components, devices, articles and systems which are in direct thermal contact with Refrigerant 6, wherein said Refrigerant 6 is in only the liquid phase. Electronic components, devices, articles and systems according to this paragraph are sometimes referred to herein for convenience as Electronic 22.

The present invention also includes operating electronic components, devices, articles and systems which are in direct thermal contact with Refrigerant 7, wherein said Refrigerant 7 is in only the liquid phase. Electronic components, devices, articles and systems according to this paragraph are sometimes referred to herein for convenience as Electronic 23.

The present invention also includes operating electronic components, devices, articles and systems which are in direct thermal contact with Refrigerant 8, wherein said Refrigerant 8 is in only the liquid phase. Electronic components, devices, articles and systems according to this paragraph are sometimes referred to herein for convenience as Electronic 24.

The present invention also includes the use of a composition comprising at least the trans isomer of 1,3,4,4,4-pentafluoro-(3-trifluoromethyl)-but-1-ene (hereinafter sometimes referred to herein as “HFO-1438ezy(E)”). Compositions according to this paragraph are sometimes referred to herein for convenience as Composition 1A.

The present invention also includes the use of a composition comprising at least the cis isomer of 1,3,4,4,4-pentafluoro-(3-trifluoromethyl)-but-1-ene (hereinafter sometimes referred to herein as “HFO-1438ezy(Z)”). Compositions according to this paragraph are sometimes referred to herein for convenience as Composition 1B.

The present invention also includes the use of a composition comprising a combination of the cis isomer and the trans isomer of 1,3,4,4,4-pentafluoro-(3-trifluoromethyl)-but-1-ene (hereinafter sometimes referred to herein as “HFO-1438EZ”). Compositions according to this paragraph are sometimes referred to herein for convenience as Composition 1C.

### BRIEF DESCRIPTION OF THE DRAWINGS

The above mentioned and other features of the present invention, and the manner of attaining them, will become more apparent and the disclosure itself will be better understood by reference to the following description of embodiments of the disclosure taken in conjunction with the accompanying drawings.

FIG. 1 is a schematic representation of a thermal management system of the present invention.

FIG. 2A is a schematic representation of a first exemplary immersion cooling system according to the present invention.

FIG. 2B is a schematic representation of a second exemplary immersion cooling system according to the present invention.

FIGS. 3A and 3B are schematic illustrations of a battery thermal management system according to one embodiment of the present invention.

FIG. 4 is a photograph showing a battery thermal management system according to one embodiment of the present invention.

FIG. 5 is a schematic diagram of an exemplary organic Rankine cycle.

FIG. 6 is a schematic diagram of an exemplary heat pump.

FIG. 7 is a schematic diagram of an exemplary secondary loop system.

FIG. 8 is a semi-schematic drawing of one example of a lithium-ion battery cooling system using a composition of the present invention.

FIG. 9 is a semi-schematic drawing of one example of a lithium-ion battery having an electrolyte formulation of the present invention.

FIG. 10 is a semi-schematic drawing of a heat pipe using a heat transfer composition of the present invention.

FIG. 11 is a side cross-sectional view of a conventional wet-etching station.

### DETAILED DESCRIPTION

### I. Definitions

The terms “R-1132(E)”, “HFO-1132(E)” and “transHFO-1132(E)” each means the trans isomer of 1,2-difluorethylene.

The terms “R-1132a” and “HFO-1132a” each means 1,1-difluoroethylene.

The terms “R-1234yf” and “HFO-1234yf” mean 2,3,3,3-tetrafluoropropene.

The terms “R-1234ze(E)” and “HFO-1234ze(E)” means the trans isomer of 1,3,3,3-tetrafluoropropene.

The terms “R-1233zd(E)” and “HFCO-1233ze(E)” means the trans isomer of 1-chloro-3,3,3-trifluoropropene.

The terms “R-1233zd(Z)” and “HFCO-1233ze(Z)” means the cis isomer of 1-chloro-3,3,3-trifluoropropene.

The terms “R-1224yd” and “HFCO-1224yd” means 1-chloro-2,3,3,3-tetrafluoropropane, without limitation as to isomeric form.

The terms “R1336mzz(E)” and “HFO-1336mzz(E)” mean the trans isomer of 1,1,1,4,4,4-hexafluoro-2-butene.

The term “HFE-7000” means 1-methoxyheptafluoropropane (C3F7OCH3).

The term “HFE-7100” means 1-methoxy-nonafluorobutane (C4F9OCH3).

The term “HFE-7200” means ethoxy-nonafluorobutane (C4F9OC2H5).

The term “HFE-7300” means 1,1,1,2,2,3,4,5,5,5-decafluoro-3-methoxy-4-trifluoromethylpentane.

The term “HFE-7500” means 2-trifluoromethyl3-ethoxydodecofluorohexane.

The term “HFO-1438EZ” means the cis and/or trans form, and any mixture of these, of the compound 1,3,4,4,4-pentafluoro-(3-trifluoromethyl)-but-1-ene, which has the structure identified below:

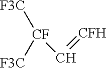

The term “HFO-1438ezy(E)” means the trans form of the compound 1,3,4,4,4-pentafluoro-(3-trifluoromethyl)-but-1-ene.

The term “HFO-1438ezy(Z)” means the cis form of the compound 1,3,4,4,4-pentafluoro-(3-trifluoromethyl)-but-1-ene.

As used herein, a reference to a defined group, such as “Heat Transfer Method 2-3” refers to each method within that group, including wherein a definition number includes a suffix. Thus, reference to “Heat Transfer Method 2-3” includes reference to each Heat Transfer Method 2A, Heat Transfer Method 2B, etc. and Heat Transfer Method 3A, Heat Transfer Method 3B, etc.

“Electronic Device”, and related word forms, means a device, or a component of a device, which is in the process of performing its intended function by receiving, and/or transmitting and/or producing electrical energy and/or electronic signals. Thus, the term “operating electronic device” as used herein includes, for example, a battery which is in the process of providing a source of electrical energy to another component and also a battery which is being charged or recharged, for example.

The term “Heat Transfer Composition” and related word forms means a composition in the form of a fluid (liquid or gas) which is used to transfer heat or energy from one fluid, article or device to another fluid, article or device, and thus includes for example refrigerants, thermal management fluids and working fluids for Rankine cycles.

The term “Rankine Cycle” as used herein refers to systems which include: 1) a boiler to change liquid to vapor at high pressure; 2) a turbine to expand the vapor to derive mechanical energy; 3) a condenser to change low pressure exhaust vapor from the turbine to low pressure liquid; and 4) a pump to move condensate liquid back to the boiler at high pressure. Such systems are commonly used for electrical power generation.

When a heat transfer composition is used in thermal management to keep a device or article within a particular temperature range (e.g., in electronic cooling), it is sometimes referred herein as a thermal management fluid.

The component(s) that are present in a heat transfer composition for the purpose of transferring heat (as opposed to, for example, providing lubrication or stabilization) in a heat transfer system (e.g., a vapor compression heat transfer system), that component or combination of components are sometimes referred to herein as a refrigerant.

“Operating Electronic Device”, and related word forms, means a device, or a component of a device, which is in the process of performing its intended function by receiving, and/or transmitting and/or producing electrical energy and/or electronic signals. Thus, the term “operating electronic device” as used herein includes, for example, a battery which is in the process of providing a source of electrical energy to another component and also a battery which is being charged or recharged.

“Thermal contact”, and related forms thereof, includes direct contact with the surface and indirect contact though another body or fluid which facilitates the flow of heat between the surface and the fluid.

“Thermal Conductivity” refers to the breakdown voltage in kV as measured in accordance with ASTM D7896-19.

“Global Warming Potential (“GWP”)” was developed to allow comparisons of the global warming impact of different gases. It is a measure of how much energy the emission of one ton of a gas will absorb over a given period of time, relative to the emission of one ton of carbon dioxide. The larger GWP, the more that a given gas warms the Earth compared to CO2 over that time period. The time period usually used for GWP is 100 years. GWP provides a common measure, which allows analysts to add up emission estimates of different gases.

“LC50” is a measure of the acute toxicity of a compound. The acute inhalation toxicity of a compound can be assessed using the method described in the OECD Guideline for Testing of Chemicals No. 403 “Acute Inhalation Toxicity” (2009), Method B.2. (Inhalation) of Commission Regulation (EC) No. 440/2008.

The term “AMES-negative” refers to a compound or composition which returns a negative result when tested under the Ames test as specified in the Toxic Substances Control Act of the United States.

“Flash Point” refers the lowest temperature at which vapors of the liquid will keep burning after the ignition source is removed as determined in accordance with ASTM D3828-16a.

“Non-flammable” in the context of heat transfer compositions, including refrigerants and thermal management compositions, means compounds or compositions which do not have a flash point below 100° F. (37.8° C.) in accordance with NFPA 30: Flammable and Combustible Liquid Code. The flash point of a fluid refers the lowest temperature at which vapors of the composition will keep burning after the ignition source is removed as determined in accordance with ASTM D3828-16a.

In the context of a refrigerant composition, a compound or composition which is non-flammable and low or no-toxicity would be classified as “A1” by ASHRAE Standard 34-2016 Designation and Safety Classification of Refrigerants and described in Appendix B1 to ASHRAE Standard 34-2016.

“No toxicity” or “low toxicity” means a fluid classified as class “A” by ASHRAE Standard 34-2016 Designation and Safety Classification of Refrigerants and described in Appendix B1 to ASHRAE Standard 34-2016.

“Capacity” is the amount of cooling provided, in BTUs/hr, by the refrigerant in the refrigeration system. This is experimentally determined by multiplying the change in enthalpy in BTU/lb, of the refrigerant as it passes through the evaporator by the mass flow rate of the refrigerant. The enthalpy can be determined from the measurement of the pressure and temperature of the refrigerant. The capacity of the refrigeration system relates to the ability to maintain an area to be cooled at a specific temperature. The capacity of a refrigerant represents the amount of cooling or heating that it provides and provides some measure of the capability of a compressor to pump quantities of heat for a given volumetric flow rate of refrigerant. In other words, given a specific compressor, a refrigerant with a higher capacity will deliver more cooling or heating power.

“Coefficient of Performance” (hereinafter “COP”) is a universally accepted measure of refrigerant performance, especially useful in representing the relative thermodynamic efficiency of a refrigerant in a specific heating or cooling cycle involving evaporation or condensation of the refrigerant. In refrigeration engineering, this term expresses the ratio of useful refrigeration or cooling capacity to the energy applied by the compressor in compressing the vapor and therefore expresses the capability of a given compressor to pump quantities of heat for a given volumetric flow rate of a heat transfer fluid, such as a refrigerant. In other words, given a specific compressor, a refrigerant with a higher COP will deliver more cooling or heating power. One means for estimating COP of a refrigerant at specific operating conditions is from the thermodynamic properties of the refrigerant using standard refrigeration cycle analysis techniques (see for example, R. C. Downing, FLUOROCARBON REFRIGERANTS HANDBOOK, Chapter 3, Prentice-Hall, 1988 which is incorporated herein by reference in its entirety).

“Vapor Degreasing” means a surface-cleaning process that uses solvent vapors to wash oils and other contaminants off of articles or parts of articles.

“Dielectric Constant” means the dielectric constant as measured in accordance with ASTM D150-11 at room temperature at 20 giga hertz (GHz).

“Dielectric Strength” refers to the breakdown voltage in kV as measured in accordance with ASTM D87-13, Procedure A, with the modification that the spacing between the electrodes is 2.54 mm and the rate of rise was 500 V/sec.

“Sensible heat” takes its ordinary meaning, that is, that heat is transferred to or from the refrigerant by causing a temperature change in the refrigerant without the refrigerant changing phase.

“Latent heat” takes its ordinary meaning, that is, that heat is transferred to or from the refrigerant by causing the refrigerant to changing phase.

As used herein, the singular forms “a”, “an”, and “the” include plural references unless the context clearly dictates otherwise.

As used herein, the recitation of numerical ranges by endpoints includes all numbers subsumed within that range (e.g., 1 to 5 includes 1, 1.5, 2, 2.75, 3, 3.8, 4, and 5).

Unless otherwise indicated, all numbers expressing quantities or ingredients, measurement of properties and so forth used in the specification and embodiments are to be understood as being modified in all instances by the term “about.” Accordingly, unless indicated to the contrary, the numerical parameters set forth in the foregoing specification and attached listing of embodiments can vary depending upon the desired properties sought to be obtained by those skilled in the art utilizing the teachings of the present disclosure. At the very least, and not as an attempt to limit the application of the doctrine of equivalents to the scope of the claimed embodiments, each numerical parameter should at least be construed in light of the number of reported significant digits and by applying ordinary rounding techniques.

As used herein, the phrase “within any range encompassed by any two of the foregoing values as endpoints” literally means that any range may be selected from any two of the values listed prior to such phrase regardless of whether the values are in the lower part of the listing or in the higher part of the listing. For example, a pair of values may be selected from two lower values, two higher values, or a lower value and a higher value.

The terms “HFO-1438ez(Z)” and “HFO-1438ez(E)” as used herein mean the compounds identified in, and having the physical properties identified in, the following Table 1, it being understood that the numeric values are proceeded by the term “about.”

TABLE 1

| | Physical Properties | | | | |
|---|---|---|---|---|---|
| | Boiling | Dielectric | Dissipation | | |
| | point | Constant | Factor | | |
| OFP | (° C.) | (20 GHz) | (20 GHz) | GWP | ODP |
| (E)-1,3,4,4,4- | 28 | 2.43 | 0.09 | <10 | 0 |
| pentafluoro-(3- | | | | | |
| trifluoromethyl)- | | | | | |
| but-1-ene | | | | | |
| (HFO-1438ezy(E)) | | | | | |
| (Z)-1,3,4,4,4- | 55 | 7.8 | TBD | <10 | 0 |
| pentafluoro-(3- | | | | | |
| trifluoromethyl)- | | | | | |
| but-1-ene | | | | | |
| (HFO-1438ezy(Z)) | | | | | |

The compositions (including each of Compositions 1A-1C) of the present invention may be used for a variety of applications including but not limited to: (1) refrigerants for use in a variety of heat transfer applications (including in thermal management systems and methods); (2) aerosol propellants; (3) blowing agents; (4) gaseous dielectrics; (5) fire suppression agents; (6) solvents; (7) cleaning agents; (8) power cycle working fluids; (9) electrolytes; and (10) starting materials for producing other organofluorine compounds.

### II. Heat Transfer Applications

The present invention includes generally heating and/or cooling generally, and particularly and preferably of electronics both during the manufacture thereof and during operations. Furthermore, the heating and cooling steps include both direct heat transfer and indirect heat transfer. As used herein, the term “direct heat transfer” refers to contact between the refrigerant compositions of the present invention, including each of Refrigerants 1-7, and the electronic component, article or device being cooled and/or heated. In this context, direct contact is intended to include contact with either the electronic portion of the component itself and/or a substrate or other platform (and extended surfaces thereof) on which electronic components are mounted.

The preferred refrigerants of the present invention, including each of Refrigerants 1 through 7, are particularly and unexpectedly advantageous in heat transfer uses and methods, including especially uses and methods relating to cooling and heating of electronic components, articles and devices, and especially in preferred embodiments comprising heating and/or cooling electronic components, articles or devices which include one or more semiconductors and/or one or more batteries. These advantages stem in part from the preferred compositions, including particularly, each of Refrigerants 1 through 7, because of applicants' recognition that these refrigerants have advantageous properties for these applications, including relatively low vapor pressure, relatively high boiling point, relatively low dielectric constant and nonflammability.

For the purposes of convenience but not by way of limitation, preferred heat transfer applications in which involve manufacture of the electronic component, article or device and heat transfer applications involving heating and/or cooling while the electronic component, article or device are operating are discussed under separate headings below, it being understood however that the disclosure of a particular embodiment below with respect to heating and/or cooling during manufacture will frequently have application to some extent also in connection with heating and/or cooling of electronic devices during operations, and visa vera. Accordingly, therefore, reference herein to thermal management systems (TMSs) and thermal management methods (TMMs) is understood to represent systems, methods and uses consistent with all types of heating and/or cooling of electronic components, articles or devices.

### II.A. Thermal Management Systems, Methods and Uses

The present invention encompasses various methods, processes and uses of the compounds and compositions of the present invention, including refrigerants of the present invention, including each of Refrigerants 1-7, in TMSs and TMMs used to maintain or help maintain a component, article or device (preferably an electronic component, article or device (including batteries) or fluid within a certain temperature range, particularly as that component, article or device or fluid is operating according to its intended purpose and/or during the manufacture of the component, device or article, particularly during the manufacture an electronic device or component (such as a semiconductor wafer or integrated circuit chip etching). For example, the refrigerants of the present invention, including each of Refrigerants 1-7, may be used to keep the temperature of a component below a defined upper and/or above a defined lower temperature, including during the processing/manufacture thereof and/or during the operation thereof for its intended purpose.

The invention includes refrigerants of the present invention, including each of Refrigerants 1-Refrigerants 8, in which the refrigerant is non-flammable.

The invention includes refrigerants of the present invention, including each of Refrigerants 1-Refrigerants 8, in which the refrigerant has a dielectric constant less than 3 at 20 GHz.

The invention includes refrigerants of the present invention, including each of Refrigerants 1-Refrigerants 8, in which the refrigerant has a dielectric constant less than 2.5 at 20 GHz.

The invention includes refrigerants of the present invention, including each of Refrigerants 1-Refrigerants 8, in which the refrigerant has a dielectric constant less than 3 at 20 GHz; (ii) has a boiling point of from about 250C to about 600C; (iii) is non-flammable; and (iv) has an Ames-negative toxicity.

The invention includes refrigerants of the present invention, including Refrigerants 1-Refrigerants 8, in which the refrigerant has a boiling point of from about 25° C. to about 600C.

The refrigerants of the present invention, including each of Refrigerants 1-Refrigerants 8, may also be used with co-TMFs which may be hexafluoroisopropylethylether, hexafluoroisopropylmethylthioether, HFE-7000, HFE-7200, HFE-7100, HFE-7300, HFE-7500, trans-1,2-dichloroethylene, n-pentane, cyclopentane, ethanol, perfluoro(2-methyl-3-pentanone) (Novec 1230), cis-HFO-1336mzz, trans-HFO-1336mzz, HFO-1234yf, HFO-1234ze(E), HFO-1233zd(E) or HFO-1233zd(Z).

Table 2 below defines some preferred refrigerants which are blends comprising HFO-1438ezy(E) and at least one co-refrigerant. The first column of the table below identifies and defines the Refrigerant Blend by number as RB1, RB2, etc., and in that column the abbreviations COMP, CEO and CO are used to identify the nature of blend components identified in columns 2 and 3. In particular, the designation COMP in column 1 indicates that the refrigerant comprises HFO-1438ezy(E) and the indicated co-refrigerant. The designation CEO in column 1 means that the refrigerant consists essentially of HFO-1438ezy(E) and the designated co-refrigerant, and the designation CO in column 1 means that the refrigerant consists of HFO-1438ezy(E) and the designated co-refrigerant. The second column indicates the amount in weight percent Compound 2 required to be present in the blend. In the third column, the co-refrigerant is identified, and if a specific amount of the co-refrigerant in the blend is required, that is indicated as well.

TABLE 4

| | wt % HFO- | |
|---|---|---|
| No. | 1438ez(E) | Co-refrigerant |
| RB1A - COMP | 0.1%-99.9% | hexafluoroisopropylethylether |
| RB1B - COMP | =>10% | hexafluoroisopropylethylether |
| RB1C - COMP | =>25% | hexafluoroisopropylethylether |
| RB1D1 - COMP | =>50% | hexafluoroisopropylethylether |
| RB1D2 - COMP | =>50% | =<50% |
| | | hexafluoroisopropylethylether |
| RB1E - COMP | =>75% | hexafluoroisopropylethylether |
| RB1F - COMP | =>90% | hexafluoroisopropylethylether |
| RB1G - CEO | =>95% | hexafluoroisopropylethylether |
| RB1H - CO | =>95% | hexafluoroisopropylethylether |
| RB2A - COMP | 0.1%-99.9% | hexafluoroisopropylmethylthioether |
| RB2B - COMP | =>10% | hexafluoroisopropylmethylthioether |
| RB2C - COMP | =>25% | hexafluoroisopropylmethylthioether |
| RB2D1 - COMP | =>50% | hexafluoroisopropylmethylthioether |
| RB2D2 - COMP | =>50% | =<50% |
| | | hexafluoroisopropylmethylthioether |
| RB2E - COMP | =>75% | hexafluoroisopropylmethylthioether |
| RB2F - COMP | =>90% | hexafluoroisopropylmethylthioether |
| RB2G - CEO | =>95% | hexafluoroisopropylmethylthioether |
| RB2H - CO | =>95% | hexafluoroisopropylmethylthioether |
| RB3A - COMP | 0.1%-99.9% | HFE-7000 |
| RB3B - COMP | =>10% | HFE-7000 |
| RB3C - COMP | =>25% | HFE-7000 |
| RB3D1 - COMP | =>50% | HFE-7000 |
| RB3D2 - COMP | =>50% | =<50% HFE-7000 |
| RB3E - COMP | =>75% | HFE-7000 |
| RB3F - COMP | =>90% | HFE-7000 |
| RB3G - CEO | =>95% | HFE-7000 |
| RB3H - CO | =>95% | HFE-7000 |
| RB4A - COMP | 0.1%-99.9% | HFE-7100 |
| RB4B - COMP | =>10% | HFE-7100 |
| RB4C - COMP | =>25% | HFE-7100 |
| RB4D1 - COMP | =>50% | HFE-7100 |
| RB4D2 - COMP | =>50% | =<50% HFE-7100 |
| RB4E - COMP | =>75% | HFE-7100 |
| RB4F - COMP | =>90% | HFE-7100 |
| RB4G - CEO | =>95% | HFE-7100 |
| RB4H - CO | =>95% | HFE-7100 |
| RB5A - COMP | 0.1%-99.9% | HFE-7200 |
| RB5B - COMP | =>10% | HFE-7200 |
| RB5C - COMP | =>25% | HFE-7200 |
| RB5D1 - COMP | =>50% | HFE-7200 |
| RB5D2 - COMP | =>50% | =<50% HFE-7200 |
| RB5E - COMP | =>75% | HFE-7200 |
| RB5F - COMP | =>90% | HFE-7200 |
| RB5G - CEO | =>95% | HFE-7200 |
| RB5H - CO | =>95% | HFE-7200 |
| RB6A - COMP | 0.1%-99.9% | HFE-7500 |
| RB6B - COMP | =>10% | HFE-7500 |
| RB6C - COMP | =>25% | HFE-7500 |
| RB6D1 - COMP | =>50% | HFE-7500 |
| RB6D2 - COMP | =>50% | =<50% HFE-7500 |
| RB6E - COMP | =>75% | HFE-7500 |
| RB6F - COMP | =>90% | HFE-7500 |
| RB6G - CEO | =>95% | HFE-7500 |
| RB6H - CO | =>95% | HFE-7500 |
| RB7A - COMP | 0.1%-99.9% | trans-1,2-dichloroethylene |
| RB7B - COMP | =>10% | trans-1,2-dichloroethylene |
| RB7C - COMP | =>25% | trans-1,2-dichloroethylene |
| RB7D1 - COMP | =>50% | trans-1,2-dichloroethylene |
| RB7D2 - COMP | =>50% | =<50% trans-1,2-dichloroethylene |
| RB7E - COMP | =>75% | trans-1,2-dichloroethylene |
| RB7F - COMP | =>90% | trans-1,2-dichloroethylene |
| RB7G - CEO | =>95% | trans-1,2-dichloroethylene |
| RB7H - CO | =>95% | trans-1,2-dichloroethylene |
| RB8A - COMP | 0.1%-99.9% | n-pentane |
| RB8B - COMP | =>10% | n-pentane |
| RB8C - COMP | =>25% | n-pentane |
| RB8D1 - COMP | =>50% | n-pentane |
| RB8D2 - COMP | =>50% | =<50% n-pentane |
| RB8E - COMP | =>75% | n-pentane |
| RB8F - COMP | =>90% | n-pentane |
| RB8G - CEO | =>95% | n-pentane |
| RB8H - CO | =>95% | n-pentane |
| RB9A - COMP | 0.1%-99.9% | cyclopentane |
| RB9B - COMP | =>10% | cyclopentane |
| RB9C - COMP | =>25% | cyclopentane |
| RB9D1 - COMP | =>50% | cyclopentane |
| RB9D2 - COMP | =>50% | =<50% cyclopentane |
| RB9E - COMP | =>75% | cyclopentane |
| RB9F - COMP | =>90% | cyclopentane |
| RB9G - CEO | =>95% | cyclopentane |
| RB9H - CO | =>95% | cyclopentane |
| RB10A - COMP | 0.1%-99.9% | ethanol |
| RB10B - COMP | =>10% | ethanol |
| RB10C - COMP | =>25% | ethanol |
| RB10D1 - COMP | =>50% | ethanol |
| RB10D2 - COMP | =>50% | =<50% ethanol |
| RB10E - COMP | =>75% | ethanol |
| RB10F - COMP | =>90% | ethanol |
| RB10G - CEO | =>95% | ethanol |
| RB10H - CO | =>95% | ethanol |
| RB11A - COMP | 0.1%-99.9% | perfluoro(2-methyl-3-pentanone) |
| RB11B - COMP | =>10% | perfluoro(2-methyl-3-pentanone) |
| RB11C - COMP | =>25% | perfluoro(2-methyl-3-pentanone) |
| RB11D1 - COMP | =>50% | perfluoro(2-methyl-3-pentanone) |
| RB11D2 - COMP | =>50% | =<50% perfluoro(2-methyl-3- |
| | | pentanone) |
| RB11E - COMP | =>75% | perfluoro(2-methyl-3-pentanone) |
| RB11F - COMP | =>90% | perfluoro(2-methyl-3-pentanone) |
| RB11G - CEO | =>95% | perfluoro(2-methyl-3-pentanone) |
| RB11H - CO | =>95% | perfluoro(2-methyl-3-pentanone) |
| RB12A - COMP | 0.1%-99.9% | HFO-1336mzz(Z) |
| RB12B - COMP | =>10% | HFO-1336mzz(Z) |
| RB12C - COMP | =>25% | HFO-1336mzz(Z) |
| RB12D1 - COMP | =>50% | HFO-1336mzz(Z) |
| RB12D2 - COMP | =>50% | =<50% HFO-1336mzz(Z) |
| RB12E - COMP | =>75% | HFO-1336mzz(Z) |
| RB12F - COMP | =>90% | HFO-1336mzz(Z) |
| RB12G - CEO | =>95% | HFO-1336mzz(Z) |
| RB12H - CO | =>95% | HFO-1336mzz(Z) |
| RB13A - COMP | 0.1%-99.9% | HFO-1336mzz(E) |
| RB13B - COMP | =>10% | HFO-1336mzz(E) |
| RB13C - COMP | =>25% | HFO-1336mzz(E) |
| RB13D1 - COMP | =>50% | HFO-1336mzz(E) |
| RB13D2 - COMP | =>50% | =<50% HFO-1336mzz(E) |
| RB13E - COMP | =>75% | HFO-1336mzz(E) |
| RB13F - COMP | =>90% | HFO-1336mzz(E) |
| RB13G - CEO | =>95% | HFO-1336mzz(E) |
| RB13H - CO | =>95% | HFO-1336mzz(E) |
| RB14A - COMP | 0.1%-99.9% | HFO-1234yf |
| RB14B - COMP | =>10% | HFO-1234yf |
| RB14C - COMP | =>25% | HFO-1234yf |
| RB14D1 - COMP | =>50% | HFO-1234yf |
| RB14D2 - COMP | =>50% | =<50% HFO-1234yf |
| RB14E - COMP | =>75% | HFO-1234yf |
| RB14F - COMP | =>90% | HFO-1234yf |
| RB14G - CEO | =>95% | HFO-1234yf |
| RB14H - CO | =>95% | HFO-1234yf |
| RB15A - COMP | 0.1%-99.9% | HFO-1234ze(E) |
| RB15B - COMP | =>10% | HFO-1234ze(E) |
| RB15C - COMP | =>25% | HFO-1234ze(E) |
| RB15D1 - COMP | =>50% | HFO-1234ze(E) |
| RB15D2 - COMP | =>50% | =<50% HFO-1234ze(E) |
| RB15E - COMP | =>75% | HFO-1234ze(E) |
| RB15F - COMP | =>90% | HFO-1234ze(E) |
| RB15G - CEO | =>95% | HFO-1234ze(E) |
| RB15H - CO | =>95% | HFO-1234ze(E) |
| RB16A - COMP | 0.1%-99.9% | HFO-1233zd(E) |
| RB16B - COMP | =>10% | HFO-1233zd(E) |
| RB16C - COMP | =>25% | HFO-1233zd(E) |
| RB16D1 - COMP | =>50% | HFO-1233zd(E) |
| RB16D2 - COMP | =>50% | =<50% HFO-1233zd(E) |
| RB16E - COMP | =>75% | HFO-1233zd(E) |
| RB16F - COMP | =>90% | HFO-1233zd(E) |
| RB16G - CEO | =>95% | HFO-1233zd(E) |
| RB16H - CO | =>95% | HFO-1233zd(E) |
| RB17A - COMP | 0.1%-99.9% | HFO-1233zd(Z) |
| RB17B - COMP | =>10% | HFO-1233zd(Z) |
| RB17C - COMP | =>25% | HFO-1233zd(Z) |
| RB17D1 - COMP | =>50% | HFO-1233zd(Z) |
| RB17D2 - COMP | =>50% | =<50% HFO-1233zd(Z) |
| RB17E - COMP | =>75% | HFO-1233zd(Z) |
| RB17F - COMP | =>90% | HFO-1233zd(Z) |
| RB17G - CEO | =>95% | HFO-1233zd(Z) |
| RB17H - CO | =>95% | HFO-1233zd(Z) |
| RB18A - COMP | 0.1%-99.9% | HFCO-1224yd |
| RB18B - COMP | =>10% | HFCO-1224yd |
| RB18C - COMP | =>25% | HFCO-1224yd |
| RB18D1 - COMP | =>50% | HFCO-1224yd |
| RB18D2 - COMP | =>50% | =<50% HFCO-1224yd |
| RB18E - COMP | =>75% | HFCO-1224yd |
| RB18F - COMP | =>90% | HFCO-1224yd |
| RB18G - CEO | =>95% | HFCO-1224yd |
| RB18H - CO | =>95% | HFCO-1224yd |
| RB19A - COMP | 0.1%-99.9% | HFO-1132(E) |
| RB19B - COMP | =>10% | HFO-1132(E) |
| RB19C - COMP | =>25% | HFO-1132(E) |
| RB19D1 - COMP | =>50% | HFO-1132(E) |
| RB19D2 - COMP | =>50% | =<50% HFO-1132(E) |
| RB19E - COMP | =>75% | HFO-1132(E) |
| RB19F - COMP | =>90% | HFO-1132(E) |
| RB19G - CEO | =>95% | HFO-1132(E) |
| RB19H - CO | =>95% | HFO-1132(E) |
| RB20A - COMP | 0.1%-99.9% | HFE-7300 |
| RB20B - COMP | =>10% | HFE-7300 |
| RB20C - COMP | =>25% | HFE-7300 |
| RB20D1 - COMP | =>50% | HFE-7300 |
| RB20D2 - COMP | =>50% | =<50% HFE-7300 |
| RB20E - COMP | =>75% | HFE-7300 |
| RB20F - COMP | =>90% | HFE-7300 |
| RB20G - CEO | =>95% | HFE-7300 |
| RB20H - CO | =>95% | HFE-7300 |

The present disclosure includes refrigerant blends of the present invention, including each of RB1-RB20, in which the refrigerant is non-flammable.

The invention includes refrigerant blends of the present invention, including each of RB1-RB20, in which the refrigerant has a dielectric constant less than about 5 at 20 GHz.

The invention includes refrigerant blends of the present invention, including each of RB1-RB20, in which the refrigerant has a dielectric constant less than about 4 at 20 GHz.

The invention includes refrigerant blends of the present invention, including each of RB1-RB20, in which the refrigerant has a dielectric constant less than about 3 at 20 GHz.

The invention includes refrigerant blends of the present invention, including each of RB1-RB20, in which the refrigerant has a dielectric constant less than about 2.5 at 20 GHz.

The invention includes refrigerant blends of the present invention, including each of RB1-RB20, in which the refrigerant has a dielectric constant less than about 4 at 20 GHz; (ii) has a boiling point of from about 250C to about 600C; (iii) is non-flammable; and (iv) has an Ames-negative toxicity.

The invention includes refrigerant blends of the present invention, including each of RB1-RB20, in which the refrigerant has a boiling point of from about 25° C. to about 600C.

Refrigerant blends of the present disclosure, including each of RB1-RB20, will be hereinafter referred to as Blends RB1-RB20 or as RB1-RB10.

Table 3 below defines some preferred uses of the present refrigerants and methods of using the present refrigerants. The first column of Table 3 below identifies and defines the use as Use1, Use2, etc., and in column 2 one or more of the refrigerants as identified above as Refrigerants 1-8 using the abbreviations Ref. 1, Ref. 2, etc an. The designation “NR” is understood to mean that the component or property is not required (but may be present) by the use defined in each particular row of the table.

TABLE 3

| | | | | | Operating |
|---|---|---|---|---|---|
| | | | | Specific Device | Temperature Range |
| | | | Heat | or article being | of Refrigerant |
| | | | Transfer | manufactured | During Manufacturing |
| Use No. | Refrigerant | Type of Use | Type | and/or operated | Process or Operation, ° C. |
| Use1A | 1 | Thermal | single | NR | NR |
| | | Management - | phase | | |
| | | Electronics | | | |
| | | Manufacture | | | |
| Use1B | 1 | Thermal | single | NR | −60° C. |
| | | Management - | phase | | to +125° C. |
| | | Electronics | | | |
| | | Manufacture | | | |
| Use1C | 1 | Thermal | phase | NR | NR |
| | | Management - | change | | |
| | | Electronics | | | |
| | | Manufacture | | | |
| Use1D | 1 | Thermal | phase | NR | −60° C. |
| | | Management - | change | | to +125° C. |
| | | Electronics | | | |
| | | Manufacture | | | |
| Use1E | 1 | Thermal | sensible | NR | NR |
| | | Management - | heat and | | |
| | | Electronics | phase | | |
| | | Manufacture | change | | |
| Use1F | 1 | Thermal | sensible | NR | −60° C. |
| | | Management - | heat and | | to +125° C. |
| | | Electronics | phase | | |
| | | Manufacture | change | | |
| Use1G | 1 | Thermal | single | NR | NR |
| | | Management - | phase | | |
| | | Semiconductor | | | |
| | | Wafer | | | |
| | | Manufacture | | | |
| Use1H | 1 | Thermal | single | NR | −60° C. |
| | | Management - | phase | | to +125° C. |
| | | Semiconductor | | | |
| | | Wafer | | | |
| | | Manufacture | | | |
| Use1I | 1 | Thermal | phase | NR | NR |
| | | Management - | change | | |
| | | Semiconductor | | | |
| | | Wafer | | | |
| | | Manufacture | | | |
| Use1J | 1 | Thermal | phase | NR | −60° C. |
| | | Management - | change | | to +125° C. |
| | | Semiconductor | | | |
| | | Wafer | | | |
| | | Manufacture | | | |
| Use1K | 1 | Thermal | sensible | NR | NR |
| | | Management - | heat and | | |
| | | Semiconductor | phase | | |
| | | Wafer | change | | |
| | | Manufacture | | | |
| Use1L | 1 | Thermal | sensible | NR | −60° C. |
| | | Management - | heat and | | to +125° C. |
| | | Semiconductor | phase | | |
| | | Wafer | change | | |
| | | Manufacture | | | |
| Use1M | 1 | Thermal | single | NR | NR |
| | | Management - | phase | | |
| | | IC Chip | | | |
| | | Manufacture | | | |
| Use1N | 1 | Thermal | single | NR | −60° C. |
| | | Management - | phase | | to +125° C. |
| | | IC Chip | | | |
| | | Manufacture | | | |
| Use1O | 1 | Thermal | phase | NR | NR |
| | | Management - | change | | |
| | | IC Chip | | | |
| | | Manufacture | | | |
| Use1P | 1 | Thermal | phase | NR | −60° C. |
| | | Management - | change | | to +125° C. |
| | | IC Chip | | | |
| | | Manufacture | | | |
| Use1Q | 1 | Thermal | sensible | NR | NR |
| | | Management - | heat and | | |
| | | IC Chip | phase | | |
| | | Manufacture | change | | |
| Use1R | 1 | Thermal | sensible | NR | −60° C. |
| | | Management - | heat and | | to +125° C. |
| | | IC Chip | phase | | |
| | | Manufacture | change | | |
| Use2A | 2 | Thermal | single | NR | NR |
| | | Management - | phase | | |
| | | Electronics | | | |
| | | Manufacture | | | |
| Use2B | 2 | Thermal | single | NR | −60° C. |
| | | Management - | phase | | to +125° C. |
| | | Electronics | | | |
| | | Manufacture | | | |
| Use2C | 2 | Thermal | phase | NR | NR |
| | | Management - | change | | |
| | | Electronics | | | |
| | | Manufacture | | | |
| Use2D | 2 | Thermal | phase | NR | −60° C. |
| | | Management - | change | | to +125° C. |
| | | Electronics | | | |
| | | Manufacture | | | |
| Use2E | 2 | Thermal | sensible | NR | NR |
| | | Management - | heat and | | |
| | | Electronics | phase | | |
| | | Manufacture | change | | |
| Use2F | 2 | Thermal | sensible | NR | −60° C. |
| | | Management - | heat and | | to +125° C. |
| | | Electronics | phase | | |
| | | Manufacture | change | | |
| Use2G | 2 | Thermal | single | NR | NR |
| | | Management - | phase | | |
| | | Semiconductor | | | |
| | | Wafer | | | |
| | | Manufacture | | | |
| Use2H | 2 | Thermal | single | NR | −60° C. |
| | | Management - | phase | | to +125° C. |
| | | Semiconductor | | | |
| | | Wafer | | | |
| | | Manufacture | | | |
| Use2I | 2 | Thermal | phase | NR | NR |
| | | Management - | change | | |
| | | Semiconductor | | | |
| | | Wafer | | | |
| | | Manufacture | | | |
| Use2J | 2 | Thermal | phase | NR | −60° C. |
| | | Management - | change | | to +125° C. |
| | | Semiconductor | | | |
| | | Wafer | | | |
| | | Manufacture | | | |
| Use2K | 2 | Thermal | sensible | NR | NR |
| | | Management - | heat and | | |
| | | Semiconductor | phase | | |
| | | Wafer | change | | |
| | | Manufacture | | | |
| Use2L | 2 | Thermal | sensible | NR | −60° C. |
| | | Management - | heat and | | to +125° C. |
| | | Semiconductor | phase | | |
| | | Wafer | change | | |
| | | Manufacture | | | |
| Use2M | 2 | Thermal | single | NR | NR |
| | | Management - | phase | | |
| | | IC Chip | | | |
| | | Manufacture | | | |
| Use2N | 2 | Thermal | single | NR | −60° C. |
| | | Management - | phase | | to +125° C. |
| | | IC Chip | | | |
| | | Manufacture | | | |
| Use2O | 2 | Thermal | phase | NR | NR |
| | | Management - | change | | |
| | | IC Chip | | | |
| | | Manufacture | | | |
| Use2P | 2 | Thermal | phase | NR | −60° C. |
| | | Management - | change | | to +125° C. |
| | | IC Chip | | | |
| | | Manufacture | | | |
| Use2Q | 2 | Thermal | sensible | NR | NR |
| | | Management - | heat and | | |
| | | IC Chip | phase | | |
| | | Manufacture | change | | |
| Use2R | 2 | Thermal | sensible | NR | −60° C. |
| | | Management - | heat and | | to +125° C. |
| | | IC Chip | phase | | |
| | | Manufacture | change | | |
| Use3A | 3 | Thermal | single | NR | NR |
| | | Management - | phase | | |
| | | Electronics | | | |
| | | Manufacture | | | |
| Use3B | 3 | Thermal | single | NR | −60° C. |
| | | Management - | phase | | to +125° C. |
| | | Electronics | | | |
| | | Manufacture | | | |
| Use3C | 3 | Thermal | phase | NR | NR |
| | | Management - | change | | |
| | | Electronics | | | |
| | | Manufacture | | | |
| Use3D | 3 | Thermal | phase | NR | −60° C. |
| | | Management - | change | | to +125° C. |
| | | Electronics | | | |
| | | Manufacture | | | |
| Use3E | 3 | Thermal | sensible | NR | NR |
| | | Management - | heat and | | |
| | | Electronics | phase | | |
| | | Manufacture | change | | |
| Use3F | 3 | Thermal | sensible | NR | −60° C. |
| | | Management - | heat and | | to +125° C. |
| | | Electronics | phase | | |
| | | Manufacture | change | | |
| Use3G | 3 | Thermal | single | NR | NR |
| | | Management - | phase | | |
| | | Semiconductor | | | |
| | | Wafer | | | |
| | | Manufacture | | | |
| Use3H | 3 | Thermal | single | NR | −60° C. |
| | | Management - | phase | | to +125° C. |
| | | Semiconductor | | | |
| | | Wafer | | | |
| | | Manufacture | | | |
| Use3I | 3 | Thermal | phase | NR | NR |
| | | Management - | change | | |
| | | Semiconductor | | | |
| | | Wafer | | | |
| | | Manufacture | | | |
| Use3J | 3 | Thermal | phase | NR | −60° C. |
| | | Management - | change | | to +125° C. |
| | | Semiconductor | | | |
| | | Wafer | | | |
| | | Manufacture | | | |
| Use3K | 3 | Thermal | sensible | NR | NR |
| | | Management - | heat and | | |
| | | Semiconductor | phase | | |
| | | Wafer | change | | |
| | | Manufacture | | | |
| Use3L | 3 | Thermal | sensible | NR | −60° C. |
| | | Management - | heat and | | to +125° C. |
| | | Semiconductor | phase | | |
| | | Wafer | change | | |
| | | Manufacture | | | |
| Use3M | 3 | Thermal | single | NR | NR |
| | | Management - | phase | | |
| | | IC Chip | | | |
| | | Manufacture | | | |
| Use3N | 3 | Thermal | single | NR | −60° C. |
| | | Management - | phase | | to +125° C. |
| | | IC Chip | | | |
| | | Manufacture | | | |
| Use3O | 3 | Thermal | phase | NR | NR |
| | | Management - | change | | |
| | | IC Chip | | | |
| | | Manufacture | | | |
| Use3P | 3 | Thermal | phase | NR | −60° C. |
| | | Management - | change | | to +125° C. |
| | | IC Chip | | | |
| | | Manufacture | | | |
| Use3Q | 3 | Thermal | sensible | NR | NR |
| | | Management - | heat and | | |
| | | IC Chip | phase | | |
| | | Manufacture | change | | |
| Use3R | 3 | Thermal | sensible | NR | −60° C. |
| | | Management - | heat and | | to +125° C. |
| | | IC Chip | phase | | |
| | | Manufacture | change | | |
| Use4A | 4 | Thermal | single | NR | NR |
| | | Management - | phase | | |
| | | Electronics | | | |
| | | Manufacture | | | |
| Use4B | 4 | Thermal | single | NR | −60° C. |
| | | Management - | phase | | to +125° C. |
| | | Electronics | | | |
| | | Manufacture | | | |
| Use4C | 4 | Thermal | phase | NR | NR |
| | | Management - | change | | |
| | | Electronics | | | |
| | | Manufacture | | | |
| Use4D | 4 | Thermal | phase | NR | −60° C. |
| | | Management - | change | | to +125° C. |
| | | Electronics | | | |
| | | Manufacture | | | |
| Use4E | 4 | Thermal | sensible | NR | NR |
| | | Management - | heat and | | |
| | | Electronics | phase | | |
| | | Manufacture | change | | |
| Use4F | 4 | Thermal | sensible | NR | −60° C. |
| | | Management - | heat and | | to +125° C. |
| | | Electronics | phase | | |
| | | Manufacture | change | | |
| Use4G | 4 | Thermal | single | NR | NR |
| | | Management - | phase | | |
| | | Semiconductor | | | |
| | | Wafer | | | |
| | | Manufacture | | | |
| Use4H | 4 | Thermal | single | NR | −60° C. |
| | | Management - | phase | | to +125° C. |
| | | Semiconductor | | | |
| | | Wafer | | | |
| | | Manufacture | | | |
| Use4I | 4 | Thermal | phase | NR | NR |
| | | Management - | change | | |
| | | Semiconductor | | | |
| | | Wafer | | | |
| | | Manufacture | | | |
| Use4J | 4 | Thermal | phase | NR | −60° C. |
| | | Management - | change | | to +125° C. |
| | | Semiconductor | | | |
| | | Wafer | | | |
| | | Manufacture | | | |
| Use4K | 4 | Thermal | sensible | NR | NR |
| | | Management - | heat and | | |
| | | Semiconductor | phase | | |
| | | Wafer | change | | |
| | | Manufacture | | | |
| Use4L | 4 | Thermal | sensible | NR | −60° C. |
| | | Management - | heat and | | to +125° C. |
| | | Semiconductor | phase | | |
| | | Wafer | change | | |
| | | Manufacture | | | |
| Use4M | 4 | Thermal | single | NR | NR |
| | | Management - | phase | | |
| | | IC Chip | | | |
| | | Manufacture | | | |
| Use4N | 4 | Thermal | single | NR | −60° C. |
| | | Management - | phase | | to +125° C. |
| | | IC Chip | | | |
| | | Manufacture | | | |
| Use4O | 4 | Thermal | phase | NR | NR |
| | | Management - | change | | |
| | | IC Chip | | | |
| | | Manufacture | | | |
| Use4P | 4 | Thermal | phase | NR | −60° C. |
| | | Management - | change | | to +125° C. |
| | | IC Chip | | | |
| | | Manufacture | | | |
| Use4Q | 4 | Thermal | sensible | NR | NR |
| | | Management - | heat and | | |
| | | IC Chip | phase | | |
| | | Manufacture | change | | |
| Use4R | 4 | Thermal | sensible | NR | −60° C. |
| | | Management - | heat and | | to +125° C. |
| | | IC Chip | phase | | |
| | | Manufacture | change | | |
| Use5A | 5 | Thermal | single | NR | NR |
| | | Management - | phase | | |
| | | Electronics | | | |
| | | Manufacture | | | |
| Use5B | 5 | Thermal | single | NR | −60° C. |
| | | Management - | phase | | to +125° C. |
| | | Electronics | | | |
| | | Manufacture | | | |
| Use5C | 5 | Thermal | phase | NR | NR |
| | | Management - | change | | |
| | | Electronics | | | |
| | | Manufacture | | | |
| Use5D | 5 | Thermal | phase | NR | −60° C. |
| | | Management - | change | | to +125° C. |
| | | Electronics | | | |
| | | Manufacture | | | |
| Use5E | 5 | Thermal | sensible | NR | NR |
| | | Management - | heat and | | |
| | | Electronics | phase | | |
| | | Manufacture | change | | |
| Use5F | 5 | Thermal | sensible | NR | −60° C. |
| | | Management - | heat and | | to +125° C. |
| | | Electronics | phase | | |
| | | Manufacture | change | | |
| Use5G | 5 | Thermal | single | NR | NR |
| | | Management - | phase | | |
| | | Semiconductor | | | |
| | | Wafer | | | |
| | | Manufacture | | | |
| Use5H | 5 | Thermal | single | NR | −60° C. |
| | | Management - | phase | | to +125° C. |
| | | Semiconductor | | | |
| | | Wafer | | | |
| | | Manufacture | | | |
| Use5I | 5 | Thermal | phase | NR | NR |
| | | Management - | change | | |
| | | Semiconductor | | | |
| | | Wafer | | | |
| | | Manufacture | | | |
| Use5J | 5 | Thermal | phase | NR | −60° C. |
| | | Management - | change | | to +125° C. |
| | | Semiconductor | | | |
| | | Wafer | | | |
| | | Manufacture | | | |
| Use5K | 5 | Thermal | sensible | NR | NR |
| | | Management - | heat and | | |
| | | Semiconductor | phase | | |
| | | Wafer | change | | |
| | | Manufacture | | | |
| Use5L | 5 | Thermal | sensible | NR | −60° C. |
| | | Management - | heat and | | to +125° C. |
| | | Semiconductor | phase | | |
| | | Wafer | change | | |
| | | Manufacture | | | |
| Use5M | 5 | Thermal | single | NR | NR |
| | | Management - | phase | | |
| | | IC Chip | | | |
| | | Manufacture | | | |
| Use5N | 5 | Thermal | single | NR | −60° C. |
| | | Management - | phase | | to +125° C. |
| | | IC Chip | | | |
| | | Manufacture | | | |
| Use5O | 5 | Thermal | phase | NR | NR |
| | | Management - | change | | |
| | | IC Chip | | | |
| | | Manufacture | | | |
| Use5P | 5 | Thermal | phase | NR | −60° C. |
| | | Management - | change | | to +125° C. |
| | | IC Chip | | | |
| | | Manufacture | | | |
| Use5Q | 5 | Thermal | sensible | NR | NR |
| | | Management - | heat and | | |
| | | IC Chip | phase | | |
| | | Manufacture | change | | |
| Use5R | 5 | Thermal | sensible | NR | −60° C. |
| | | Management - | heat and | | to +125° C. |
| | | IC Chip | phase | | |
| | | Manufacture | change | | |
| Use6A | 6 | Thermal | single | NR | NR |
| | | Management - | phase | | |
| | | Electronics | | | |
| | | Manufacture | | | |
| Use6B | 6 | Thermal | single | NR | −60° C. |
| | | Management - | phase | | to +125° C. |
| | | Electronics | | | |
| | | Manufacture | | | |
| Use6C | 6 | Thermal | phase | NR | NR |
| | | Management - | change | | |
| | | Electronics | | | |
| | | Manufacture | | | |
| Use6D | 6 | Thermal | phase | NR | −60° C. |
| | | Management - | change | | to +125° C. |
| | | Electronics | | | |
| | | Manufacture | | | |
| Use6E | 6 | Thermal | sensible | NR | NR |
| | | Management - | heat and | | |
| | | Electronics | phase | | |
| | | Manufacture | change | | |
| Use6F | 6 | Thermal | sensible | NR | −60° C. |
| | | Management - | heat and | | to +125° C. |
| | | Electronics | phase | | |
| | | Manufacture | change | | |
| Use6G | 6 | Thermal | single | NR | NR |
| | | Management - | phase | | |
| | | Semiconductor | | | |
| | | Wafer | | | |
| | | Manufacture | | | |
| Use6H | 6 | Thermal | single | NR | −60° C. |
| | | Management - | phase | | to +125° C. |
| | | Semiconductor | | | |
| | | Wafer | | | |
| | | Manufacture | | | |
| Use6I | 6 | Thermal | phase | NR | NR |
| | | Management - | change | | |
| | | Semiconductor | | | |
| | | Wafer | | | |
| | | Manufacture | | | |
| Use6J | 6 | Thermal | phase | NR | −60° C. |
| | | Management - | change | | to +125° C. |
| | | Semiconductor | | | |
| | | Wafer | | | |
| | | Manufacture | | | |
| Use6K | 6 | Thermal | sensible | NR | NR |
| | | Management - | heat and | | |
| | | Semiconductor | phase | | |
| | | Wafer | change | | |
| | | Manufacture | | | |
| Use6L | 6 | Thermal | sensible | NR | −60° C. |
| | | Management - | heat and | | to +125° C. |
| | | Semiconductor | phase | | |
| | | Wafer | change | | |
| | | Manufacture | | | |
| Use6M | 6 | Thermal | single | NR | NR |
| | | Management - | phase | | |
| | | IC Chip | | | |
| | | Manufacture | | | |
| Use6N | 6 | Thermal | single | NR | −60° C. |
| | | Management - | phase | | to +125° C. |
| | | IC Chip | | | |
| | | Manufacture | | | |
| Use6O | 6 | Thermal | phase | NR | NR |
| | | Management - | change | | |
| | | IC Chip | | | |
| | | Manufacture | | | |
| Use6P | 6 | Thermal | phase | NR | −60° C. |
| | | Management - | change | | to +125° C. |
| | | IC Chip | | | |
| | | Manufacture | | | |
| Use6Q | 6 | Thermal | sensible | NR | NR |
| | | Management - | heat and | | |
| | | IC Chip | phase | | |
| | | Manufacture | change | | |
| Use6R | 6 | Thermal | sensible | NR | −60° C. |
| | | Management - | heat and | | to +125° C. |
| | | IC Chip | phase | | |
| | | Manufacture | change | | |
| Use7A | 7 | Thermal | single | NR | NR |
| | | Management - | phase | | |
| | | Electronics | | | |
| | | Manufacture | | | |
| Use7B | 7 | Thermal | single | NR | −60° C. |
| | | Management - | phase | | to +125° C. |
| | | Electronics | | | |
| | | Manufacture | | | |
| Use7C | 7 | Thermal | phase | NR | NR |
| | | Management - | change | | |
| | | Electronics | | | |
| | | Manufacture | | | |
| Use7D | 7 | Thermal | phase | NR | −60° C. |
| | | Management - | change | | to +125° C. |
| | | Electronics | | | |
| | | Manufacture | | | |
| Use7E | 7 | Thermal | sensible | NR | NR |
| | | Management - | heat and | | |
| | | Electronics | phase | | |
| | | Manufacture | change | | |
| Use7F | 7 | Thermal | sensible | NR | −60° C. |
| | | Management - | heat and | | to +125° C. |
| | | Electronics | phase | | |
| | | Manufacture | change | | |
| Use7G | 7 | Thermal | single | NR | NR |
| | | Management - | phase | | |
| | | Semiconductor | | | |
| | | Wafer | | | |
| | | Manufacture | | | |
| Use7H | 7 | Thermal | single | NR | −60° C. |
| | | Management - | phase | | to +125° C. |
| | | Semiconductor | | | |
| | | Wafer | | | |
| | | Manufacture | | | |
| Use7I | 7 | Thermal | phase | NR | NR |
| | | Management - | change | | |
| | | Semiconductor | | | |
| | | Wafer | | | |
| | | Manufacture | | | |
| Use7J | 7 | Thermal | phase | NR | −60° C. |
| | | Management - | change | | to +125° C. |
| | | Semiconductor | | | |
| | | Wafer | | | |
| | | Manufacture | | | |
| Use7K | 7 | Thermal | sensible | NR | NR |
| | | Management - | heat and | | |
| | | Semiconductor | phase | | |
| | | Wafer | change | | |
| | | Manufacture | | | |
| Use7L | 7 | Thermal | sensible | NR | −60° C. |
| | | Management - | heat and | | to +125° C. |
| | | Semiconductor | phase | | |
| | | Wafer | change | | |
| | | Manufacture | | | |
| Use7M | 7 | Thermal | single | NR | NR |
| | | Management - | phase | | |
| | | IC Chip | | | |
| | | Manufacture | | | |
| Use7N | 7 | Thermal | single | NR | −60° C. |
| | | Management - | phase | | to +125° C. |
| | | IC Chip | | | |
| | | Manufacture | | | |
| Use7O | 7 | Thermal | phase | NR | NR |
| | | Management - | change | | |
| | | IC Chip | | | |
| | | Manufacture | | | |
| Use7P | 7 | Thermal | phase | NR | −60° C. |
| | | Management - | change | | to +125° C. |
| | | IC Chip | | | |
| | | Manufacture | | | |
| Use7Q | 7 | Thermal | sensible | NR | NR |
| | | Management - | heat and | | |
| | | IC Chip | phase | | |
| | | Manufacture | change | | |
| Use7R | 7 | Thermal | sensible | NR | −60° C. |
| | | Management - | heat and | | to +125° C. |
| | | IC Chip | phase | | |
| | | Manufacture | change | | |
| Use8A | 8 | Thermal | single | NR | NR |
| | | Management - | phase | | |
| | | Electronics | | | |
| | | Manufacture | | | |
| Use8B | 8 | Thermal | single | NR | −60° C. |
| | | Management - | phase | | to +125° C. |
| | | Electronics | | | |
| | | Manufacture | | | |
| Use8C | 8 | Thermal | phase | NR | NR |
| | | Management - | change | | |
| | | Electronics | | | |
| | | Manufacture | | | |
| Use8D | 8 | Thermal | phase | NR | −60° C. |
| | | Management - | change | | to +125° C. |
| | | Electronics | | | |
| | | Manufacture | | | |
| Use8E | 8 | Thermal | sensible | NR | NR |
| | | Management - | heat and | | |
| | | Electronics | phase | | |
| | | Manufacture | change | | |
| Use8F | 8 | Thermal | sensible | NR | −60° C. |
| | | Management - | heat and | | to +125° C. |
| | | Electronics | phase | | |
| | | Manufacture | change | | |
| Use8G | 8 | Thermal | single | NR | NR |
| | | Management - | phase | | |
| | | Semiconductor | | | |
| | | Wafer | | | |
| | | Manufacture | | | |
| Use8H | 8 | Thermal | single | NR | −60° C. |
| | | Management - | phase | | to +125° C. |
| | | Semiconductor | | | |
| | | Wafer | | | |
| | | Manufacture | | | |
| Use8I | 8 | Thermal | phase | NR | NR |
| | | Management - | change | | |
| | | Semiconductor | | | |
| | | Wafer | | | |
| | | Manufacture | | | |
| Use8J | 8 | Thermal | phase | NR | −60° C. |
| | | Management - | change | | to +125° C. |
| | | Semiconductor | | | |
| | | Wafer | | | |
| | | Manufacture | | | |
| Use8K | 8 | Thermal | sensible | NR | NR |
| | | Management - | heat and | | |
| | | Semiconductor | phase | | |
| | | Wafer | change | | |
| | | Manufacture | | | |
| Use8L | 8 | Thermal | sensible | NR | −60° C. |
| | | Management - | heat and | | to +125° C. |
| | | Semiconductor | phase | | |
| | | Wafer | change | | |
| | | Manufacture | | | |
| Use8M | 8 | Thermal | single | NR | NR |
| | | Management - | phase | | |
| | | IC Chip | | | |
| | | Manufacture | | | |
| Use8N | 8 | Thermal | single | NR | −60° C. |
| | | Management - | phase | | to +125° C. |
| | | IC Chip | | | |
| | | Manufacture | | | |
| Use8O | 8 | Thermal | phase | NR | NR |
| | | Management - | change | | |
| | | IC Chip | | | |
| | | Manufacture | | | |
| Use8P | 8 | Thermal | phase | NR | −60° C. |
| | | Management - | change | | to +125° C. |
| | | IC Chip | | | |
| | | Manufacture | | | |
| Use8Q | 8 | Thermal | sensible | NR | NR |
| | | Management - | heat and | | |
| | | IC Chip | phase | | |
| | | Manufacture | change | | |
| Use8R | 8 | Thermal | sensible | NR | −60° C. |
| | | Management - | heat and | | to +125° C. |
| | | IC Chip | phase | | |
| | | Manufacture | change | | |
| Use9A1 | 1 | Thermal | single | Battery | NR |
| | | Management | phase | | |
| | | Immersion | | | |
| Use9A2 | 1 | Thermal | phase | Battery | NR |
| | | Management | change | | |
| | | Immersion | | | |
| Use9A3 | 1 | Thermal | single | Battery | NR |
| | | Management | phase and | | |
| | | Immersion | phase | | |
| | | | change | | |
| Use9B1 | 1 | Thermal | single | Battery | −40° C.-80° C. |
| | | Management | phase | | |
| | | Immersion | | | |
| Use9B2 | 1 | Thermal | phase | Battery | −40° C.-80° C. |
| | | Management | change | | |
| | | Immersion | | | |
| Use9B3 | 1 | Thermal | single | Battery | −40° C.-80° C. |
| | | Management | phase and | | |
| | | Immersion | phase | | |
| | | | change | | |
| Use9C1 | 1 | Thermal | single | EV Battery | NR |
| | | Management | phase | | |
| | | Immersion | | | |
| Use9C2 | 1 | Thermal | phase | EV Battery | NR |
| | | Management | change | | |
| | | Immersion | | | |
| Use9C3 | 1 | Thermal | single | EV Battery | NR |
| | | Management | phase and | | |
| | | Immersion | phase | | |
| | | | change | | |
| Use9D1 | 1 | Thermal | single | EV Battery | −40° C.-80° C. |
| | | Management | phase | | |
| | | Immersion | | | |
| Use9D2 | 1 | Thermal | phase | EV Battery | −40° C.-80° C. |
| | | Management | change | | |
| | | Immersion | | | |
| Use9D3 | 1 | Thermal | single | EV Battery | −40° C.-80° C. |
| | | Management | phase and | | |
| | | Immersion | phase | | |
| | | | change | | |
| Use9E1 | 1 | Thermal | single | Data Center | NR |
| | | Management | phase | Server | |
| | | Immersion | | | |
| Use9E2 | 1 | Thermal | phase | Data Center | NR |
| | | Management | change | Server | |
| | | Immersion | | | |
| Use9E3 | 1 | Thermal | single | Data Center | NR |
| | | Management | phase and | Server | |
| | | Immersion | phase | | |
| | | | change | | |
| Use9F1 | 1 | Thermal | single | Data Center | 30° C.-80° C. |
| | | Management | phase | Server | |
| | | Immersion | | | |
| Use9F2 | 1 | Thermal | phase | Data Center | 30° C.-80° C. |
| | | Management | change | Server | |
| | | Immersion | | | |
| Use9F3 | 1 | Thermal | single | Data Center | 30° C.-80° C. |
| | | Management | phase and | Server | |
| | | Immersion | phase | | |
| | | | change | | |
| Use9G1 | 1 | Thermal | single | ICs | NR |
| | | Management | phase | | |
| | | Immersion | | | |
| Use9G2 | 1 | Thermal | phase | ICs | NR |
| | | Management | change | | |
| | | Immersion | | | |
| Use9G3 | 1 | Thermal | single | ICs | NR |
| | | Management | phase and | | |
| | | Immersion | phase | | |
| | | | change | | |
| Use9H1 | 1 | Thermal | single | ICs | 30° C.-80° C. |
| | | Management | phase | | |
| | | Immersion | | | |
| Use9H2 | 1 | Thermal | phase | ICs | 30° C.-80° C. |
| | | Management | change | | |
| | | Immersion | | | |
| Use9H3 | 1 | Thermal | single | ICs | 30° C.-80° C. |
| | | Management | phase and | | |
| | | Immersion | phase | | |
| | | | change | | |
| Use10A1 | 2 | Thermal | single | Battery | NR |
| | | Management | phase | | |
| | | Immersion | | | |
| Use10A2 | 2 | Thermal | phase | Battery | NR |
| | | Management | change | | |
| | | Immersion | | | |
| Use10A3 | 2 | Thermal | single | Battery | NR |
| | | Management | phase and | | |
| | | Immersion | phase | | |
| | | | change | | |
| Use10B1 | 2 | Thermal | single | Battery | −40° C.-80° C. |
| | | Management | phase | | |
| | | Immersion | | | |
| Use10B2 | 2 | Thermal | phase | Battery | −40° C.-80° C. |
| | | Management | change | | |
| | | Immersion | | | |
| Use10B3 | 2 | Thermal | single | Battery | −40° C.-80° C. |
| | | Management | phase and | | |
| | | Immersion | phase | | |
| | | | change | | |
| Use10C1 | 2 | Thermal | single | EV Battery | NR |
| | | Management | phase | | |
| | | Immersion | | | |
| Use10C2 | 2 | Thermal | phase | EV Battery | NR |
| | | Management | change | | |
| | | Immersion | | | |
| Use10C3 | 2 | Thermal | single | EV Battery | NR |
| | | Management | phase and | | |
| | | Immersion | phase | | |
| | | | change | | |
| Use10D1 | 2 | Thermal | single | EV Battery | −40° C.-80° C. |
| | | Management | phase | | |
| | | Immersion | | | |
| Use10D2 | 2 | Thermal | phase | EV Battery | −40° C.-80° C. |
| | | Management | change | | |
| | | Immersion | | | |
| Use10D3 | 2 | Thermal | single | EV Battery | −40° C.-80° C. |
| | | Management | phase and | | |
| | | Immersion | phase | | |
| | | | change | | |
| Use102E1 | 2 | Thermal | single | Data Center | NR |
| | | Management | phase | Server | |
| | | Immersion | | | |
| Use10E2 | 2 | Thermal | phase | Data Center | NR |
| | | Management | change | Server | |
| | | Immersion | | | |
| Use10E3 | 2 | Thermal | single | Data Center | NR |
| | | Management | phase and | Server | |
| | | Immersion | phase | | |
| | | | change | | |
| Use10F1 | 2 | Thermal | single | Data Center | 30° C.-80° C. |
| | | Management | phase | Server | |
| | | Immersion | | | |
| Use10F2 | 2 | Thermal | phase | Data Center | 30° C.-80° C. |
| | | Management | change | Server | |
| | | Immersion | | | |
| Use10F3 | 2 | Thermal | single | Data Center | 30° C.-80° C. |
| | | Management | phase and | Server | |
| | | Immersion | phase | | |
| | | | change | | |
| Use10G1 | 2 | Thermal | single | ICs | NR |
| | | Management | phase | | |
| | | Immersion | | | |
| Use10G2 | 2 | Thermal | phase | ICs | NR |
| | | Management | change | | |
| | | Immersion | | | |
| Use10G3 | 2 | Thermal | single | ICs | NR |
| | | Management | phase and | | |
| | | Immersion | phase | | |
| | | | change | | |
| Use10H1 | 2 | Thermal | single | ICs | 30° C.-80° C. |
| | | Management | phase | | |
| | | Immersion | | | |
| Use10H2 | 2 | Thermal | phase | ICs | 30° C.-80° C. |
| | | Management | change | | |
| | | Immersion | | | |
| Use10H3 | 2 | Thermal | single | ICs | 30° C.-80° C. |
| | | Management | phase and | | |
| | | Immersion | phase | | |
| | | | change | | |
| Use11A1 | 3 | Thermal | single | Battery | NR |
| | | Management | phase | | |
| | | Immersion | | | |
| Use11A2 | 3 | Thermal | phase | Battery | NR |
| | | Management | change | | |
| | | Immersion | | | |
| Use113 | 3 | Thermal | single | Battery | NR |
| | | Management | phase and | | |
| | | Immersion | phase | | |
| | | | change | | |
| Use11B1 | 3 | Thermal | single | Battery | −40° C.-80° C. |
| | | Management | phase | | |
| | | Immersion | | | |
| Use11B2 | 3 | Thermal | phase | Battery | −40° C.-80° C. |
| | | Management | change | | |
| | | Immersion | | | |
| Use11B3 | 3 | Thermal | single | Battery | −40° C.-80° C. |
| | | Management | phase and | | |
| | | Immersion | phase | | |
| | | | change | | |
| Use11C1 | 3 | Thermal | single | EV Battery | NR |
| | | Management | phase | | |
| | | Immersion | | | |
| Use11C2 | 3 | Thermal | phase | EV Battery | NR |
| | | Management | change | | |
| | | Immersion | | | |
| Use11C3 | 3 | Thermal | single | EV Battery | NR |
| | | Management | phase and | | |
| | | Immersion | phase | | |
| | | | change | | |
| Use11D1 | 3 | Thermal | single | EV Battery | −40° C.-80° C. |
| | | Management | phase | | |
| | | Immersion | | | |
| Use11D2 | 3 | Thermal | phase | EV Battery | −40° C.-80° C. |
| | | Management | change | | |
| | | Immersion | | | |
| Use11D3 | 3 | Thermal | single | EV Battery | −40° C.-80° C. |
| | | Management | phase and | | |
| | | Immersion | phase | | |
| | | | change | | |
| Use11E1 | 3 | Thermal | single | Data Center | NR |
| | | Management | phase | Server | |
| | | Immersion | | | |
| Use11E2 | 3 | Thermal | phase | Data Center | NR |
| | | Management | change | Server | |
| | | Immersion | | | |
| Use11E3 | 3 | Thermal | single | Data Center | NR |
| | | Management | phase and | Server | |
| | | Immersion | phase | | |
| | | | change | | |
| Use11F1 | 3 | Thermal | single | Data Center | 30° C.-80° C. |
| | | Management | phase | Server | |
| | | Immersion | | | |
| Use11F2 | 3 | Thermal | phase | Data Center | 30° C.-80° C. |
| | | Management | change | Server | |
| | | Immersion | | | |
| Use11F3 | 3 | Thermal | single | Data Center | 30° C.-80° C. |
| | | Management | phase and | Server | |
| | | Immersion | phase | | |
| | | | change | | |
| Use11G1 | 3 | Thermal | single | ICs | NR |
| | | Management | phase | | |
| | | Immersion | | | |
| Use11G2 | 3 | Thermal | phase | ICs | NR |
| | | Management | change | | |
| | | Immersion | | | |
| Use11G3 | 3 | Thermal | single | ICs | NR |
| | | Management | phase and | | |
| | | Immersion | phase | | |
| | | | change | | |
| Use11H1 | 3 | Thermal | single | ICs | 30° C.-80° C. |
| | | Management | phase | | |
| | | Immersion | | | |
| Use11H2 | 3 | Thermal | phase | ICs | 30° C.-80° C. |
| | | Management | change | | |
| | | Immersion | | | |
| Use11H3 | 3 | Thermal | single | ICs | 30° C.-80° C. |
| | | Management | phase and | | |
| | | Immersion | phase | | |
| | | | change | | |
| Use11A1 | 4 | Thermal | single | Battery | NR |
| | | Management | phase | | |
| | | Immersion | | | |
| Use11A2 | 4 | Thermal | phase | Battery | NR |
| | | Management | change | | |
| | | Immersion | | | |
| Use11A3 | 4 | Thermal | single | Battery | NR |
| | | Management | phase and | | |
| | | Immersion | phase | | |
| | | | change | | |
| Use11B1 | 4 | Thermal | single | Battery | −40° C.-80° C. |
| | | Management | phase | | |
| | | Immersion | | | |
| Use11B2 | 4 | Thermal | phase | Battery | −40° C.-80° C. |
| | | Management | change | | |
| | | Immersion | | | |
| Use11B3 | 4 | Thermal | single | Battery | −40° C.-80° C. |
| | | Management | phase and | | |
| | | Immersion | phase | | |
| | | | change | | |
| Use11C1 | 4 | Thermal | single | EV Battery | NR |
| | | Management | phase | | |
| | | Immersion | | | |
| Use11C2 | 4 | Thermal | phase | EV Battery | NR |
| | | Management | change | | |
| | | Immersion | | | |
| Use11C3 | 4 | Thermal | single | EV Battery | NR |
| | | Management | phase and | | |
| | | Immersion | phase | | |
| | | | change | | |
| Use11D1 | 4 | Thermal | single | EV Battery | −40° C.-80° C. |
| | | Management | phase | | |
| | | Immersion | | | |
| Use11D2 | 4 | Thermal | phase | EV Battery | −40° C.-80° C. |
| | | Management | change | | |
| | | Immersion | | | |
| Use11D3 | 4 | Thermal | single | EV Battery | −40° C.-80° C. |
| | | Management | phase and | | |
| | | Immersion | phase | | |
| | | | change | | |
| Use11E1 | 4 | Thermal | single | Data Center | NR |
| | | Management | phase | Server | |
| | | Immersion | | | |
| Use11E2 | 4 | Thermal | phase | Data Center | NR |
| | | Management | change | Server | |
| | | Immersion | | | |
| Use11E3 | 4 | Thermal | single | Data Center | NR |
| | | Management | phase and | Server | |
| | | Immersion | phase | | |
| | | | change | | |
| Use11F1 | 4 | Thermal | single | Data Center | 30° C.-80° C. |
| | | Management | phase | Server | |
| | | Immersion | | | |
| Use11F2 | 4 | Thermal | phase | Data Center | 30° C.-80° C. |
| | | Management | change | Server | |
| | | Immersion | | | |
| Use11F3 | 4 | Thermal | single | Data Center | 30° C.-80° C. |
| | | Management | phase and | Server | |
| | | Immersion | phase | | |
| | | | change | | |
| Use11G1 | 4 | Thermal | single | ICs | NR |
| | | Management | phase | | |
| | | Immersion | | | |
| Use11G2 | 4 | Thermal | phase | ICs | NR |
| | | Management | change | | |
| | | Immersion | | | |
| Use11G3 | 4 | Thermal | single | ICS | NR |
| | | Management | phase and | | |
| | | Immersion | phase | | |
| | | | change | | |
| Use11H1 | 4 | Thermal | single | ICs | 30° C.-80° C. |
| | | Management | phase | | |
| | | Immersion | | | |
| Use11H2 | 4 | Thermal | phase | ICs | 30° C.-80° C. |
| | | Management | change | | |
| | | Immersion | | | |
| Use11H3 | 4 | Thermal | single | ICs | 30° C.-80° C. |
| | | Management | phase and | | |
| | | Immersion | phase | | |
| | | | change | | |
| Use12A1 | 5 | Thermal | single | Battery | NR |
| | | Management | phase | | |
| | | Immersion | | | |
| Use12A2 | 5 | Thermal | phase | Battery | NR |
| | | Management | change | | |
| | | Immersion | | | |
| Use123 | 5 | Thermal | single | Battery | NR |
| | | Management | phase and | | |
| | | Immersion | phase | | |
| | | | change | | |
| Use12B1 | 5 | Thermal | single | Battery | −40° C.-80° C. |
| | | Management | phase | | |
| | | Immersion | | | |
| Use12B2 | 5 | Thermal | phase | Battery | −40° C.-80° C. |
| | | Management | change | | |
| | | Immersion | | | |
| Use12B3 | 5 | Thermal | single | Battery | −40° C.-80° C. |
| | | Management | phase and | | |
| | | Immersion | phase | | |
| | | | change | | |
| Use12C1 | 5 | Thermal | single | EV Battery | NR |
| | | Management | phase | | |
| | | Immersion | | | |
| Use12C2 | 5 | Thermal | phase | EV Battery | NR |
| | | Management | change | | |
| | | Immersion | | | |
| Use12C3 | 5 | Thermal | single | EV Battery | NR |
| | | Management | phase and | | |
| | | Immersion | phase | | |
| | | | change | | |
| Use12D1 | 5 | Thermal | single | EV Battery | −40° C.-80° C. |
| | | Management | phase | | |
| | | Immersion | | | |
| Use12D2 | 5 | Thermal | phase | EV Battery | −40° C.-80° C. |
| | | Management | change | | |
| | | Immersion | | | |
| Use12D3 | 5 | Thermal | single | EV Battery | −40° C.-80° C. |
| | | Management | phase and | | |
| | | Immersion | phase | | |
| | | | change | | |
| Use12E1 | 5 | Thermal | single | Data Center | NR |
| | | Management | phase | Server | |
| | | Immersion | | | |
| Use12E2 | 5 | Thermal | phase | Data Center | NR |
| | | Management | change | Server | |
| | | Immersion | | | |
| Use12E3 | 5 | Thermal | single | Data Center | NR |
| | | Management | phase and | Server | |
| | | Immersion | phase | | |
| | | | change | | |
| Use12F1 | 5 | Thermal | single | Data Center | 30° C.-80° C. |
| | | Management | phase | Server | |
| | | Immersion | | | |
| Use12F2 | 5 | Thermal | phase | Data Center | 30° C.-80° C. |
| | | Management | change | Server | |
| | | Immersion | | | |
| Use12F3 | 5 | Thermal | single | Data Center | 30° C.-80° C. |
| | | Management | phase and | Server | |
| | | Immersion | phase | | |
| | | | change | | |
| Use12G1 | 5 | Thermal | single | ICs | NR |
| | | Management | phase | | |
| | | Immersion | | | |
| Use12G2 | 5 | Thermal | phase | ICs | NR |
| | | Management | change | | |
| | | Immersion | | | |
| Use12G3 | 5 | Thermal | single | ICs | NR |
| | | Management | phase and | | |
| | | Immersion | phase | | |
| | | | change | | |
| Use12H1 | 5 | Thermal | single | ICs | 30° C.-80° C. |
| | | Management | phase | | |
| | | Immersion | | | |
| Use12H2 | 5 | Thermal | phase | ICs | 30° C.-80° C. |
| | | Management | change | | |
| | | Immersion | | | |
| Use12H3 | 5 | Thermal | single | ICs | 30° C.-80° C. |
| | | Management | phase and | | |
| | | Immersion | phase | | |
| | | | change | | |
| Use13A1 | 6 | Thermal | single | Battery | NR |
| | | Management | phase | | |
| | | Immersion | | | |
| Use13A2 | 6 | Thermal | phase | Battery | NR |
| | | Management | change | | |
| | | Immersion | | | |
| Use13A3 | 6 | Thermal | single | Battery | NR |
| | | Management | phase and | | |
| | | Immersion | phase | | |
| | | | change | | |
| Use13B1 | 6 | Thermal | single | Battery | −40° C.-80° C. |
| | | Management | phase | | |
| | | Immersion | | | |
| Use13B2 | 6 | Thermal | phase | Battery | −40° C.-80° C. |
| | | Management | change | | |
| | | Immersion | | | |
| Use13B3 | 6 | Thermal | single | Battery | −40° C.-80° C. |
| | | Management | phase and | | |
| | | Immersion | phase | | |
| | | | change | | |
| Use13C1 | 6 | Thermal | single | EV Battery | NR |
| | | Management | phase | | |
| | | Immersion | | | |
| Use13C2 | 6 | Thermal | phase | EV Battery | NR |
| | | Management | change | | |
| | | Immersion | | | |
| Use13C3 | 6 | Thermal | single | EV Battery | NR |
| | | Management | phase and | | |
| | | Immersion | phase | | |
| | | | change | | |
| Use13D1 | 6 | Thermal | single | EV Battery | −40° C.-80° C. |
| | | Management | phase | | |
| | | Immersion | | | |
| Use13D2 | 6 | Thermal | phase | EV Battery | −40° C.-80° C. |
| | | Management | change | | |
| | | Immersion | | | |
| Use13D3 | 6 | Thermal | single | EV Battery | −40° C.-80° C. |
| | | Management | phase and | | |
| | | Immersion | phase | | |
| | | | change | | |
| Use13E1 | 6 | Thermal | single | Data Center | NR |
| | | Management | phase | Server | |
| | | Immersion | | | |
| Use13E2 | 6 | Thermal | phase | Data Center | NR |
| | | Management | change | Server | |
| | | Immersion | | | |
| Use13E3 | 6 | Thermal | single | Data Center | NR |
| | | Management | phase and | Server | |
| | | Immersion | phase | | |
| | | | change | | |
| Use13F1 | 6 | Thermal | single | Data Center | 30° C.-80° C. |
| | | Management | phase | Server | |
| | | Immersion | | | |
| Use13F2 | 6 | Thermal | phase | Data Center | 30° C.-80° C. |
| | | Management | change | Server | |
| | | Immersion | | | |
| Use13F3 | 6 | Thermal | single | Data Center | 30° C.-80° C. |
| | | Management | phase and | Server | |
| | | Immersion | phase | | |
| | | | change | | |
| Use13G1 | 6 | Thermal | single | ICs | NR |
| | | Management | phase | | |
| | | Immersion | | | |
| Use13G2 | 6 | Thermal | phase | ICs | NR |
| | | Management | change | | |
| | | Immersion | | | |
| Use13G3 | 6 | Thermal | single | ICs | NR |
| | | Management | phase and | | |
| | | Immersion | phase | | |
| | | | change | | |
| Use13H1 | 6 | Thermal | single | ICs | 30° C.-80° C. |
| | | Management | phase | | |
| | | Immersion | | | |
| Use13H2 | 6 | Thermal | phase | ICs | 30° C.-80° C. |
| | | Management | change | | |
| | | Immersion | | | |
| Use13H3 | 6 | Thermal | single | ICs | 30° C.-80° C. |
| | | Management | phase and | | |
| | | Immersion | phase | | |
| | | | change | | |
| Use14A1 | 7 | Thermal | single | Battery | NR |
| | | Management | phase | | |
| | | Immersion | | | |
| Use14A2 | 7 | Thermal | phase | Battery | NR |
| | | Management | change | | |
| | | Immersion | | | |
| Use14A3 | 7 | Thermal | single | Battery | NR |
| | | Management | phase and | | |
| | | Immersion | phase | | |
| | | | change | | |
| Use14B1 | 7 | Thermal | single | Battery | −40° C.-80° C. |
| | | Management | phase | | |
| | | Immersion | | | |
| Use14B2 | 7 | Thermal | phase | Battery | −40° C.-80° C. |
| | | Management | change | | |
| | | Immersion | | | |
| Use14B3 | 7 | Thermal | single | Battery | −40° C.-80° C. |
| | | Management | phase and | | |
| | | Immersion | phase | | |
| | | | change | | |
| Use14C1 | 7 | Thermal | single | EV Battery | NR |
| | | Management | phase | | |
| | | Immersion | | | |
| Use14C2 | 7 | Thermal | phase | EV Battery | NR |
| | | Management | change | | |
| | | Immersion | | | |
| Use14C3 | 7 | Thermal | single | EV Battery | NR |
| | | Management | phase and | | |
| | | Immersion | phase | | |
| | | | change | | |
| Use14D1 | 7 | Thermal | single | EV Battery | −40° C.-80° C. |
| | | Management | phase | | |
| | | Immersion | | | |
| Use14D2 | 7 | Thermal | phase | EV Battery | −40° C.-80° C. |
| | | Management | change | | |
| | | Immersion | | | |
| Use14D3 | 7 | Thermal | single | EV Battery | −40° C.-80° C. |
| | | Management | phase and | | |
| | | Immersion | phase | | |
| | | | change | | |
| Use14E1 | 7 | Thermal | single | Data Center | NR |
| | | Management | phase | Server | |
| | | Immersion | | | |
| Use14E2 | 7 | Thermal | phase | Data Center | NR |
| | | Management | change | Server | |
| | | Immersion | | | |
| Use14E3 | 7 | Thermal | single | Data Center | NR |
| | | Management | phase and | Server | |
| | | Immersion | phase | | |
| | | | change | | |
| Use14F1 | 7 | Thermal | single | Data Center | 30° C.-80° C. |
| | | Management | phase | Server | |
| | | Immersion | | | |
| Use14F2 | 7 | Thermal | phase | Data Center | 30° C.-80° C. |
| | | Management | change | Server | |
| | | Immersion | | | |
| Use14F3 | 7 | Thermal | single | Data Center | 30° C.-80° C. |
| | | Management | phase and | Server | |
| | | Immersion | phase | | |
| | | | change | | |
| Use14G1 | 7 | Thermal | single | ICs | NR |
| | | Management | phase | | |
| | | Immersion | | | |
| Use14G2 | 7 | Thermal | phase | ICs | NR |
| | | Management | change | | |
| | | Immersion | | | |
| Use14G3 | 7 | Thermal | single | ICs | NR |
| | | Management | phase and | | |
| | | Immersion | phase | | |
| | | | change | | |
| Use14H1 | 7 | Thermal | single | ICs | 30° C.-80° C. |
| | | Management | phase | | |
| | | Immersion | | | |
| Use14H2 | 7 | Thermal | phase | ICs | 30° C.-80° C. |
| | | Management | change | | |
| | | Immersion | | | |
| Use14H3 | 7 | Thermal | single | ICs | 30° C.-80° C. |
| | | Management | phase and | | |
| | | Immersion | phase | | |
| | | | change | | |

Various details, examples and descriptions of these and other specific applications, uses and methods are discussed below:

### Heat Transfer Compositions

As mentioned above, the present invention provides various methods, processes, and uses of the refrigerants of the present invention, including each of Refrigerants 1-8, to transmit heat from one location to another (or from one body, or article or fluid to another body, article or fluid). For example, the refrigerants of the present invention, including each of Refrigerants 1-8 and each of Blends RB1-RB20, may be used to keep the temperature of a device below a defined upper and/or above a defined lower temperature. In another example, the present refrigerants, which include refrigerants of the present invention, including each of Refrigerants 1-8 and each of Blends RB1-RB20, may be used for energy conversion, as in the capture of waste heat from industrial or other processes and the conversion to electrical or mechanical energy.

### Thermal Management Systems and Methods

One important category of use of the present refrigerants is in connection with thermal management systems and methods. Accordingly, the present invention encompasses various methods, processes and uses of the compounds and compositions of the present invention, including refrigerants of the present invention, including each of Refrigerants 1-8 and each of Blends RB1-RB20, in thermal management systems (hereinafter sometimes referred to as TMS) which operated to maintain an article or device (preferably an electronic component, device, article (including a battery)) or fluid within a certain temperature range, particularly as that article, device or fluid is operating according to its intended purpose and/or during the manufacture of a device or article, particularly during the manufacture an electronic device or component (such as a semiconductor wafer or integrated circuit chip). For example, the TMSs may keep the temperature of a device below a defined upper and/or above a defined lower temperature, including during the processing/manufacture thereof.

As discussed above, the refrigerants of the present invention, including each of Refrigerants 1-8 and RB1-RB20, can be advantageously used in a method or device or system of cooling and/or heating in an electronic device and/or used in a method or device or system for manufacture of an electronic component, device or article (such as a semiconductor wafer or integrated circuit chip).

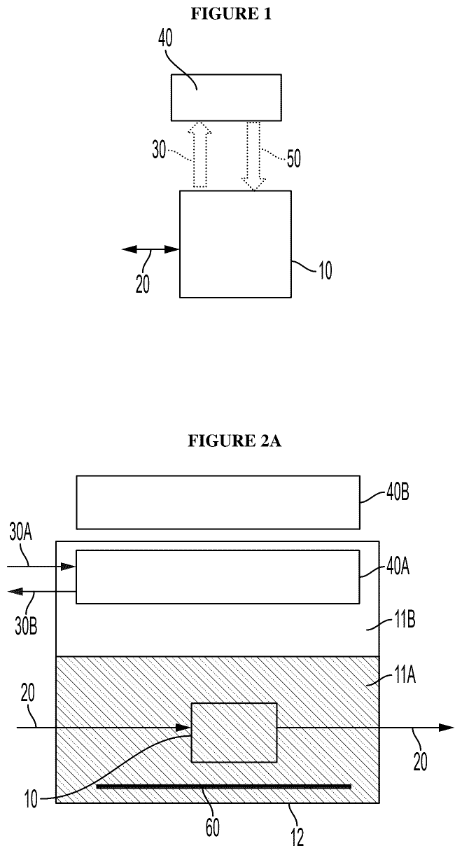

Preferred embodiments of the present thermal management methods are now discussed in connection with FIG. 1. An operating electronic device is shown schematically as 10 having a source of electrical energy and/or signals 20 flowing into and/or out of the device 10 and which generates heat as a result of its operation based on the electrical energy and/or signals 20. The refrigerants of the present invention, including each of Refrigerants 1-8 and RB1-RB20, are provided in thermal contact with the operating device 10 such that it removes heat, represented by the out flowing arrow 30. Heat is removed from the operating electronic device by sensible heat being added to the liquid thermal management fluid of the present invention (i.e., increasing the temperature of the liquid), or by causing a phase change in the thermal management liquid (i.e., vaporizing the liquid) or a combination of these. In preferred embodiments, the methods provide a supply of the refrigerants of the present invention, including each of Refrigerants 1-8 and RB1-RB20, to the device 10 such that the flow of heat from the device 10 through the present refrigerant 30 maintains the operating electrical device at or within a preferred operating temperature range. In preferred embodiments, the preferred operating temperature range of the electrical device is from about 700C to about 1500C, and even more preferably from about 700C to about 1200C, and the flow of heat 30 from the device 10 through the refrigerants of the present invention, including each of Refrigerants 1-8 and RB1-RB20, maintains the operating electrical device at or within such preferred temperature ranges. Preferably, the refrigerant 30 of the present invention, which has absorbed heat from the device, is in thermal contact with a heat sink, represented schematically as 40, at a temperature below the temperature of the heat transfer fluid 30 and thereby transfers the heat generated by the device 10 to the heat sink 40. In this way, the heat-depleted refrigerant 50 can be returned to the electronic device 10 to repeat the cycle of cooling.

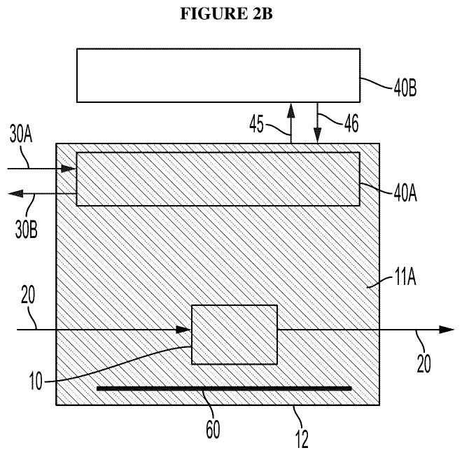

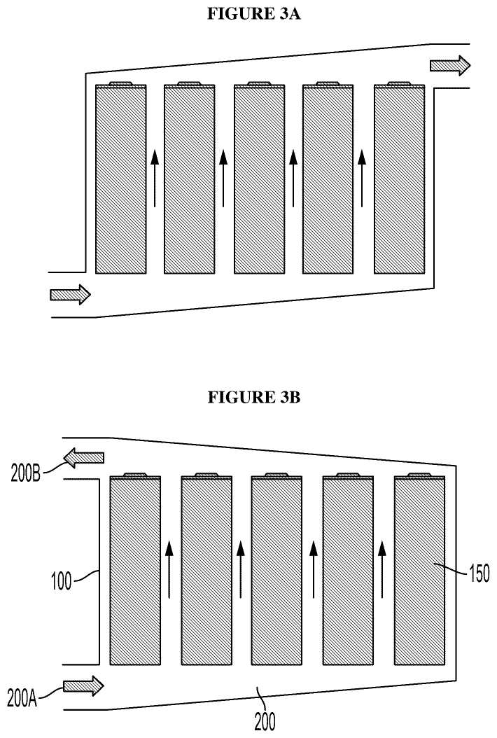

In a preferred embodiment of the present methods, the step of removing heat through the refrigerants of the present invention, including each of Refrigerants 1-8 and RB1-RB20, comprises evaporating the refrigerant using the heat generated by the operation of the electronic device, and the step of transferring that heat from the refrigerant to the heat sink comprises condensing the refrigerant by rejecting heat to the heat sink. In such methods, the temperature of the refrigerants of the present invention, including each of Refrigerants 1-8 and RB1-RB20, during said evaporation step is preferably greater than 50° C., or preferably greater than about 55° C., or preferably in the range of from about 55° C. to about 85° C., or preferably from about 65° C. to about 75° C. Applicants have found that the refrigerants of the present invention, including each of Refrigerants 1-8 and RB1-RB20, provide excellent performance in such methods and at the same time allow the use of relatively low cost, lightweight and reliable equipment to provide the necessary cooling, as will be explained further in connection with particular embodiments as described in connection with FIG. 2A below.

In a further preferred embodiment of the present methods, the step of removing heat through the refrigerants of the present invention, including each of Refrigerants 1-8 and RB1-RB20, comprises adding sensible heat to the refrigerant (e.g., raising the temperature of the liquid up to about 70° C. or less at about atmospheric pressure, i.e., wherein the fluid is not required to be in a high pressure container or vessel) using the heat generated by the operation of the electronic device, and the step of transferring that heat from the refrigerant to a heat sink and thereby reducing the liquid temperature by rejecting heat to the heat sink. The cooled liquid is then returned to thermal contact with the electrical device wherein the cycle starts over. In preferred embodiments, the temperature of the refrigerant that transfers heat to the heat sink is greater than about 40° C., or preferably greater than about 55° C., or preferably in the range of from about 45° C. to about 70° C., or preferably from about 45° C. to about 65° C., and preferably is at a pressure that is about atmospheric. Applicants have found that the refrigerants of the present invention, including each of Refrigerants 1-8 and RB1-RB20, provide excellent performance in such methods and at the same time allow the use for relatively low cost, lightweight and reliable equipment to provide the necessary cooling, as will be explained further in connection with particular embodiments as described in connection with FIG. 2B below.

It will be appreciated by those skilled in the art that the present invention comprises systems and methods which use both sensible heat transfer and phase change heat transfer as described above.

A particular method according to the present invention will now be described in connection with FIGS. 2A and 2B in which an electronic device 10 is contained in an appropriate container 12, and preferably a sealed container, and is in direct contact with, and preferably fully immersed in liquid the refrigerants 11A (shown schematically by gray shading) of the present invention, including each of Refrigerants 1-8 and RB1-RB20. For the purposes of convenience, such cooling methods, devices and system are sometimes referred to herein as “immersion cooling” methods, devices and systems.

In immersion cooling methods, devices and systems used to cool electrical devices or components, the operating electronic device 10 has a source of electrical energy and/or signals 20 flowing into and/or out of the container 12 and into and/or out of device 10, which generates heat as a result of its operation based on the electrical energy and/or signals 20. As those skilled in the art will appreciate, it is a significant challenge to discover a refrigerant that can perform effectively in such applications since the fluid must not only provide all of the other properties mentioned above, but it must also be able to do so while in intimate contact with an operating electronic device, that is, one which involves the flow of electrical current/signals. It will be appreciated that many fluids that might be otherwise viable for use in such applications will not be useable because they will either short-out the device, degrade when exposed to the conditions created by the operation of the electronic device (i.e., degrade the cooling effect over time and/or the operating stability of the device), or have some other property detrimental to operation when in contact with an operating electronic device.

In contrast, the present thermal management methods produce excellent and unexpected results by providing the refrigerants of the present invention, including each of Refrigerants 1-8 and RB1-RB20, in direct thermal and physical contact with the device 10 as it is operating. This heat of operation is safely and effectively transferred to the refrigerant 11A by: (a) causing the liquid phase of the fluid refrigerant to evaporate and form vapor 11B; or (b) raising the temperature of the liquid refrigerant 11A; or (c) a combination of (a) and (b).

When the refrigerants of the present invention, including each of Refrigerants 1-8 and RB1-RB20, is a single-phase liquid, it will remain liquid when heated by the heat-generating component. Thus, the refrigerant can be brought into contact with the heat generating component, resulting in the removal of the heat from the heat generating component and the production of a refrigerant with a higher temperature. The refrigerant is then transported to a secondary cooling loop, such as a radiator or another refrigerated system. An example of such a system is illustrated in FIG. 2, where the refrigerant enters a battery pack enclosure containing a number of cells and exits the enclosure having taken up heat from the battery pack.

When the refrigerants of the present invention, including each of Refrigerants 1-8 and RB1-RB20, is present in two phases, the heat-generating component is in thermal contact with the refrigerants of the present invention, including each of Refrigerants 1-8 and RB1-RB20, and transfers heat to the refrigerant, resulting in the boiling thereof. The refrigerant is then condensed. An example of such a system is where the heat-generating component is immersed in the refrigerant of the present invention, including each of Refrigerants 1-8 and RB1-RB20, and an external cooling circuit condenses the boiling fluid into a liquid state.

In the case of the phase change heat transfer systems of the present invention, reference is made herein to FIG. 2A. In such an operation, heat is carried away from the device 10 as the refrigerants of the present invention, including each of Refrigerants 1-8 and RB1-RB20, evaporates and the vapor rises through the remaining refrigerant liquid in the container 12. The refrigerant vapor 11B then rejects the heat it has absorbed to a heat sink 40, which can be an enclosed heat sink 40A and/or an external heat sink 40B. An example of a heat sink that is internal to the container 12 are condenser coils 30A and 30B with circulating liquid, such as water, at a temperature below the condensing temperature of the refrigerant vapor. An example of a heat sink that is external to the container 12 would be passing relatively cool ambient air over the container 12 (which preferably in such case include cooling fins or the like), which will serve to condense the heat transfer vapor 11B on the interior surface of the container. As a result of this condensation, liquid refrigerant is returned to the pool of liquid fluid 11A in which the device 10 remains immersed in operation.

In the case of a sensible heat transfer systems of the present invention, reference is made herein to FIG. 2B. In such an operation heat is carried away from the device as the temperature of liquid 11A, including the refrigerants of the present invention, including each of Refrigerants 1-8 and RB1-RB20, increases upon accepting heat being generated by the device, which is immersed, and preferably substantially fully immersed in the refrigerant 11A of the present invention. The higher temperature refrigerant liquid 11A then rejects the heat it has absorbed to a heat sink 40, which can be an enclosed heat sink 40A and/or an external heat sink 40B. An example of a heat sink that is internal to the container 12 are cooling coils 30A and 30B with circulating liquid, such as water, at a temperature below the temperature of heated liquid. An example of a heat sink that is external to the container 12 would be removing heated liquid 11A from the container through a conduit 45 where it is thermally contacted with a cool fluid, such as might be provided by relatively cool ambient air, or cooled water or refrigerant, which will serve to lower the temperature of the liquid. Cooled liquid is then returned via conduit 46.

Optionally, but preferably in certain embodiments involving thermal management of the batteries used in electronic vehicles, the thermal management system includes a heating element which is able to heat the refrigerants of the present invention, including each of Refrigerants 1-8 and RB1-RB20, such as for example an electrical heating element 60 which is also immersed in the refrigerant. As those skilled in the art will appreciate, the batteries in electronic vehicles (which would correspond to the operating electronic device 10 in FIGS. 2A and 2B) can reach relatively low temperatures while parked outside in the winter months in many geographical locations, and frequently such low temperature conditions are not desirable for battery operation. Accordingly, the thermal management system of the present invention can include sensors and control modules (not shown) which turn on the heating element when the battery temperature is below a predetermined level. In such a case, the heater 60 would be activated, the refrigerant liquid 11A would be heated, and would in turn transfer this heat to the electronic device 10 until the minimum temperature is reached. Thereafter during operation, the refrigerants of the present invention, including each of Refrigerants 1-8 and RB1-RB20, would serve the cooling function as described above.

For the purposes of this invention, the refrigerants of the present invention, including each of Refrigerants 1-8 and RB1-RB20, can be in direct contact with the heat-generating component or in indirect contact with the heat-generating component.

When the refrigerants of the present invention, including each of Refrigerants 1-8 and RB1-RB20, is in indirect contact with the heat-generating component, the refrigerant fluid can be used in a closed system in the electronic device, which may include at least two heat exchangers. When the refrigerants of the present invention, including each of Refrigerants 1-8 and RB1-RB20, are used to cool the heat-generating component, heat can be transferred from the component to the refrigerant, usually through a heat exchanger in contact with at least a part of the component or the heat can be transferred to circulating air which can conduct the heat to a heat exchanger that is in thermal contact with the refrigerant.

In a particularly preferred feature of the present invention, the refrigerants of the present invention, including each of Refrigerants 1-8 and RB1-RB20, is in direct contact with the heat-generating component. In particular, the heat generating component is fully or partially immersed in the refrigerant. Preferably the heat generating component is fully immersed in the refrigerants of the present invention, including each of Refrigerants 1-8 and RB1-RB20. The refrigerant, as a warmed fluid or as a vapor, can then be circulated to a heat exchanger which takes the heat from the fluid or vapor and transfers it to the outside environment by way of a heat sink such as ambient air or water cooled by ambient air or otherwise. After this heat transfer, the cooled refrigerant (cooled or condensed) is recycled back into the system to cool the heat-generating component.

Electrical conductivity and/or dielectric strength of a refrigerant becomes important if the fluid comes in direct contact with the electronic components of the electronic device (such as in direct immersion cooling), or if the refrigerant leaks out of a cooling loop or is spilled during maintenance and comes in contact with the electrical circuits. Thus, the refrigerants of the present invention, including each of Refrigerants 1-8 and RB1-RB20, is preferably an electrically insulating thermal management fluid.

The refrigerants of the present invention, including each of Refrigerants 1-8 and RB1-RB20, may be recirculated passively or actively in the device, for example by using mechanical equipment such as a pump. In a preferred feature of the present invention, the refrigerants of the present invention, including each of Refrigerants 1-8 and RB1-RB20, is recirculated passively in the device.

Passive recirculating systems work by transferring heat from the heat-generating component to the refrigerant until it typically is vaporized, allowing the heated vapor to proceed to a heat exchange surface at which it transfers its heat to the heat exchanger surface and condenses back into a liquid. It will be appreciated that the heat exchange surface can be part of a separate heat exchange unit and/or can be integral with the container, as described above for example in connection with FIG. 2. The condensed liquid then returns, preferably fully passively by the force of gravity and/or a wicking structure, into the refrigerant in contact with the heat-generating component. Thus, in a preferred feature of the invention, the step of transferring heat from the heat-generating component to the refrigerants of the present invention, including each of Refrigerants 1-8 and RB1-RB20, causes the thermal management fluid to vaporize.

Examples of passive recirculating systems include a heat pipe or a thermosyphon. Such systems passively recirculate the refrigerants of the present invention, including each of Refrigerants 1-8 and RB1-RB20, using gravity. In such a system, the refrigerant is heated by the heat-generating component, resulting in a heated refrigerant which is less dense and more buoyant. This refrigerant travels to a storage container, such as a tank where it cools and condenses. The cooled refrigerant then flows back to the heat source.

### Electrical Device Cooling

The present disclosure includes the use of the refrigerants of the present invention, including each of Refrigerants 1-8 and RB1-RB20, to cool and optionally heat electronic devices that produce or include a component that is a heat-generating component. The heat-generating component can be any component that includes an electronic element that generates heat as part of its operation. For the purposes of this invention, the heat generating component includes but is not limited to: semiconductor integrated circuits (ICs), electrochemical cells, power transistors, resistors, and electroluminescent elements, such as microprocessors, wafers used to manufacture semiconductor devices, power control semiconductors, electrical distribution switch gear, power transformers, circuit boards, multi-chip modules, packaged or unpackaged semiconductor devices, semiconductor integrated circuits, fuel cells, lasers (conventional or laser diodes), light emitting diodes (LEDs), and electrochemical cells, e.g. used for high power applications such as, for example, hybrid or electric vehicles.

For the purpose of this invention, the electronic device includes but is not limited to: personal computers, microprocessors, servers, cell phones, tablets, digital home appliances (e.g., televisions, media players, games consoles etc.), personal digital assistants, datacenters, batteries both stationary and in vehicles, including Li-ion batteries and other batteries used in hybrid or electric vehicles, wind turbine, train engine, or generator. Preferably the electronic device is a hybrid or electric vehicle.

The present invention further relates to an electronic device comprising the refrigerants of the present invention, including each of Refrigerants 1-8 and RB1-RB20. For the purposes of this invention, the refrigerant is provided for cooling and/or heating the electronic device.

The present invention further relates to an electronic device comprising a heat generating component and a refrigerant of the present invention, including each of Refrigerants 1-8 and RB1-RB20, for cooling, and optionally heating, the electronic device.

The present invention further relates to an electronic device comprising a heat generating component, a heat exchanger, a pump and a refrigerant of the present invention, including each of Refrigerants 1-8 and RB1-RB20. For the purpose of this invention, the electronic device can be any such device, including but not limited to personal computers, microprocessors, servers, cell phones, tablets, digital home appliances (e.g. televisions, media players, games consoles etc.), personal digital assistants, datacenters, hybrid or electric vehicles, batteries both stationary and in vehicles, electrical drive motors, fuel cells (e.g., hydrogen fuel cells) and electrical generators, preferably wherein the electronic device is in a hybrid vehicle, or electric vehicle, or wind turbine, or train.

For the purposes of this invention, the heat generating component can be any electrical component that generates heat during operation, but preferably electronic components that generate heat at high levels of heat flux. Examples of heat generating components that can be cooled according to the present invention include semiconductor integrated circuits (ICs), electrochemical cells, power transistors, resistors, and electroluminescent elements, such as microprocessors, wafers used to manufacture semiconductor devices, power control semiconductors, electrical distribution switch gear, power transformers, printed circuit boards (PCBs), multi-chip modules, packaged or unpackaged semiconductor devices, semiconductor integrated circuits, fuel cells, lasers (conventional or laser diodes), light emitting diodes (LEDs), and electrochemical cells, e.g. used for high power applications such as, for example, hybrid or electric vehicles.

### Lithium-Ion Battery Cooling Systems

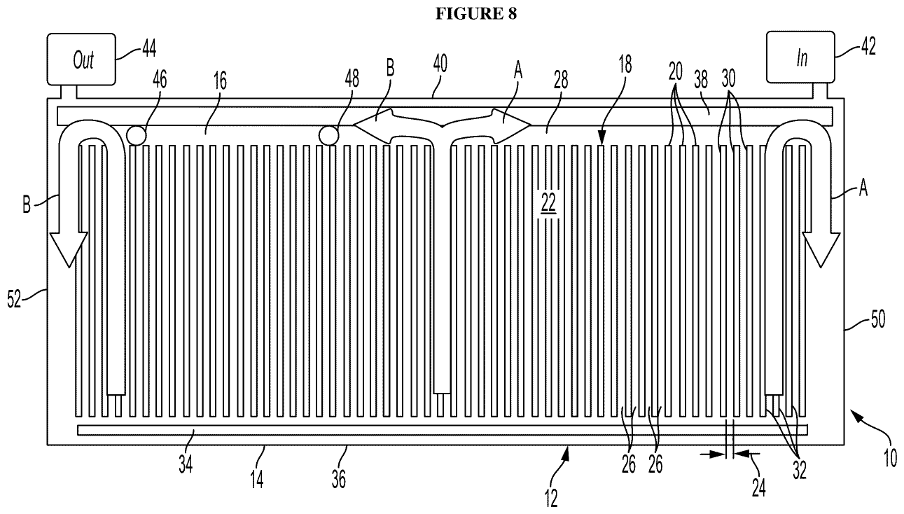

Examples of the present thermal management methods useful for lithium-ion battery cooling, including the use of refrigerants of the present invention, including each of Refrigerants 1-8 and RB1-RB20, in such methods, including Heat Transfer Method 1, will now be described in connection with FIG. 8. A vehicle battery pack with a self-contained liquid cooling system 10 comprising a module 12 formed of a container 14 with an interior space 16 for supporting a battery assembly 18. The container 14 is a closed and sealed container 14 for forming a self-contained liquid cooling system 10. The battery assembly 18 includes a plurality of battery cells 20 such as a plurality of Lithium-ion (Li-ion) batteries for use in a hybrid vehicle. In another embodiment, the plurality of battery cells 20 is Li-ion batteries for use in a Battery Electric Vehicle (BEV). Additional batteries for use with other prime mover vehicles may be provided with the liquid cooling system 10 of the present invention, where each battery cell includes active material for generating power from an electrochemical reaction within the interior space 16 of the container 14. The battery cells 20 are preferably stacked to form a battery cell stack 22. In the embodiment shown, a gap 24 between each battery cell 20 is between 0.25-0.50 mm, forming a fluid channel 26 between each battery cell 20. In another embodiment, the gap 24 may be less than 0.25 mm. It is understood that other gap sizes can be used as desired.

A composition of the present invention, including Compositions 1, and the refrigerants of the present invention, including each of Refrigerants 1-8 and RB1-RB20, is disposed within the interior space 16 of the container 14 and the fluid level shown is such that the battery assembly 18 is completely immersed within the composition/refrigerant of the present invention. The composition of the present invention, including Composition 1, and the refrigerants of the present invention, including each of Refrigerants 1-8 and RB1-RB20, is in contact with the battery cells 20 through the fluid channels 26 formed by gaps 24.

A heating element 34 is located at a base area 36 of the container 14. The heating element 34 shown is an electronic heating element. It is understood that other heating element types may be used. The heating element 34 is shown as a single element; however, multiple heating elements 34 such as heating plates may be provided.

A cooling element 38 is located at an upper area 40 of the container 14. The cooling element 38 may be a chilled water condenser having an inlet 42 and an outlet 44 extending beyond the walls of the sealed container 14 for importing and exporting water for the cooling element 38. In another embodiment, the cooling element 38 may be a chilled water plate. In still another embodiment, the cooling element 38 may be a thin aluminum heat sink having external chilled water travelling through the cooling element 38. The cooling element 38 may be a graphite foil impregnated with an electrically nonconductive polymer. The cooling element may also be formed from copper.

In the embodiment shown, arrows “A” and “B” indicate a flow 28 of the composition of the present invention, including Composition 1, and the refrigerants of the present invention, including each of Refrigerants 1-8 and RB1-RB20. Upon heating of each battery cell 20 by the heating element 34, the fluid 28, including compositions of the present invention, including Compositions 1, and the refrigerants of the present invention, including each of Refrigerants 1-8 and RB1-RB20, is exposed to a front surface area 30 and a rear surface area 32 of the battery cells 20, and will boil. The heated coolant 28 will rise and flow to the top of the battery cell stack 22 to be cooled by the cooling element 38. The cooled coolant 28 will return to the base area 36, generally following either coolant paths “A” or “B.” Where the general location of the coolant 28 at the moment of boiling is located within the fluid channels 26 of the battery cells 20 in the center area and toward a side 50 of the container 14, the coolant 28 will tend to follow flow path “A”. Similarly, if the general location of the dielectric coolant 28 at the moment of boiling is located within the fluid channels 26 of the battery cells 20 in the center area and toward an opposing side 52 of the container 14, the dielectric coolant 28 will tend to follow flow path “B”.

A coolant temperature sensor 46 is located on or near the cooling element 38. In the embodiment shown, the temperature sensor 46 is located within the area of the outlet 44 of the cooling element 38 and measures a temperature of the dielectric coolant 28 of the present invention at a point of exposure to the cooling element. The temperature sensor 46 may be located anywhere within the battery cell stack 22 as desired.

A coolant level sensor 48 is also provided and is located near the upper area 40 of the container 14 to measure the fluid level of the dielectric coolant 28, including compositions of the present invention, including Composition 1, and the refrigerants of the present invention, including each of Refrigerants 1-8 and RB1-RB20, within the container 14, ensuring complete immersion of the battery assembly 18 within the dielectric coolant 28.

### Heat Pipe Cooling and Heating

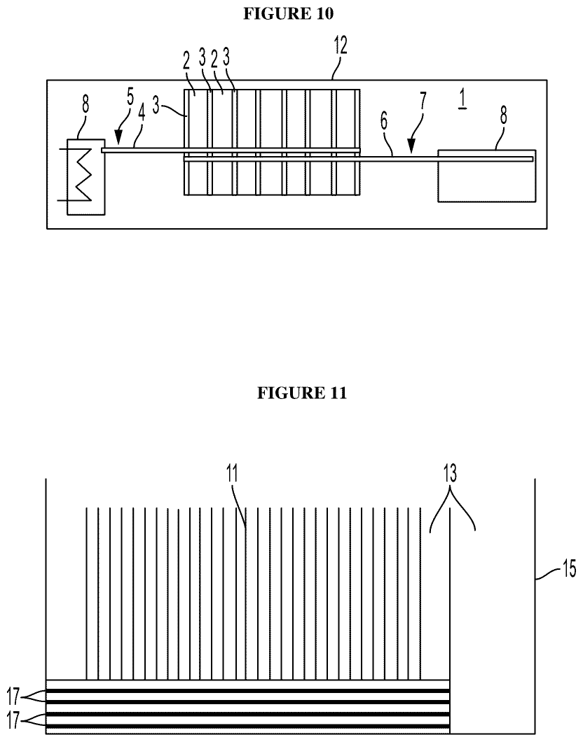

An example of the present heat transfer methods using a heat pipe is now described with respect to FIG. 10, which is a specific example of a heat pipe in an energy storage assembly 1 according to one exemplary embodiment of the invention. The energy storage assembly 1 may be part of a motor vehicle 12, in particular of a hybrid or electric vehicle, and is provided to supply electric power to electric consumers, like e.g., an electrical drive unit (not shown), on the motor vehicle side. The energy storage assembly 1 includes a plurality of electrical energy stores. 2. The electrical energy stores 2 are electrically connected via an electric connection element (not shown), in particular in the form of a conductive rail or conductor rail (“bus bar”), i.e., connected in series or in parallel. The electric connection element contacts hereby corresponding electrical connectors (not shown) arranged on respective exposed outer wall sections of corresponding energy storage housings (not shown) of the energy stores 2 in parallel alignment arranged adjacent to one another to thereby form an energy store stack (“stack”). Plate-shaped spacer elements 3 are respectively arranged between the energy stores 2 to separate them and at the same time thermally conductive properties. The spacer elements 3 thus provide, on one hand, spacing between immediately adjacent energy stores 2 so that immediately adjacent energy stores 2 do not contact each other electrically or mechanically. On the other hand, the spacer elements 3 act as a result of their thermally conductive properties as heat conductors for the purpose of cooling the energy stores 2 or the energy storage assembly 1 by dissipating heat, particularly from the contacting energy stores 2, or, for the purpose of heating the energy stores 2 or energy storage assembly 1 by supplying heat, particularly to the contacting energy stores 2. A heat pipe 4 of a first heat pipe assembly 5 and of a heat pipe 6 of a second heat pipe assembly 7 are provide. The heat pipes 4, 6 thus extend along this side surface of the energy store stack and are thermally coupled to the spacer elements 3, respectively. The spacer elements 3 thus form a thermal bridge between the heat pipes 4 of the first heat pipe assembly 5 and the heat pipes 6 of the second heat pipe assembly 7, on one hand, and the energy stores 2, on the other hand. The respective heat pipes 4 of the first heat pipe assembly 5 are arranged and aligned such as to be thermally coupled with respective evaporation zones, in which a contained refrigerant of the present invention, including each of Refrigerants 1-8 and RB1-RB20, can be evaporated, to the spacer elements 3. Heat (evaporation heat) required for the evaporation of the present refrigerant is thus removed from the spacer elements 3 or via the spacer elements 3 from the energy stores 2. The energy stores 2, including the energy storage assembly 1, can thus be cooled via the heat pipes 4 of the first heat pipe assembly 5. Also, the respective condensation zones of the heat pipes 4 of the first heat pipe assembly 5, in which condensation zones a contained gaseous refrigerant of the present invention, including each of Refrigerants 1-8 and RB1-RB20, can be condensed, are thermally coupled with a heat sink 8 in the form of a motor-vehicle-side heat exchanger. Heat (condensation heat) generated during condensation of the present refrigerant can thus be transferred to the heat sink 8. The heat exchanger can be part of the energy storage assembly 1, i.e., belong to or associated with the energy storage assembly 1. The respective heat pipes 6 of the second heat pipe assembly 7 are arranged and aligned such as to be thermally coupled with their respective condensation zones, in which the contained gaseous refrigerant of the present invention can be condensed, to the spacer elements 3. Heat (condensation heat) can thus be transferred during condensation of the present refrigerant to the spacer elements 3 or via the spacer elements 3 to the energy stores 2. Thus, the energy stores 2 and the energy storage assembly 1, can be heated via the heat pipes 6 of the second heat pipe assembly 7. Also, the respective evaporation zones of the heat pipes 6 of the second heat pipe assembly 7, in which evaporation zones a contained refrigerant of the present invention can be evaporated, are thermally coupled with a heat source 9 in the form of a functional component, i.e., e.g., a charger or a control device or a control electronics, associated to the energy storage assembly 1. Heat (evaporation heat) required for the evaporation of the refrigerant can thus be removed from the heat source 9. Thus, the functional component can be cooled via the heat pipes 6 of the second heat pipe assembly 7. The two heat pipe assemblies 5, 7, and their associated heat pipes 4, 6 enables implementation of a temperature control device for controlling the temperature, i.e., for heating or cooling, of the energy stores 2 of the energy storage assembly 1. The heat pipes useful according to the present invention include both gravity return heat pipe, capillary return heat pipe and gravity/capillary return heat pipes.

### Organic Rankine Cycles

When a refrigerant of the present invention, including each of Refrigerants 1-8 and RB1-RB20, is used in an Organic Rankine cycle, it may be referred to as a working fluid.

The working fluid therefore corresponds to refrigerant as discussed in this application. All preferred features of the heat transfer fluid apply to the working fluid as described herein.

Rankine cycle systems are known to be a simple and reliable means to convert heat energy into mechanical energy in the form of shaft power. In industrial settings, it may be possible to use flammable working fluids such as toluene and pentane, particularly when the industrial setting has large quantities of flammables already on site in processes or storage. However, for instances where the risk associated with use of a flammable and/or toxic working fluid is not acceptable, such as power generation in populous areas or near buildings, it is necessary or at least highly desirable to use non-flammable and/or non-toxic refrigerants as the working fluid. There is also a drive in the industry for these materials to be environmentally acceptable in terms of GWP.

The process for recovering waste heat in an Organic Rankine cycle according to the present invention preferably involves pumping liquid-phase working fluids of the present invention, including the refrigerant of the present invention, including each of Refrigerants 1-8 and RB1-RB20, through a boiler where an external (waste) heat source, such as a process stream, heats the working fluid causing it to evaporate into a saturated or superheated vapor. This vapor is expanded through a turbine wherein the waste heat energy is converted into mechanical energy. Subsequently, the vapor phase working fluid is condensed to a liquid and pumped back to the boiler in order to repeat the heat extraction cycle.

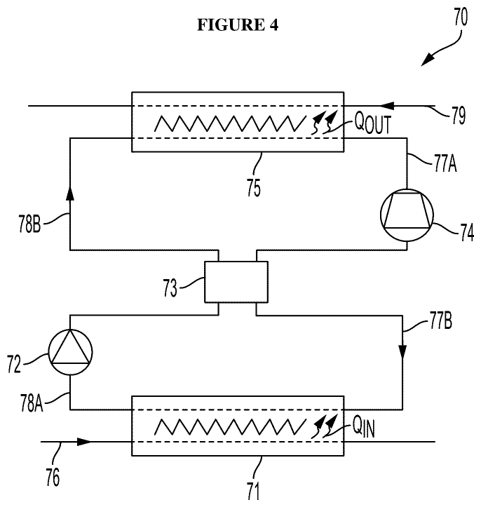

Referring to FIG. 4, in an exemplary organic Rankine cycle system 70, working fluid of the present invention, including refrigerant of the present invention, including each of Refrigerants 1-8 and RB1-RB20, is circulated between an evaporator 71 and a condenser 75, with a pump 72 and an expansion device 74 functionally disposed therebetween. In the illustrated embodiment, an external flow of fluid is directed to evaporator 71 via external warm conduit 76. External warm conduit 76 may carry fluid from a warm heat source, such as a waste heat source from industrial processes (e.g., power generation), flue gases, exhaust gases, geothermal sources, etc.

Evaporator 71 is preferably configured as a heat exchanger which may include, e.g., a series of thermally connected, but fluidly isolated, tubes carrying fluid from warm conduit 76 and fluid from working fluid conduit 77B respectively. Thus, evaporator 71 facilitates the transfer of heat QIN from the warm fluid arriving from external warm conduit 76 to the relatively cooler (e.g., “cold”) working fluid arriving from expansion device 74 via working fluid conduit 77B.

The working fluid of the present invention, including the present fluoroethers, thus exits from evaporator 71, having been warmed by the absorption of heat QIN, and then travels through working fluid conduit 78A to pump 72. Pump 72 pressurizes the working fluid, thereby further warming the fluid through external energy inputs (e.g., electricity). The resulting “hot” fluid passes to an input of condenser 75 via conduit 78B, optionally via a regenerator 73 as described below.

Condenser 75 is configured as a heat exchanger similar to evaporator 71, and may include, e.g., a series of thermally connected, but fluidly isolated, tubes carrying fluid from cool conduit 79 and fluid from working fluid conduit 78B respectively. Condenser 75 facilitates the transfer of heat QOUT to the cool fluid arriving from external cool conduit 79 to the relatively warmer (e.g., “hot”) working fluid of the present invention, including the refrigerant of the present invention, including each of Refrigerants 1-8 and RB1-RB20, arriving from pump 72 via working fluid conduit 78B.

The working fluid of the present invention, including each of Refrigerants 1-8 and RB1-RB20, exiting from condenser 75, having thus been cooled by the loss of heat QOUT, then travels through working fluid conduit 77A to expansion device 74. Expansion device 74 allows the working fluid to expand, thereby further cooling the fluid. At this stage, the fluid of the present invention, including the present fluoroethers, may perform work, e.g., by driving a turbine. The resulting “cold” fluid passes to an input of evaporator 71 via conduit 77B, optionally via a regenerator 73 as described below, and the cycle begins anew.

Thus, working fluid conduits 77A, 77B, 78A and 78B define a closed loop such that the working fluid contained therein may be reused indefinitely, or until routing maintenance is required.

In the illustrated embodiment, regenerator 73 may be functionally disposed between evaporator 71 and condenser 75. Regenerator 73 allows the “hot” working fluid of the present invention, including the present fluoroethers, exiting from pump 72 and the “cold” working fluid issued from expansion device 74 to exchange some heat, potentially with a time lag between deposit of heat from the hot working fluid and release of that heat to the cold working fluid. In some applications, this can increase the overall thermal efficiency of Rankine cycle system 70.

The invention also provides a process for converting thermal energy to mechanical energy in a Rankine cycle, the method comprising the steps of i) vaporizing a working fluid of the invention, including refrigerant of the present invention, including each of Refrigerants 1-8 and RB1-RB20, with a heat source and expanding the resulting vapor, then ii) cooling the working fluid with a heat sink to condense the vapor, wherein the working fluid is a refrigerant of the present invention, including each of Refrigerants 1-8 and RB1-RB20.

The mechanical work may be transmitted to an electrical device such as a generator to produce electrical power.

The heat source maybe provided by, for example, a thermal energy source selected from industrial waste heat, solar energy, geothermal hot water, low pressure steam, distributed power generation equipment utilizing fuel cells, prime movers, or an internal combustion engine. The low-pressure steam is preferably a low-pressure geothermal steam or is provided by a fossil fuel powered electrical generating power plant.

The heat source is preferably provided by a thermal energy source selected from industrial waste heat, or an internal combustion engine.

It will be appreciated that the heat source temperatures can vary widely, for example from about 90° C. to >800° C., and can be dependent upon a myriad of factors including geography, time of year, etc. for certain combustion gases and some fuel cells.

Systems based on sources such as waste water or low pressure steam from, e.g., a plastics manufacturing plants and/or from chemical or other industrial plant, petroleum refinery, and related word forms, as well as geothermal sources, may have source temperatures that are at or below about 175° C. or at or below about 100° C., and in some cases as low as about 90° C. or even as low as about 80° C. Gaseous sources of heat such as exhaust gas from combustion process or from any heat source where subsequent treatments to remove particulates and/or corrosive species result in low temperatures may also have source temperatures that are at or below 200° C., at or below about 175° C., at or below about 130° C., at or below about 120° C., at or below about 100° C., at or below about 100° C., and in some cases as low as about 90° C. or even as low as about 80° C.

However, it is preferred in some applications that the heat source has a temperature of at least about 200° C., for example of from about 200° C. to about 400° C.

In an alternative preferred embodiment, the heat source has a temperature of from 400 to 800° C., more preferably 400 to 600° C.

### Heat Pumps

The refrigerant of the present invention, including each of Refrigerants 1-8 and RB1-RB20, may be used in a high temperature heat pump system.

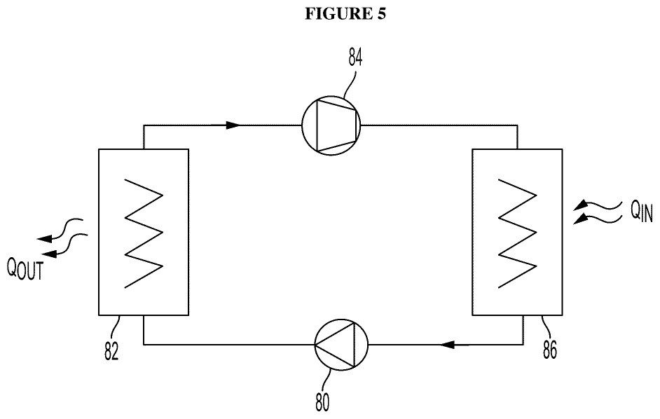

Referring to FIG. 5, in one exemplary heat pump system, compressor 80, such as a rotary, piston, screw, or scroll compressor, compresses a refrigerant of the present invention, including each of Refrigerants 1-8 and RB1-RB20, which is conveyed to a condenser 82 to release heat QOUT to a first location, followed by passing the refrigerant through an expansion device 84 to lower the refrigerant pressure, followed by passing the refrigerant through an evaporator 86 to absorb heat QIN from a second location. The refrigerant is then conveyed back to the compressor 80 for compression.

The present invention provides a method of heating a fluid or body using a high temperature heat pump, said method comprising the steps of (a) condensing a refrigerant of the present invention, including each of Refrigerants 1-8 and RB1-RB20, in the vicinity of the fluid of body or be heated, and (b) evaporating said refrigerant.

Examples of high temperature heat pumps include a heat pump tumble dryer or an industrial heat pump. It will be appreciated the heat pump may comprise a suction line/liquid line heat exchanger (SL-LL HX). By “high temperature heat pump”, it is meant a heat pump that is able to generate temperatures of at least about 80° C., preferably at least about 90° C., preferably at least about 100° C., more preferably at least about 110° C.

### Secondary Loop System

The refrigerant of the present invention, including each of Refrigerants 1-8 and RB1-RB20, may be used as secondary refrigerant fluid in a secondary loop system.

A secondary loop system contains a primary vapor compression system loop that uses a primary refrigerant and whose evaporator cools the secondary loop fluid. The secondary refrigerant fluid, including refrigerant of the present invention, including each of Refrigerants 1-8 and RB1-RB20, then provides the necessary cooling for an application. The secondary refrigerant fluid should preferably be non-flammable and have low toxicity since the fluid in such a loop is potentially exposed to humans in the vicinity of the cooled space. In other words, the refrigerant of the present invention, including each of Refrigerants 1-8 and RB1-RB20, may be used as a “secondary refrigerant fluid” in a secondary loop system.

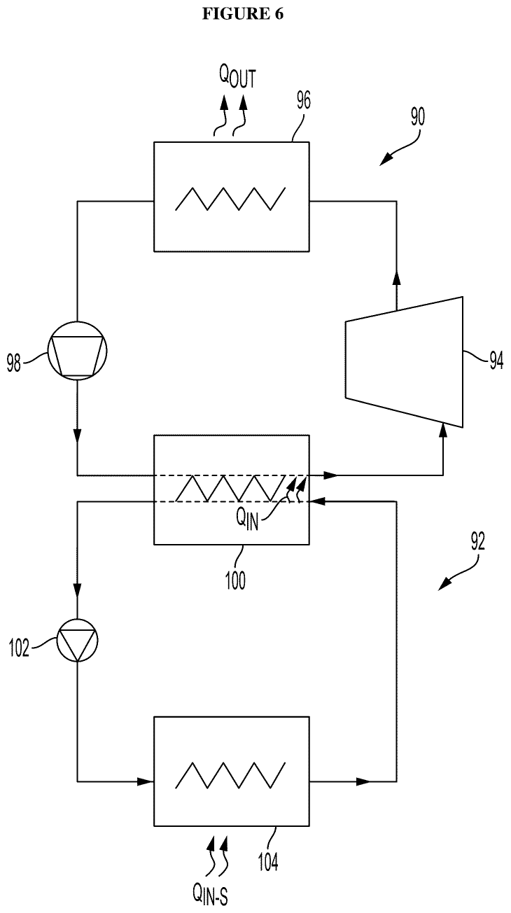

Referring to FIG. 6, one exemplary secondary loop system includes a primary loop 90 and a secondary loop 92. In primary loop 90, compressor 94, such as a rotary, piston, screw, or scroll compressor, compresses a primary refrigerant, which is conveyed to a condenser 96 to release heat QOUT to a first location, followed by passing the primary refrigerant through an expansion device 98 to lower the refrigerant pressure, followed by passing the primary refrigerant through a refrigerant/secondary fluid heat exchanger 100 to exchange heat QIN with a secondary fluid, including the present fluoroethers, with the secondary fluid pumped through secondary loop 92 via a pump 102 to a secondary loop heat exchanger 104 to exchange heat with a further location, for example to absorb heat QIN-S to providing cooling to the further location.

The primary fluid used in the primary loop (vapor compression cycle, external/outdoors part of the loop) may be selected from but not limited to HFO-1234ze(E), HFO-1234yf, propane, R455A, R32, R466A, R44B, R290, R717, R452B, R448A, and R449A, preferably HFO-1234ze(E), HFO-1234yf, or propane.

The secondary loop system may be used in refrigeration or air conditioning applications, that is, the secondary loop system may be a secondary loop refrigeration system or a secondary loop air conditioning system.

Examples of refrigeration systems which can include a secondary loop refrigeration system that include a secondary refrigerant of the present invention, including the present fluoroethers, include: a low temperature refrigeration system, a medium temperature refrigeration system, a commercial refrigerator, a commercial freezer, an industrial freezer, an industrial refrigerator, and a chiller.

Examples of air conditioning systems which can include a secondary loop air conditioning system which utilize a refrigerant of the present invention, including the present fluoroethers, include in mobile air conditioning systems or stationary air conditioning systems. Mobile air-conditioning systems including air conditioning of road vehicles such as automobiles, trucks and buses, as well as air conditioning of boats, and trains. For example, where a vehicle contains a battery or electric power source.

Examples of stationary air conditioning systems which can include a secondary loop air conditioning system which utilize a refrigerant of the present invention, including the present fluoroethers, include: a chiller, particularly a positive displacement chiller, more particularly an air cooled or water-cooled direct expansion chiller, which is either modular or conventionally singularly packaged, a residential air conditioning system, particularly a ducted split or a ductless split air conditioning system, a residential heat pump, a residential air to water heat pump/hydronic system, an industrial air conditioning system, a commercial air conditioning system, particularly a packaged rooftop unit and a variable refrigerant flow (VRF) system, and a commercial air source, water source or ground source heat pump system.

A particularly preferred heat transfer system according to the present invention is an automotive air conditioning system comprising a vapor compression system (the primary loop) and a secondary loop air conditioning system, wherein the primary loop contains HFO-1234yf as the refrigerant and the second loop contains a refrigerant or heat transfer composition of the present invention, including the present fluoroethers. In particular, the secondary loop can be used to cool a component in the car engine, such as the battery.

It will be appreciated that the secondary loop air conditioning or refrigeration system may comprise a suction line/liquid line heat exchanger (SL-LL HX).

The present heat transfer fluids, or heat transfer compositions which can include a secondary loop air conditioning system which utilize a refrigerant of the present invention, including Refrigerants 1-8 and RB1-RB20, may be used as a replacement for existing fluids.

The invention includes a method of replacing an existing heat transfer fluid in a heat transfer system, said method comprising the steps of (a) removing at least a portion of said existing heat transfer fluid from said system, and subsequently (b) introducing into said system a refrigerant of the present invention, including Refrigerants 1-8 and RB1-RB20. Step (a) may involve removing at least about 5 wt. %, at least about 10 wt. %, at least about 15 wt. %, at least about 50 wt. % at least about 70 wt. %, at least about 90 wt. %, at least about 95 wt. %, at least about 99 wt. % or at least about 99.5 wt. % or substantially all of said existing heat transfer fluid from said system prior to step (b).

The method may optionally comprise the step of flushing said system with a solvent after conducting step (a) and prior to conducting step (b).

For the purposes of this invention, the refrigerant of the present invention, including each of Refrigerants 1-8 and RB1-RB20, can be used to replace an existing fluid in an electronic device, in an Organic Rankine cycle, in a high temperature heat pump or in a secondary loop.

For example, the refrigerant of the present invention, including each of Refrigerants 1-8 and RB1-RB20, may be used as a replacement for existing fluids such as HFC-4310mee, HFE-7100 and HFE-7200. Alternatively, the refrigerant of the present invention, including each of Refrigerants 1-8 and RB1-RB20, can be used to replace water and glycol. The replacement may be in existing systems, or in new systems which are designed to work with an existing fluid. Alternatively, the refrigerant of the present invention, including each of Refrigerants 1-8 and RB1-RB20, can be used in applications in which the existing refrigerant was previously used. Alternatively, the refrigerant of the present invention, including each of Refrigerants 1-8 and RB1-RB20, may be used to retrofit an existing refrigerant in an existing system. Alternatively, the refrigerant of the present invention, including each of Refrigerants 1-8 and RB1-RB20, may be used in new systems which are designed to work with an existing refrigerant.

The invention provides a method of replacing an existing refrigerant in a heat transfer system, said method comprising the steps of (a) removing at least a portion of said existing refrigerant from said system, and subsequently (b) introducing into said system refrigerant of the present invention, including each of Refrigerants 1-8 and RB1-RB20. The existing refrigerants may be selected, for example, from HFC-4310mee, HFE-7100 and HFE-7200.

Step (a) may involve removing at least about 5 wt. %, at least about 10 wt. %, at least about 15 wt. %, at least about 50 wt. % at least about 70 wt. %, at least about 90 wt. %, at least about 95 wt. %, at least about 99 wt. % or at least about 99.5 wt. % of said existing refrigerant from said system prior to step (b).

The method may optionally comprise the step of flushing said system with a solvent after conducting step (a) and prior to conducting step (b).

### Solvent and Cleaning Uses, Methods, and Systems

The present invention provides solvating methods. Such methods include cleaning methods generally, etching methods, carrier solvent applications (for coating applications, lubricant deposition, silicone deposition, and other coatings, including in connection with coatings of medical devices heparin and PTFE for example) using a composition of the present invention, including Composition 1.

With respect to cleaning methods, all such methods are included within the scope of the present invention. Preferred cleaning methods include vapor degreasing by contacting the article, device or component thereof with a composition of the present invention, including Composition 1. A wide variety of contaminants can be removed from a wide variety of article, device and components. Examples of contaminants that can be removed using a composition of the present invention, including the present fluoroethers, include, for example, light oils, medium oils, fluorolubes, greases and silicones and waxes. Examples of article, device and components that can be cleaned using a composition of the present invention, including Composition 1, include, for example electronic components (including silicon wafers, PCBs, semiconductor surfaces), precision parts (including aircraft parts and components) light oils, medium oils, fluorolubes, greases and silicones and waxes.

Preferred solvent vapor phase degreasing and defluxing methods of the present invention include immersing a soiled substrate or part (e.g., a printed circuit board or a fabricated metal, glass, ceramic, plastic, or elastomer part or composite) or a portion of a substrate or part into a boiling, non-flammable liquid in accordance with the present invention, including a composition of the present invention, including Composition 1, followed by rinsing the part in a second tank or cleaning zone by immersion or distillate spray with a clean solvent which can also be any one of the compositions of the present invention. The parts are then dried by maintaining the cooled part in the condensing vapors until temperature has reached equilibrium.

Solvent cleaning of various types of parts generally occurs in batch, hoist-assisted batch, conveyor batch, or in-line type conveyor degreaser and defluxer equipment. Parts may also be cleaned in open top defluxing or degreasing equipment. In both types of equipment, the entrance and/or exit ends of the equipment can be in open communication with both the ambient environment and the solvent within the equipment. In order to minimize the loss of solvent from the equipment by either convection or diffusion, a common practice in the art is to use.

The present invention includes solvent compositions comprising a composition of the present invention, including Composition 1, in combination with a co-solvent. The co-solvent may be selected from the group consisting of hexafluoroisopropylethylether, hexafluoroisopropylmethylthioether, HFE-7000, HFE-7200, HFE-7100, HFE-7300, HFE-7500, HFE-7600, trans-1,2-dichloroethylene, n-pentane, cyclopentane, ethanol, perfluoro(2-methyl-3-pentanone) (Novec 1230), cis-HFO-1336mzz, trans-HFO-1336mzz, HF-1234yf, HFO-1234ze(E), HFO-1233zd(E) and HFO-1233zd(Z).

### Electrolyte Formulations and Batteries

The present invention also provides electrolyte formulations, and batteries containing electrolyte formulations, which comprise a a composition of the present invention, including Composition 1. In general, the electrolyte formulations comprise: (a) electrolyte; (b) organic solvent for the electrolyte; and (c) additives that are included in the formulation to provide a desired property, or an improvement to a desired property, of the electrolyte formulation and/or of the battery which contains the electrolyte. A composition of the present invention, including Composition 1, can be included in the formulation as a solvent (or co-solvent) for the electrolyte and/or as an additive.

Thus, the present invention provides electrolyte formulations comprising: a salt, preferably lithium-ion salt; a solvent for the salt, said solvent comprising a composition of the present invention, including Composition 1 either with or without a co-solvent; and one or more additives different than the compounds of the present invention. The present invention also provides electrolyte formulations comprising: electrolyte, and preferably lithium ion electrolyte; (b) solvent for the lithium-ion electrolyte; and (c) an additive comprising a composition of the present invention, including Composition 1, either with or without additional additives.

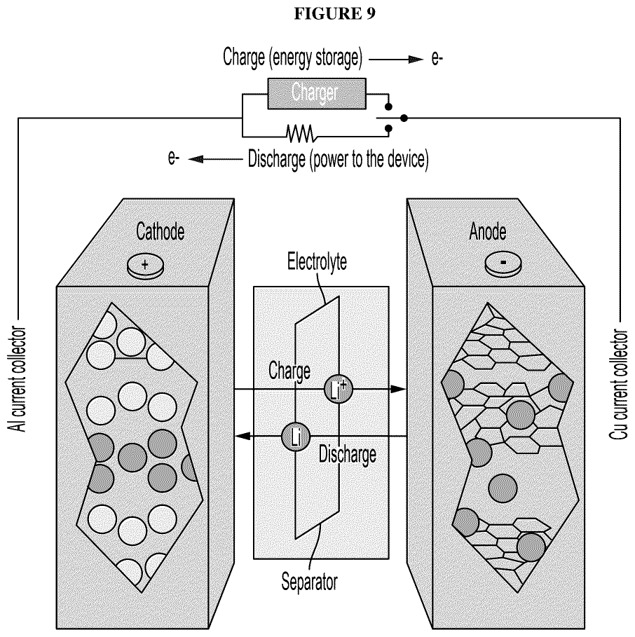

The present invention also provides batteries in general, and rechargeable lithium-ion batteries in particular, which contain an electrolyte formulation containing a a composition of the present invention, including Composition 1. An exemplary rechargeable lithium-ion battery is illustrated in FIG. 9 hereof, which shows a cathode and an anode and electrolyte formulation of the present invention which facilitates the flow of lithium ions between the cathode and the anode.

Although it is contemplated that the present electrolyte formulations may be useful in batteries in general, in preferred embodiments the electrolyte formulation comprises a lithium-ion electrolyte useful in rechargeable batteries. Non-limiting examples of lithium salts that may comprise the electrolyte portion of the formulation include: LiPF6, LiAsF6, LiClO4*LiBF4, LiBC4Og(LiBOB), LiBCO4F, (LiODFB), LiPF3 (C2F5)3(LiFAP), LiBF3(C2F5)LiPF3(C,F5)3(LiFAB), LiN, (CF3SO,) LiN(C,F5SO,), LiCF3SO3, LiC(CF3SO)3, LiPF4(CF3)2,LiPF3(CF3)3, LiPF3(iSO-C3C7)3, LiPF5(iso-C3F7). The overall salt concentration may vary depending on the particular needs of the application, in some embodiments the electrolyte may be present in the formulation in an amount between about 0.3M and about 2.5M or, from about 0.7M to about 1.5M.

### II.B. Heating and Cooling During Manufacture

With particular reference to FIG. 11, a side cross-sectional view of a refrigerant cooled conventional wet-etching station is illustrated. The basic operation of such a wet-etching station includes providing a container 15 which holds a bath of chemical etchant 13 for etching a plurality of semiconductor wafers 11. The temperature of the chemical etchant 13 is preferably kept as uniform as possible with the goal of maintaining the surface of wafers 11 such that they are uniformly etched by being immersed in the bath 15 of chemical etchant. To help maintain such a uniform temperature, a plurality of cooling lines 17 are installed in a portion of the container 15 holding chemical etchant bath 13 such that the cooling lines 17 are in contact with the chemical etchant 13. During wet etching process, the present refrigerants, including particularly each of Refrigerants 1-8, circulate through the coolant lines 17 and transport heat from the chemical etchant, either by sensible temperature change, or phase change and/or a combination of by sensible temperature change and phase change.

### EXAMPLES

### Example 1—Physical Property Measurement

The boiling point (“BP”) and dielectric constant (“Dk”) of HFO-1438ez(E) and HFO-1438ez(Z) were determined and the results are reported below in Table E1. Static dielectric constant for new molecules was calculated using Kirkwood theory as described in papers by Wang and Anderko [P. Wang and A. Anderko, Computation of dielectric constants of solvent mixtures and electrolyte solutions, Fluid Phase Equilibria 186 (2001) 103-122] and Harvey and Lemmon [A. H. Harvey and E. W. Lemmon, Method for estimating dielectric constant of natural gas mixtures, International Journal of Thermophysics 26 (2005) 31-46]. The dielectric property of each of HFO-1438ez(E) and HFO-1438ez(Z) was determined using the Agilent 85070 Dielectric Probe. All measurements were made at ambient pressure and room temperature (approximately 23° C.). Prior to making measurements, the system was calibrated from 1 GHz to 20 GHz with an open circuit, a short circuit, and DI water (@22.4° C.) standard. The result of the calibration is shown in the Table E1 below for DI H2O, and is consistent with DI water at 22.4° C. The accuracy of the probe is given as: Dielectric constant, er′=er′+/−0.05|er*| with er″=er″+/−0.05|er*| and (loss=er″/er′).

TABLE E1

| | | Calculated Dk | | |
|---|---|---|---|---|
| Name | BP, ° C. | at 20 KHz | GWP | ODP |
| HFO- | 30 | 2.22 | <10 | 0 |
| 1438ez(E) | | | | |
| HFO- | 55 | 7.8 | <10 | 0 |
| 1438ez(Z) | | | | |

### Example 2—Battery Cooling in Electric Vehicles Using Each of Refrigerants 1-8 and RB1-RB20

Batteries of electric vehicles develop heat during operation when charging and discharging. The typical design of vehicle batteries differs between three types: cylindrical cells, pouch cells and prismatic cells. All three types have different considerations in terms of heat transfer due to their shape. Prismatic and pouch cells are often used with cooling plates due to the straight outer faces. Cylindrical cells employ cooling ribbons that are in thermal contact with the outer shell of the cells. Extensive heat generation during charging and discharging of the cells can lead to an increase in temperature that can cause decreasing performance and reduced battery lifetime.

A battery cooling plate set up may be used to provide active cooling to a battery and remove the heat (e.g., to remove heat from the battery of an electric vehicle). In this Example, the performance of refrigerant fluids of the present invention, including each of Refrigerants 1-8 and of RB1-RB20, compared to 3M Novec 7200 are analyzed for the ability to provide cooling in single phase heat transfer.

It will be appreciated that the convective heat transfer can occur either by direct contact, i.e., when the battery is immersed in the fluid that may be pumped through the battery enclosure or indirectly, i.e., by using a cooling plate with a combination of convective and conductive heat transfer.

The present example uses a round tube with an internal diameter of 0.55 inches to provide a cooling load of 10246 BTU/h (3 kW). The tube length was 30 ft (9.14m) with an assumed pressure drop of 2.9PSI (20 kPa). The fluid temperature was 7.2 C (45F). The internal heat transfer coefficient is determined for turbulent flow. The necessary mass flow rate to remove the cooling load is determined for both fluids. The results of the comparison are shown in the Table E2 below. It can be seen in the results that the necessary mass flow rate to remove the generated heat is about or less than for 3M Novec 7200 and that the useful output (I.e., the heat transfer coefficient) is about or higher than 3M Novec 7200.

TABLE E2

| | Mass Flow | | Internal heat |
|---|---|---|---|
| | Rate | Prandtl | transfer coefficient |
| Fluid | (lb./s) | Number [—] | (BTU/(h-ft2-F.) |
| Refrigerants 1-7 | 0.9-1 | 9-11 | 300-350 |
| and RB 1-RB20 | | | |
| 3M Novec 7200 | 0.98 | 10.4 | 303.4 |

### Example 3A—Singe Phase (Sensible Heat) Immersion Cooling In Battery Applications Using Each of Refrigerants 1-7 and RB1-RB20

Batteries of electric vehicles develop heat during operation when charging and discharging. The typical design of vehicle batteries differs between three types: cylindrical cells, pouch cells and prismatic cells. All three types have different considerations in terms of heat transfer due to their shape. Extensive heat generation during charging and discharging of the cells can lead to an increase in temperature that can cause decreasing performance and reduced battery lifetime.

Refrigerants 1-8 and/or RB1-RB20 preferably have low dielectric constants, high dielectric strength, and are non-flammable fluids, which allows for direct cooling of the battery cells that are immersed in each of Refrigerants 1-8 and RB1-RB20.

The present example considers a battery module that consists of 1792 cylindrical battery cells of 18650 type. In one case the battery module is cooled by a 50/50 mixture of water/glycol in a flat tube heat exchanger that is on contact with the battery cells. In the other case the cells are immersed in each of Refrigerants 1-8 and/or RB1-RB20, i.e., are in direct contact with the fluid. The waste heat for the battery module is 8750 W that is evenly distributed over the total number of cells. The assumptions and operating conditions are listed in Table E3A1 and Table E3A2.

TABLE E3A1

| | | | Refrigerants |
|---|---|---|---|
| | | Water/ | 1-8 and RB1- |
| Parameter | Unit | Glycol | RB20 |
| Battery diameter | [mm] | 18.5 | 18.5 |
| Battery gap | [mm] | 3.8 | 1.5 |
| Battery height | [mm] | 65 | |
| Number of batteries | [—] | 1792 | |
| Battery mass | [g] | 49 | |
| Battery specific heat | [J/kgK] | 830 | |
| Total battery module waste heat | [W] | 8750 | |
| Fluid flow rate | [kg/s] | 0.1 | |
| Initial module temperature | [° C.] | 30 | |
| Fluid inlet temperature | [° C.] | 10 | |
| Cooling channel height | [mm] | 30 | n/a |
| Cooling channel width | [mm] | 2.8 | n/a |
| Heat exchanger flat tube wall | [mm] | 0.5 | n/a |
| thickness | | | |
| Heat exchanger flat tube thermal | [W/mK] | 3 | n/a |
| conductivity | | | |
| Heat exchanger flat tube relative | [—] | 0.0003 | n/a |
| surface roughness | | | |

TABLE E3A2

| | |
|---|---|
| Minimum cell | Maximum cell |
| temperature [° C.] | temperatures [° C.] |

| | Water/ | Refrigerants | Water/ | Refrigerants |
|---|---|---|---|---|
| | Glycol | 1-8 and | Glycol | 1-8 and |
| Time | 50/50 | RB1-RB20 | 50/50 | RB1-RB20 |
| 0 | 30.0 | 30.0 | 30.0 | 30.0 |
| 100 | 35.8 | 10-40 | 36.8 | 30-40 |
| 200 | 40.3 | 10-40 | 42.0 | 30-40 |
| 300 | 43.6 | 10-45 | 46.0 | 30-45 |
| 400 | 46.1 | 10-45 | 49.2 | 30-50 |
| 500 | 48.0 | 10-45 | 51.7 | 30-50 |
| 600 | 49.5 | 10-50 | 53.6 | 30-55 |
| 700 | 50.5 | 10-50 | 55.1 | 30-55 |
| 800 | 51.4 | 10-50 | 56.3 | 30-55 |
| 900 | 52.0 | 10-50 | 57.2 | 30-55 |

### Example 3B—Single Phase (Sensible Heat) Data Center Cooling Using Each of Refrigerants 1-8 and RB1-RB20

Data centers, also described herein as server banks or server hubs, are designed to maximize computing and storage capacity while minimizing space requirements. This results in densely packed arrays of servers and networking gear which can lead to concentrated heat generation. In addition, data centers operate around the clock, further contributing to heat build-up. With effective cooling, the efficiency and longevity of server hardware can be improved.

Refrigerants 1-8 and RM1-RM20 preferably have low dielectric constants, high dielectric strength, and are non-flammable fluids, which allows for direct cooling of the data centers that are immersed in each of Refrigerants 1-8 and RM1-RM20, including by causing sensible heat transfer to the refrigerant (i.e., refrigerant temperature change not associated with phase change).

A data center is thus cooled using separately each of Refrigerants 1-8 and RM1-RM20, and the system operates effectively, efficiently, safely and reliably. The electronic components are kept in the most desired operating temperature range while the data center is performing its functions.

### Example 3C—Single Phase (Sensible Heat) Semiconductor Integrated Circuit Cooling Using Each of Refrigerants 1-8 and RB1-RB20

Example 3B is repeated, except the cooling is applied to one or more semiconductor integrated circuit(s) using each of Refrigerants 1-8 and RM1-RM20. Effective and advantageous cooling is achieved by direct contact comprising at least partial immersion of the semiconductor integrated circuit in each of Refrigerants 1-8 and RM1-RM20. The semiconductor integrated circuit(s) are cooled with each of Refrigerants 1-8 and RM1-RM20 and the semiconductor integrated circuit(s) operate effectively, efficiently, safely and reliably while at least partially immersed in Refrigerants 1-8 and RM1-RM20, and the semiconductor integrated circuit(s) are kept in the most desired operating temperature range while performing its functions.

### Example 3D—Single Phase (Sensible Heat) Microprocessor Cooling Using Each of Refrigerants 1-8 and RB1-RB20

Example 3B is repeated, except the cooling is applied to one or more microprocessor(s) using each of Refrigerants 1-8 and RM1-RM20. Effective and advantageous cooling is achieved by direct contact comprising at least partial immersion of the microprocessor(s) in each of Refrigerants 1-8 and RM1-RM20. The microprocessor(s) are cooled with each of Refrigerants 1-8 and RM1-RM20 and the component/article/device operates effectively, efficiently, safely and reliably while at least partially immersed in Refrigerants 1-8 and RM1-RM20, and the microprocessor(s) are kept in the most desired operating temperature range while performing its functions.

### Example 3E—Single Phase (Sensible Heat) Electrochemical Cell Cooling Using Each of Refrigerants 1-8 and RB1-RB20

Example 3B is repeated, except the cooling is applied to one or more electrochemical cell(s) using each of Refrigerants 1-8 and RM1-RM20. Effective and advantageous cooling is achieved by direct contact comprising at least partial immersion of the electrochemical cell(s) in each of Refrigerants 1-8 and RM1-RM20. The electrochemical cell(s) are cooled with each of Refrigerants 1-8 and RM1-RM20 absorbing heat via and the electrochemical cell(s) operate effectively, efficiently, safely and reliably while at least partially immersed in each of Refrigerants 1-8 and RM1-RM20, and the electrochemical cell(s) are kept in the most desired operating temperature range while performing its functions.

### Example 3F—Single Phase (Sensible Heat) Fuel Cell Cooling Using Each of Refrigerants 1-8 and RB1-RB20

Example 3B is repeated, except the cooling is applied to one or more fuel cell(s) using each of Refrigerants 1-8 and RM1-RM20. Effective and advantageous cooling is achieved by direct contact comprising at least partial immersion of the fuel cell(s) in each of Refrigerants 1-8 and RM1-RM20. The fuel cell(s) are cooled with each of Refrigerants 1-8 and RM1-RM20 and the fuel cell(s) operate effectively, efficiently, safely and reliably while at least partially immersed in each of Refrigerants 1-8 and RM1-RM20, and the fuel cell(s) are kept in the most desired operating temperature range while performing its functions.

### Example 3G—Single Phase (Sensible Heat) Resistor Cooling Using Each of Refrigerants 1-8 and RB1-RB20

Example 3B is repeated, except the cooling is applied to one or more resistor(s) using each of Refrigerants 1-8 and RM1-RM20. Effective and advantageous cooling is achieved by direct contact comprising at least partial immersion of the resistor(s) in each of Refrigerants 1-8 and RM1-RM20. The resistor(s) are cooled with each of Refrigerants 1-8 and RM1-RM20 and the resistor(s) operate effectively, efficiently, safely and reliably while at least partially immersed in each of Refrigerants 1-8 and RM1-RM20, and the resistor(s) are kept in the most desired operating temperature range while performing its functions.

### Example 3H—Single Phase (Sensible Heat) Power Transistor Cooling Using Each of Refrigerants 1-8 and RB1-RB20

Example 3B is repeated, except the cooling is applied to one or more power transistor(s) using each of Refrigerants 1-8 and RM1-RM20. Effective and advantageous cooling is achieved by direct contact comprising at least partial immersion of the power transistor(s) in each of Refrigerants 1-8 and RM1-RM20. The power transistor(s) are cooled with each of Refrigerants 1-8 and RM1-RM20 and the power transistor(s) operate effectively, efficiently, safely and reliably while at least partially immersed in each of Refrigerants 1-8 and RM1-RM20, and the power transistor(s) are kept in the most desired operating temperature range while performing its functions.

### Example 31—Single Phase (Sensible Heat) Power Control Semiconductor Cooling Using Each of Refrigerants 1-8 and RB1-RB20

Example 3B is repeated, except the cooling is applied to one or more power control semiconductor(s) using each of Refrigerants 1-8 and RM1-RM20. Effective and advantageous cooling is achieved by direct contact comprising at least partial immersion of the power control semiconductor(s) in each of Refrigerants 1-8 and RM1-RM20. The power control semiconductor(s) are cooled with each of Refrigerants 1-8 and RM1-RM20 and the power control semiconductor(s) operate effectively, efficiently, safely and reliably while at least partially immersed in each of Refrigerants 1-8 and RM1-RM20, and the power control semiconductor(s) are kept in the most desired operating temperature range while performing its functions.

### Example 3J—Single Phase (Sensible Heat) Power Transformer Cooling Using Each of Refrigerants 1-8 and RB1-RB20

Example 3B is repeated, except the cooling is applied to one or more power transformer(s) using each of Refrigerants 1-8 and RM1-RM20. Effective and advantageous cooling is achieved by direct contact comprising at least partial immersion of the power transformer(s) in each of Refrigerants 1-8 and RM1-RM20. The power transformer(s) are cooled with each of Refrigerants 1-8 and RM1-RM20 and the power transformer(s) operate effectively, efficiently, safely and reliably while at least partially immersed in each of Refrigerants 1-8 and RM1-RM20, and the power transformer(s) are kept in the most desired operating temperature range while performing its functions.

### Example 3K—Single Phase (Sensible Heat) Printed Circuit Board Cooling Using Each of Refrigerants 1-8 and RB1-RB20

Example 3B is repeated, except the cooling is applied to one or more printed circuit board(s) using each of Refrigerants 1-8 and RM1-RM20. Effective and advantageous cooling is achieved by direct contact comprising at least partial immersion of the printed circuit board(s) in each of Refrigerants 1-8 and RM1-RM20. The printed circuit board(s) are cooled with each of Refrigerants 1-8 and RM1-RM20 and the printed circuit board(s) operate effectively, efficiently, safely and reliably while at least partially immersed in each of Refrigerants 1-8 and RM1-RM20, and the printed circuit board(s) are kept in the most desired operating temperature range while performing its functions.

### Example 3L—Single Phase (Sensible Heat) Laser Cooling Using Each of Refrigerants 1-8 and RB1-RB20

Example 3B is repeated, except the cooling is applied to one or more laser(s) using each of Refrigerants 1-8 and RM1-RM20. Effective and advantageous cooling is achieved by direct contact comprising at least partial immersion of the laser(s) in each of Refrigerants 1-8 and RM1-RM20. The printed laser(s) are cooled with each of Refrigerants 1-8 and RM1-RM20 and the laser(s) operate effectively, efficiently, safely and reliably while at least partially immersed in each of Refrigerants 1-8 and RM1-RM20, and the laser(s) are kept in the most desired operating temperature range while performing its functions.

### Example 3M—Single Phase (Sensible Heat) Multi-chip Module Cooling Using Each of Refrigerants 1-8 and RB1-RB20

Example 3B is repeated, except the cooling is applied to one or more multi-chip modules(s) using each of Refrigerants 1-8 and RM1-RM20. Effective and advantageous cooling is achieved by direct contact comprising at least partial immersion of the multi-chip modules(s) in each of Refrigerants 1-8 and RM1-RM20. The multi-chip modules(s) are cooled with each of Refrigerants 1-8 and RM1-RM20 and the multi-chip modules(s) operate effectively, efficiently, safely and reliably while at least partially immersed in each of Refrigerants 1-8 and RM1-RM20, and the multi-chip modules(s) are kept in the most desired operating temperature range while performing its functions.

### Example 3N—Single Phase (Sensible Heat) LED Cooling Using Each of Refrigerants 1-8 and RB1-RB20

Example 3B is repeated, except the cooling is applied to one or more LED(s) using each of Refrigerants 1-8 and RM1-RM20. Effective and advantageous cooling is achieved by direct contact comprising at least partial immersion of the LED(s) in each of Refrigerants 1-8 and RM1-RM20. The LED(s) are cooled with each of Refrigerants 1-8 and RM1-RM20 and the LED(s) operate effectively, efficiently, safely and reliably while at least partially immersed in each of Refrigerants 1-8 and RM1-RM20, and the LED(s) are kept in the most desired operating temperature range while performing its functions.

### Example 30—Single Phase (Sensible Heat) Electrical Distribution Switch Gear Cooling Using Each of Refrigerants 1-8 and RB1-RB20

Example 3B is repeated, except the cooling is applied to one or more electrical distribution switch gear(s) using each of Refrigerants 1-8 and RM1-RM20. Effective and advantageous cooling is achieved by direct contact comprising at least partial immersion of the electrical distribution switch gear(s) in each of Refrigerants 1-8 and RM1-RM20. The electrical distribution switch gear(s) are cooled with each of Refrigerants 1-8 and RM1-RM20 and the electrical distribution switch gear(s) operate effectively, efficiently, safely and reliably while at least partially immersed in each of Refrigerants 1-8 and RM1-RM20, and the electrical distribution switch gear(s) are kept in the most desired operating temperature range while performing its functions.

### Example 4A—Two Phase (Latent Heat) Immersion Cooling In Battery Applications Using Each of Refrigerants 1-7 and RB1-RB20

Example 3A is repeated except cooling comprising two phase (latent heat) cooling is provided to the batteries using each of Refrigerants 1-8 and RM1-RM20. Effective and advantageous cooling is achieved by direct contact comprising at least partial immersion of the batteries in each of Refrigerants 1-8 and RM1-RM20. The batteries are cooled with each of Refrigerants 1-8 and RM1-RM20 and the batteries operate effectively, efficiently, safely and reliably while at least partially immersed in each of Refrigerants 1-8 and RM1-RM20, and the batteries are kept in the most desired operating temperature range while performing its functions.

### Example 5A—Two Phase (Latent Heat) Immersion Cooling In Data Center Applications Using Each of Refrigerants 1-8 and RB1-RB20

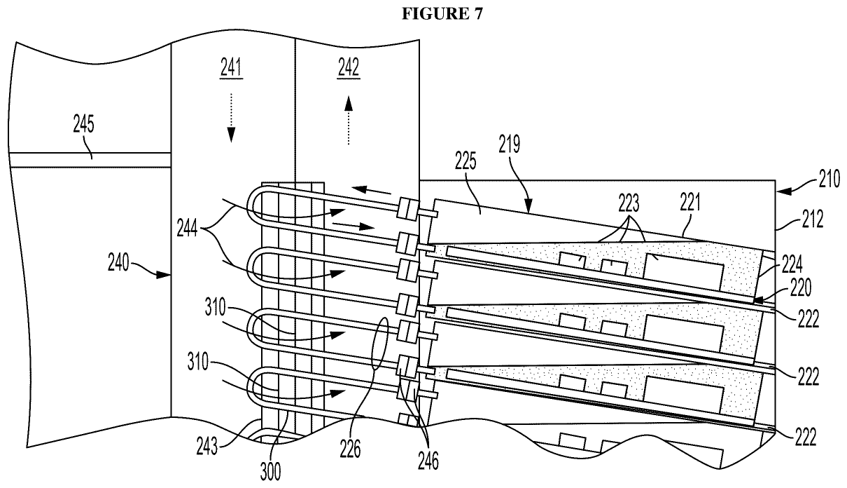

An example of data center cooling is provided, making reference to FIG. 7. A data center, generally denoted 200, includes a plurality of electronic subsystems 220 contained in one or more of electronics racks 210. At least one, and preferably a plurality, and preferably all, of the electronic subsystems 220 are associated with a cooling station 240 that includes (in one embodiment) a vertically extending, liquid-to-air heat exchanger 243 and supply and return ducting 241, 242 for directing a cooling airflow 244 across liquid-to-air heat exchanger 243. A cooling subsystem 219 is associated with at least one, and preferably a plurality, and preferably all, of the multiple electronic subsystems 220. In a preferred embodiment, as shown in FIG. 7, all of the subsystem 220 are associated with the cooling station 240 and a cooling subsystem 219. Each cooling subsystem 219 comprises (in this embodiment) a housing 221 (which preferably is a low-pressure housing) which encloses a respective electronic subsystem 220 comprising a plurality of electronic components 223. The electronic components are in operation as part of the data center and are generating heat as a result of performing their function in the data center. The components include, by way of example, printed circuit boards, microprocessor modules, and memory devices. Each electronic subsystem has, as it is operating, its heat generating components immersed in a thermal management fluid of the present disclosure 224, including each of Refrigerants 1-8 and RM 1-RM20. The fluid 224 boils in typical operation, generating dielectric vapor 225 according to the present disclosure. In the illustrated embodiment, electronic subsystems 220 are angled by providing upward-sloped support rails 222 within electronics rack 210 to accommodate the electronic subsystems 220 at an angle. Angling of the electronic subsystems as illustrated facilitates buoyancy-driven circulation of vapor 225 between the cooling subsystem 219 and the liquid-to-air heat exchanger 243 of the associated local cooling station 240. However, the excellent results according to the present disclosure and the present example are achieved equally well when such angling is not used. Multiple coolant loops 226 are coupled in fluid and thermal contact with the liquid-cooled electronic subsystems and a respective portion of liquid-to-air heat exchanger 243. In particular, multiple tubing sections 300 pass through liquid-to-air heat exchanger 243, which in this example includes a plurality of air-cooling fins 310. Vapor 225 is buoyancy-driven from housing 221 to the corresponding tubing section 300 of liquid-to-air heat exchanger 243, where the vapor condenses and is then returned as liquid to the associated liquid-cooled electronics subsystem. Cooling airflow 244 is provided in parallel to the supply ducting 241 of multiple local cooling stations 240 of data center 200, and the heated airflow is exhausted via return ducting 242. The equipment as described herein, but not the fluid of the present disclosure, is disclosed in US 2013/0019614, which is incorporated herein by reference.

The system as described above is operated with a thermal management fluid consisting of the present disclosure, including each of Refrigerants 1-8 and RB1-RB20 and ambient air as the heat sink for the condenser, and this system operates to effectively, efficiently, safely and reliably maintain the electronic components in the most desired operating temperature range while the system is performing its function in the operating data center.

### Example 5B—Two Phase (Latent Heat) Immersion Semiconductor Integrated Circuit Cooling Using Each of Refrigerants 1-8 and RB1-RB20

Example 5A is repeated, except the cooling is applied to one or more semiconductor integrated circuit(s) using each of Refrigerants 1-8 and RM1-RM20. Effective and advantageous cooling is achieved by direct contact comprising at least partial immersion of the semiconductor integrated circuit in each of Refrigerants 1-8 and RM1-RM20. The semiconductor integrated circuit(s) are cooled with each of Refrigerants 1-8 and RM1-RM20 and the semiconductor integrated circuit(s) operate effectively, efficiently, safely and reliably while at least partially immersed in Refrigerants 1-8 and RM1-RM20, and the semiconductor integrated circuit(s) are kept in the most desired operating temperature range while performing its functions.

### Example 5C—Two Phase (Latent Heat) Immersion Microprocessor Cooling Using Each of Refrigerants 1-8 and RB1-RB20

Example 5A is repeated, except the cooling is applied to one or more microprocessor(s) using each of Refrigerants 1-8 and RM1-RM20. Effective and advantageous cooling is achieved by direct contact comprising at least partial immersion of the microprocessor(s) in each of Refrigerants 1-8 and RM1-RM20. The microprocessor(s) are cooled with each of Refrigerants 1-8 and RM1-RM20 and the component/article/device operates effectively, efficiently, safely and reliably while at least partially immersed in Refrigerants 1-8 and RM1-RM20, and the microprocessor(s) are kept in the most desired operating temperature range while performing its functions.

### Example 5D—Two Phase (Latent Heat) Immersion Electrochemical Cell Cooling Using Each of Refrigerants 1-8 and RB1-RB20

Example 5A is repeated, except the cooling is applied to one or more electrochemical cell(s) using each of Refrigerants 1-8 and RM1-RM20. Effective and advantageous cooling is achieved by direct contact comprising at least partial immersion of the electrochemical cell(s) in each of Refrigerants 1-8 and RM1-RM20. The electrochemical cell(s) are cooled with each of Refrigerants 1-8 and RM1-RM20 absorbing heat via and the electrochemical cell(s) operate effectively, efficiently, safely and reliably while at least partially immersed in each of Refrigerants 1-8 and RM1-RM20, and the electrochemical cell(s) are kept in the most desired operating temperature range while performing its functions.

### Example 5E—Two Phase (Latent Heat) Immersion Fuel Cell Cooling Using Each of Refrigerants 1-8 and RB1-RB20

Example 5A is repeated, except the cooling is applied to one or more fuel cell(s) using each of Refrigerants 1-8 and RM1-RM20. Effective and advantageous cooling is achieved by direct contact comprising at least partial immersion of the fuel cell(s) in each of Refrigerants 1-8 and RM1-RM20. The fuel cell(s) are cooled with each of Refrigerants 1-8 and RM1-RM20 and the fuel cell(s) operate effectively, efficiently, safely and reliably while at least partially immersed in each of Refrigerants 1-8 and RM1-RM20, and the fuel cell(s) are kept in the most desired operating temperature range while performing its functions.

### Example 5F—Two Phase (Latent Heat) Immersion Resistor Cooling Using Each of Refrigerants 1-8 and RB1-RB20

Example 5A is repeated, except the cooling is applied to one or more resistor(s) using each of Refrigerants 1-8 and RM1-RM20. Effective and advantageous cooling is achieved by direct contact comprising at least partial immersion of the resistor(s) in each of Refrigerants 1-8 and RM1-RM20. The resistor(s) are cooled with each of Refrigerants 1-8 and RM1-RM20 and the resistor(s) operate effectively, efficiently, safely and reliably while at least partially immersed in each of Refrigerants 1-8 and RM1-RM20, and the resistor(s) are kept in the most desired operating temperature range while performing its functions.

### Example 5G—Two Phase (Latent Heat) Immersion Power Transistor Cooling Using Each of Refrigerants 1-8 and RB1-RB20

Example 5A is repeated, except the cooling is applied to one or more power transistor(s) using each of Refrigerants 1-8 and RM1-RM20. Effective and advantageous cooling is achieved by direct contact comprising at least partial immersion of the power transistor(s) in each of Refrigerants 1-8 and RM1-RM20. The power transistor(s) are cooled with each of Refrigerants 1-8 and RM1-RM20 and the power transistor(s) operate effectively, efficiently, safely and reliably while at least partially immersed in each of Refrigerants 1-8 and RM1-RM20, and the power transistor(s) are kept in the most desired operating temperature range while performing its functions.

### Example 5H—Two Phase (Latent Heat) Immersion Power Control Semiconductor Cooling Using Each of Refrigerants 1-8 and RB1-RB20

Example 5A is repeated, except the cooling is applied to one or more power control semiconductor(s) using each of Refrigerants 1-8 and RM1-RM20. Effective and advantageous cooling is achieved by direct contact comprising at least partial immersion of the power control semiconductor(s) in each of Refrigerants 1-8 and RM1-RM20. The power control semiconductor(s) are cooled with each of Refrigerants 1-8 and RM1-RM20 and the power control semiconductor(s) operate effectively, efficiently, safely and reliably while at least partially immersed in each of Refrigerants 1-8 and RM1-RM20, and the power control semiconductor(s) are kept in the most desired operating temperature range while performing its functions.

### Example 51—Two Phase (Latent Heat) Immersion Power Transformer Cooling Using Each of Refrigerants 1-8 and RB1-RB20

Example 5A is repeated, except the cooling is applied to one or more power transformer(s) using each of Refrigerants 1-8 and RM1-RM20. Effective and advantageous cooling is achieved by direct contact comprising at least partial immersion of the power transformer(s) in each of Refrigerants 1-8 and RM1-RM20. The power transformer(s) are cooled with each of Refrigerants 1-8 and RM1-RM20 and the power transformer(s) operate effectively, efficiently, safely and reliably while at least partially immersed in each of Refrigerants 1-8 and RM1-RM20, and the power transformer(s) are kept in the most desired operating temperature range while performing its functions.

### Example 5J—Two Phase (Latent Heat) Immersion Printed Circuit Board Cooling Using Each of Refrigerants 1-8 and RB1-RB20

Example 5A is repeated, except the cooling is applied to one or more printed circuit board(s) using each of Refrigerants 1-8 and RM1-RM20. Effective and advantageous cooling is achieved by direct contact comprising at least partial immersion of the printed circuit board(s) in each of Refrigerants 1-8 and RM1-RM20. The printed circuit board(s) are cooled with each of Refrigerants 1-8 and RM1-RM20 and the printed circuit board(s) operate effectively, efficiently, safely and reliably while at least partially immersed in each of Refrigerants 1-8 and RM1-RM20, and the printed circuit board(s) are kept in the most desired operating temperature range while performing its functions.

### Example 5K—Two Phase (Latent Heat) Immersion Laser Cooling Using Each of Refrigerants 1-8 and RB1-RB20

Example 5A is repeated, except the cooling is applied to one or more laser(s) using each of Refrigerants 1-8 and RM1-RM20. Effective and advantageous cooling is achieved by direct contact comprising at least partial immersion of the laser(s) in each of Refrigerants 1-8 and RM1-RM20. The printed laser(s) are cooled with each of Refrigerants 1-8 and RM1-RM20 and the laser(s) operate effectively, efficiently, safely and reliably while at least partially immersed in each of Refrigerants 1-8 and RM1-RM20, and the laser(s) are kept in the most desired operating temperature range while performing its functions.

### Example 5L—Two Phase (Latent Heat) Immersion Multi-chip Module Cooling Using Each of Refrigerants 1-8 and RB1-RB20

Example 5A is repeated, except the cooling is applied to one or more multi-chip modules(s) using each of Refrigerants 1-8 and RM1-RM20. Effective and advantageous cooling is achieved by direct contact comprising at least partial immersion of the multi-chip modules(s) in each of Refrigerants 1-8 and RM1-RM20. The multi-chip modules(s) are cooled with each of Refrigerants 1-8 and RM1-RM20 and the multi-chip modules(s) operate effectively, efficiently, safely and reliably while at least partially immersed in each of Refrigerants 1-8 and RM1-RM20, and the multi-chip modules(s) are kept in the most desired operating temperature range while performing its functions.

### Example 5M—Two Phase (Latent Heat) Immersion LED Cooling Using Each of Refrigerants 1-8 and RB1-RB20

Example 5A is repeated, except the cooling is applied to one or more LED(s) using each of Refrigerants 1-8 and RM1-RM20. Effective and advantageous cooling is achieved by direct contact comprising at least partial immersion of the LED(s) in each of Refrigerants 1-8 and RM1-RM20. The LED(s) are cooled with each of Refrigerants 1-8 and RM1-RM20 and the LED(s) operate effectively, efficiently, safely and reliably while at least partially immersed in each of Refrigerants 1-8 and RM1-RM20, and the LED(s) are kept in the most desired operating temperature range while performing its functions.

### Example 5N—Two Phase (Latent Heat) Immersion Electrical Distribution Switch Gear Cooling Using Each of Refrigerants 1-8 and RB1-RB20

### Example 6—Method and Use of Each of Refrigerants 1-8 and RB1-RM20 In Fabrication of an Electronic Component

An electronic component which undergoes processing that includes thermal control of the component (such as for example, in the etching of a silcon wafer as illustrated for example in FIG. 11) is contacted, directly or indirectly, by each of Refrigerant 1 through 8 and RM1-RM20 to transfer heat between (to and/or from said electronic component) as part of the manufacturing process. Effective temperature control is provided.

1. A method of heating and/or cooling of electronic components, articles and/or devices during the manufacture and/or operation thereof comprising:
(a) providing an electronic component, article or device which is being manufactured and/or being operated for its intended purpose; and
(b) transferring heat to and/or from said electronic component, article and/or device during at least a portion of said manufacturing and/or operating process by directly or indirectly transferring heat between said electronic component, article and/or device and a refrigerant fluid comprising at least trans-1,3,4,4,4-pentafluoro-(3-trifluoromethyl)-but-1-ene (hereinafter “HFO-1438ezy(E)”).

2. The method of claim 1 wherein said step of transferring heat comprises direct heat transfer.

3. The method of claim 1 wherein said step of transferring heat comprises indirect heat transfer.

4. The method of claim 1 wherein said refrigerant fluid comprises at least about 10% by weigh of HFO-1438ezy(E).

5. The method of claim 1 wherein said refrigerant fluid comprises at least about 50% by weigh of HFO-1438ezy(E).

6. The method of claim 1 wherein said refrigerant fluid comprises at least about 75% by weigh of HFO-1438ezy(E).

7. The method of claim 1 wherein said refrigerant fluid comprises at least about 90% by weigh of HFO-1438ezy(E).

8. The method of claim 1 wherein said refrigerant fluid consists essentially of HFO-1438ezy(E).

9. The method of claim 1 wherein said refrigerant fluid consists of HFO-1438ezy(E).

10. The method of claim 1 wherein said step of transferring heat comprises cooling said electronic component, article and/or device by transferring heat from said electronic component, article and/or device to said refrigerant during at least a portion of said manufacturing and/or operating process.

11. The method of claim 1 wherein said providing step comprises providing an electronic component comprising an integrated circuit.

12. The method of claim 1 wherein said electronic component is in a server.

13. The method of claim 12 wherein said server is a data center server.

14. The method of claim 1 wherein said providing step comprises providing a battery.

15. The method of claim 14 wherein said battery is in an electric or hybrid vehicle.

16. The method of claim 1 wherein said step of transferring heat comprises at least partially immersing said electronic component, article and/or device in said refrigerant fluid.

17. The method of claim 16 wherein said step of transferring heat comprises fully immersing said electronic component, article and/or device in said refrigerant fluid.

18. The method of claim 1 wherein said providing step comprises providing an electronic article during the process of manufacturing said electronic article.

19. The method of claim 16 wherein said electronic article is a wafer.

20. The method of claim 17 wherein said process of manufacturing said wafer comprises etching a portion of said wafer.
